(19) United States
(12) Patent Application Publication
(10) Pub. No.: US 2026/0090190 A1
(43) Pub. Date: Mar. 26, 2026

(54) COMPOSITION FOR ORGANIC OPTOELECTRONIC DEVICE, ORGANIC OPTOELECTRONIC DEVICE, AND DISPLAY DEVICE

(71) Applicant: SAMAUNG SDI CO., LTD., Yongin-si, Gyeonggi-do (KR)

(72) Inventors: Kipo JANG, Suwon-si, Gyeonggi-do (KR); Yunsoo KIM, Suwon-si, Gyeonggi-do (KR); Dong Min KANG, Suwon-si, Gyeonggi-do (KR); Sunghyun JUNG, Suwon-si, Gyeonggi-do (KR); Jihun SHIN, Suwon-si, Gyeonggi-do (KR); Hyung Sun KIM, Suwon-si, Gyeonggi-do (KR); Ho Kuk JUNG, Suwon-si, Gyeonggi-do (KR); Hansol SEO, Suwon-si, Gyeonggi-do (KR)

(21) Appl. No.: 19/107,806

(22) PCT Filed: Aug. 29, 2023
(86) PCT No.: PCT/KR2023/012764

§ 371 Date: Feb. 28, 2025

(30) Foreign Application Priority Data
Sep. 2, 2022 (KR) 10-2022-0111657

(51) Int. Cl. H10K 50/12; H10K 85/30; H10K 85/60; H10K 101/00

(52) U.S. Cl. CPC H10K 50/12; H10K 85/346; H10K 85/622; H10K 85/626; H10K 85/633; H10K 85/636; H10K 85/654; H10K 85/6572; H10K 85/6574; H10K 85/6576; H10K 2101/90

(57) ABSTRACT

Provided are a composition for an organic optoelectronic device, and an organic optoelectronic device including the same, and a display device, the composition including a first compound, a second compound, and a third compound, wherein the first compound is represented by Chemical Formula 1, the second compound is represented by Chemical Formula 2 or a combination of Chemical Formula 3 and Chemical Formula 4, and the third compound is represented by Chemical Formula 5.

The details of Chemical Formula 1 to Chemical Formula 5 are as described in the specification.

### TECHNICAL FIELD

A composition for an organic optoelectronic device, an organic optoelectronic device, and a display device are disclosed.

### BACKGROUND ART

An organic optoelectronic device (organic optoelectronic diode) is a device capable of converting electrical energy and optical energy to each other.

Organic optoelectronic devices may be largely divided into two types according to a principle of operation. One is a photoelectric device that generates electrical energy by separating excitons formed by light energy into electrons and holes, and transferring the electrons and holes to different electrodes, respectively and the other is light emitting device that generates light energy from electrical energy by supplying voltage or current to the electrodes.

Examples of the organic optoelectronic device include an organic photoelectric device, an organic light emitting diode, an organic solar cell, and an organic photoconductor drum.

Among them, organic light emitting diodes (OLEDs) are attracting much attention in recent years due to increasing demands for flat panel display devices. The organic light emitting diode is a device that converts electrical energy into light, and the performance of the organic light emitting diode is greatly influenced by an organic material between electrodes.

### DISCLOSURE

### Technical Problem

An embodiment provides a composition for an organic optoelectronic device capable of implementing a high-efficiency and long life-span organic optoelectronic device.

Another embodiment provides an organic optoelectronic device including the composition for an organic optoelectronic device.

Another embodiment provides a display device including the organic optoelectronic device.

### Technical Solution

According to an embodiment, a composition for an organic optoelectronic device includes a first compound, a second compound, and a third compound, wherein the first compound is represented by Chemical Formula 1, the second compound is represented by Chemical Formula 2 or a combination of Chemical Formula 3 and Chemical Formula 4, and the third compound is represented by Chemical Formula 5.

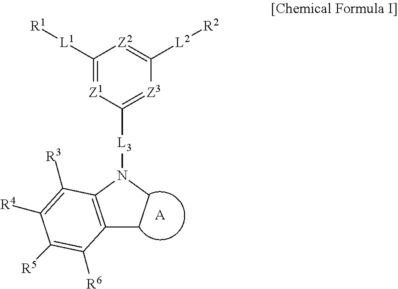

In Chemical Formula 1,
Z¹ to Z³ are N or C-L^{a}-R^{a}
at least two of Z¹ to Z³ are N,
L^{a} and L¹ to L³ are each independently a single bond, a substituted or unsubstituted C6 to C20 arylene group, a substituted or unsubstituted C2 to C20 heterocyclic group, or a combination thereof,
R¹ and R² are each independently a substituted or unsubstituted C6 to C30 aryl group, a substituted or unsubstituted C2 to C30 heterocyclic group, or a combination thereof,
R^{a}, and R³ to R⁶ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
ring A is represented by any one of Chemical Formula I-1 to Chemical Formula I-6,

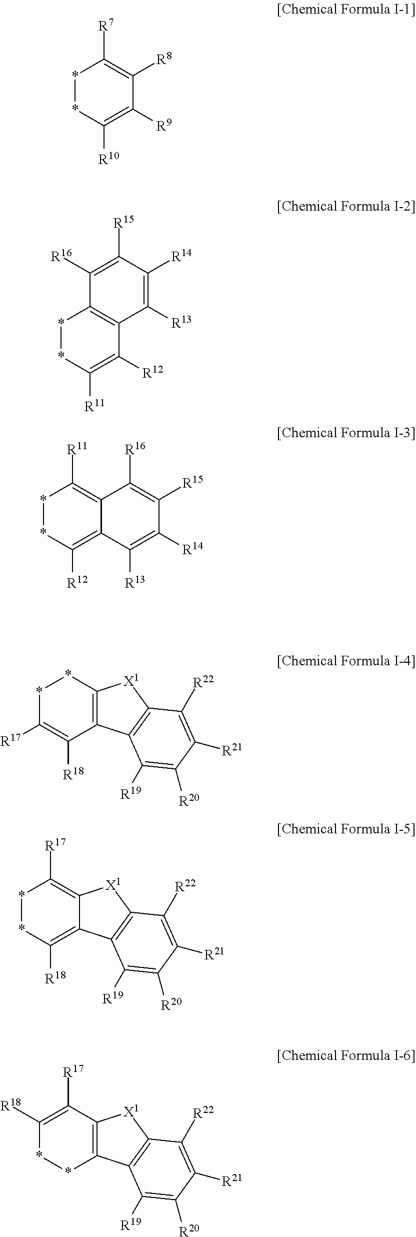

In Chemical Formula I-1 to Chemical Formula I-6,
X¹ is O, S, or NR^{b}
R^{b} and R⁷ to R²² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
* is a linking point;

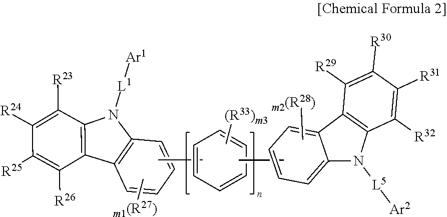

wherein, in Chemical Formula 2,
Ar¹ and Ar² are each independently a substituted or unsubstituted C6 to C30 aryl group or a substituted or unsubstituted C2 to C30 heterocyclic group,
L⁴ and L⁵ are each independently a single bond or a substituted or unsubstituted C6 to C20 arylene group,
R²³ to R³³ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group,
m1 and m2 are each independently one of integers of 1 to 3,
m3 is one of integers of 1 to 4, and
n is one of integers of 0 to 2;

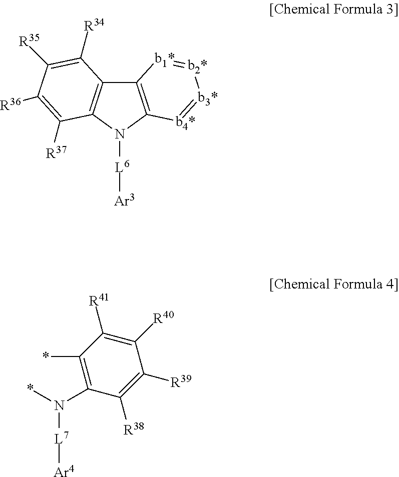

wherein, in Chemical Formulas 3 and 4,
Ar³ and Ar⁴ are each independently a substituted or unsubstituted C6 to C30 aryl group or a substituted or unsubstituted C2 to C30 heterocyclic group,
among b₁* to b₄* in Chemical Formula 3, two adjacent ones are each a linking carbon (C) that is linked to * in Chemical Formula 4,
among b₁* to b₄* in Chemical Formula 3, the remaining two that are not linked to * in Chemical Formula 4 are each independently C-L^{b}-R^{c},
L^{b}, L⁶, and L⁷ are each independently a single bond or a substituted or unsubstituted C6 to C20 arylene group, and
R^{c} and R³⁴ to R⁴¹ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group;

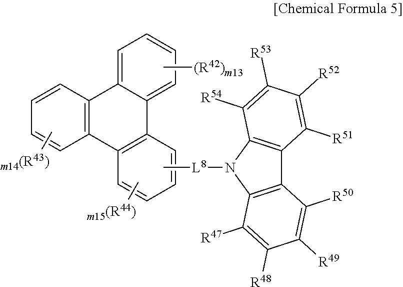

wherein, in Chemical Formula 5,
R⁴² to R⁴⁴ and R⁴⁷ to R⁵⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
m13 and m14 are each independently one of integers of 1 to 4,
m15 is one of integers of 1 to 3, and
L⁸ is a single bond, or a substituted or unsubstituted C6 to C20 arylene group including at least one of a meta-phenylene group and a para-phenylene group.

According to another embodiment, an organic optoelectronic device includes an anode and a cathode facing each other, and at least one organic layer between the anode and the cathode, wherein the organic layer includes a light emitting layer and the light emitting layer includes the aforementioned composition for an organic optoelectronic device.

According to another embodiment, a display device including the organic optoelectronic device is provided.

### Advantageous Effects

High-efficiency long life-span organic optoelectronic devices may be realized.

### DESCRIPTION OF THE DRAWINGS

FIG. 1 is a cross-sectional view illustrating an organic light emitting diode according to an embodiment.

### DESCRIPTION OF SYMBOLS

100: organic light emitting diode
105: organic layer
110: cathode
120: anode
130: light emitting layer
140: hole transport region
150: electron transport region

### BEST MODE

Hereinafter, embodiments of the present invention are described in detail. However, these embodiments are exemplary, and this disclosure is not limited thereto.

As used herein, when a definition is not otherwise provided, “substituted” refers to replacement of at least one hydrogen of a substituent or a compound by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a C1 to C20 alkoxy group, a C1 to C10 trifluoroalkyl group, a cyano group, or a combination thereof.

In one example of the present invention, the “substituted” refers to replacement of at least one hydrogen of a substituent or a compound by deuterium, a cyano group, a C1 to C30 alkyl group, a C1 to C10 alkylsilyl group, a C6 to C30 arylamine group, a C6 to C30 arylsilyl group, a C3 to C30 cycloalkyl group, a C3 to C30 heterocycloalkyl group, a C6 to C30 aryl group, or a C2 to C30 heteroaryl group. In specific example of the present invention, the “substituted” refers to replacement of at least one hydrogen of a substituent or a compound by deuterium, a cyano group, a C1 to C20 alkyl group, a C6 to C30 arylamine group, a C6 to C30 aryl group, or a C2 to C30 heteroaryl group. In specific example of the present invention, the “substituted” refers to replacement of at least one hydrogen of a substituent or a compound by deuterium, a cyano group, a C1 to C5 alkyl group, a C6 to C20 arylamine group, a C6 to C18 aryl group, a dibenzofuranyl group, a dibenzothiophenyl group, a carbazolyl group, or a pyridinyl group. In specific example of the present invention, the “substituted” refers to replacement of at least one hydrogen of a substituent or a compound by deuterium, a cyano group, a methyl group, an ethyl group, a propyl group, a butyl group, a C6 to C20 arylamine group, a phenyl group, a biphenyl group, a terphenyl group, a naphthyl group, a triphenyl group, a fluorenyl group, a dibenzofuranyl group, a dibenzothiophenyl group, a carbazolyl group, or a pyridinyl group.

In the present specification, “unsubstituted” refers to non-replacement of a hydrogen atom by another substituent and remaining of the hydrogen atom.

In the present specification, “hydrogen substitution (—H)” may include “deuterium substitution (—D)” or “tritium substitution (—T).”

In the present specification, when a definition is not otherwise provided, “hetero” refers to one including one to three heteroatoms selected from N, O, S, P, and Si, and remaining carbons in one functional group.

In the present specification, “aryl group” refers to a group including at least one hydrocarbon aromatic moiety, and all elements of the hydrocarbon aromatic moiety have p-orbitals which form conjugation, for example a phenyl group, a naphthyl group, and the like, two or more hydrocarbon aromatic moieties may be linked by a sigma bond and may be, for example a biphenyl group, a terphenyl group, a quaterphenyl group, and the like, and two or more hydrocarbon aromatic moieties are fused directly or indirectly to provide a non-aromatic fused ring, for example a fluorenyl group.

The aryl group may include a monocyclic, polycyclic, or fused ring polycyclic (i.e., rings sharing adjacent pairs of carbon atoms) functional group.

As used herein, “heterocyclic group” is a generic concept of a heteroaryl group, and may include at least one heteroatom selected from N, O, S, P, and Si instead of carbon (C) in a cyclic compound such as aryl group, a cycloalkyl group, a fused ring thereof, or a combination thereof.

When the heterocyclic group is a fused ring, the entire ring or each ring of the heterocyclic group may include one or more heteroatoms.

For example, “a heteroaryl group” may refer to aryl group including at least one heteroatom selected from N, O, S, P, and Si. Two or more heteroaryl groups are linked by a sigma bond directly, or when the heteroaryl group includes two or more rings, the two or more rings may be fused. When the heteroaryl group is a fused ring, each ring may include one to three heteroatoms.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted triphenylene group, a substituted or unsubstituted perylenyl group, a substituted or unsubstituted fluorenyl group, a substituted or unsubstituted indenyl group, or a combination thereof, but is not limited thereto.

More specifically, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted dibenzofuranyl group, or a substituted or unsubstituted dibenzothiophenyl group, or a combination thereof, but are not limited thereto.

As used herein, hole characteristics refer to an ability to donate an electron to form a hole when an electric field is applied and that a hole formed in the anode may be easily injected into the light emitting layer and transported in the light emitting layer due to conductive characteristics according to a highest occupied molecular orbital (HOMO) level.

In addition, electron characteristics refer to an ability to accept an electron when an electric field is applied and that electron formed in the cathode may be easily injected into the light emitting layer and transported in the light emitting layer due to conductive characteristics according to a lowest unoccupied molecular orbital (LUMO) level.

Hereinafter, a composition for an organic optoelectronic device according to an embodiment is described.

The composition for an organic optoelectronic device according to an embodiment is a mixture including three types of compounds, specifically, a first compound having electronic characteristics, a second compound having hole characteristics, and a third compound having buffer characteristics.

The third compound is a compound having a wide HOMO-LUMO band gap including both the HOMO-LUMO band gaps of the first compound and the second compound, and has a lower hole mobility than the hole mobility of the second compound having the hole characteristics, which slows down the hole injection characteristic and can bring about an effect of reducing hole traps.

In addition, as the third compound has lower electron mobility than the electron mobility of the first compound, and the light emitting layer region relatively shifts toward the hole transport auxiliary layer, exciton quenching at the interface with the electron transport auxiliary layer and deterioration thereby may be reduced, and thus makes it possible to increase the life-span.

The first compound having the electronic characteristics has a structure in which carbazole or a carbazole derivative is substituted with a nitrogen-containing 6-membered ring and is represented by Chemical Formula 1.

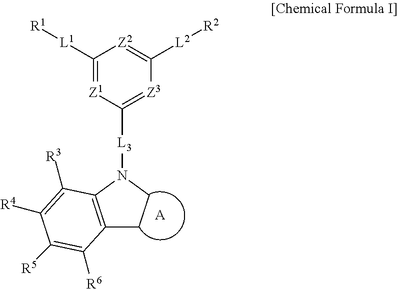

In Chemical Formula 1,
Z¹ to Z³ are N or C-L^{a}-R^{a},
at least two of Z¹ to Z³ are N,
L^{a} and L¹ to L³ are each independently a single bond, a substituted or unsubstituted C6 to C20 arylene group, a substituted or unsubstituted C2 to C20 heterocyclic group, or a combination thereof,
R¹ and R² are each independently a substituted or unsubstituted C6 to C30 aryl group, a substituted or unsubstituted C2 to C30 heterocyclic group, or a combination thereof,
R^{a}, and R³ to R⁶ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
ring A is represented by any one of Chemical Formula I-1 to Chemical Formula I-6,

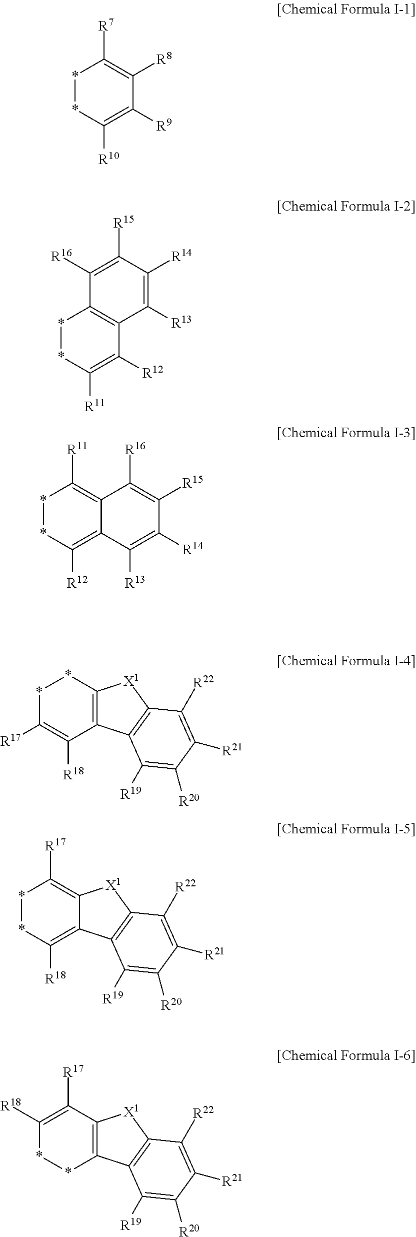

wherein, in Chemical Formula I-1 to Chemical Formula I-6,
X¹ is O, S, or NR,
R^{b} and R⁷ to R²² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
* is a linking point.

Specifically, Z¹ to Z³ in Chemical Formula 1 may each independently be N or CH, and at least two of Z¹ to Z³ may be N.

For example, Z¹ to Z³ may each be N.

For example, Z¹ and Z³ may be N, and Z² may be CH.

L¹ to L³ in Chemical Formula 1 may each independently be a single bond, a substituted or unsubstituted phenylene group, a substituted or unsubstituted biphenylene group, a substituted or unsubstituted naphthylene group, a substituted or unsubstituted carbazolylene group, a substituted or unsubstituted dibenzofuranylene group, a substituted or unsubstituted dibenzothiophenylene group, or a substituted or unsubstituted pyridinylene group.

R¹ and R² in Chemical Formula 1 may each independently be a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted carbazolyl group, a substituted or unsubstituted indolocarbazolyl group, a substituted or unsubstituted dibenzofuranyl group, a substituted or unsubstituted dibenzothiophenyl group, a substituted or unsubstituted fused carbazolyl group, a substituted or unsubstituted fused dibenzofuranyl group, a substituted or unsubstituted fused dibenzothiophenyl group, a substituted or unsubstituted fused indolocarbazolyl group, a substituted or unsubstituted pyridinyl group, a substituted or unsubstituted pyrimidinyl group, a substituted or unsubstituted triazinyl group, a substituted or unsubstituted quinolinyl group, a substituted or unsubstituted isoquinolinyl group, a substituted or unsubstituted quinoxalinyl group, a substituted or unsubstituted quinazolinyl group, or a substituted or unsubstituted benzoquinazolinyl group.

In a specific example of the present invention, L¹ to L³ in Chemical Formula 1 may each independently be a single bond, a substituted or unsubstituted m-phenylene group, or a substituted or unsubstituted p-phenylene group.

For example, R¹ and R² in Chemical Formula 1 may each independently be a substituted or unsubstituted phenyl group, a substituted or unsubstituted biphenyl group, a substituted or unsubstituted terphenyl group, a substituted or unsubstituted naphthyl group, a substituted or unsubstituted fluorenyl group, a substituted or unsubstituted carbazolyl group, a substituted or unsubstituted dibenzofuranyl group, or a substituted or unsubstituted dibenzothiophenyl group.

Chemical Formula 1 may be represented by any one of Chemical Formula 1A to Chemical Formula 1J, depending on the specific structure of the carbazole and carbazole derivative.

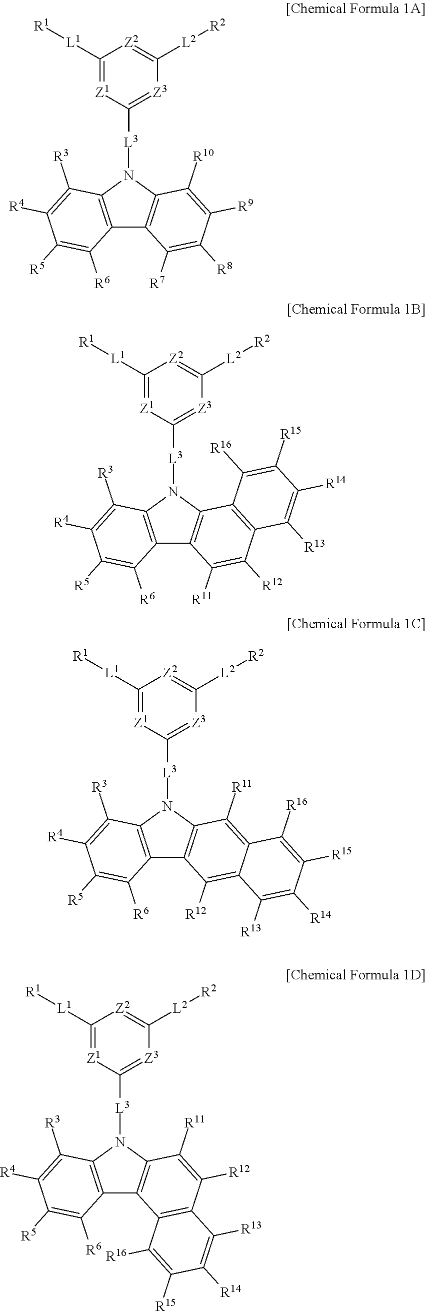

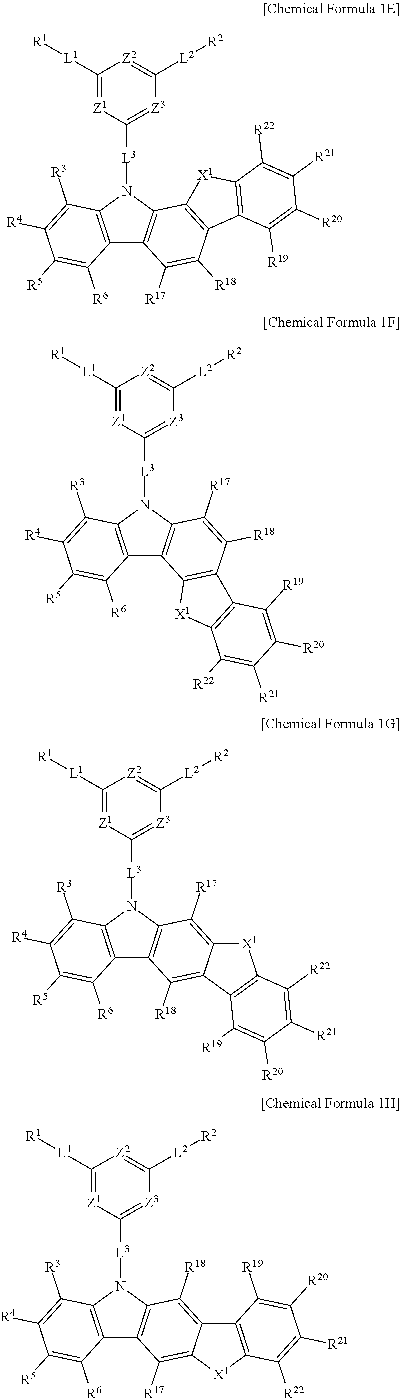

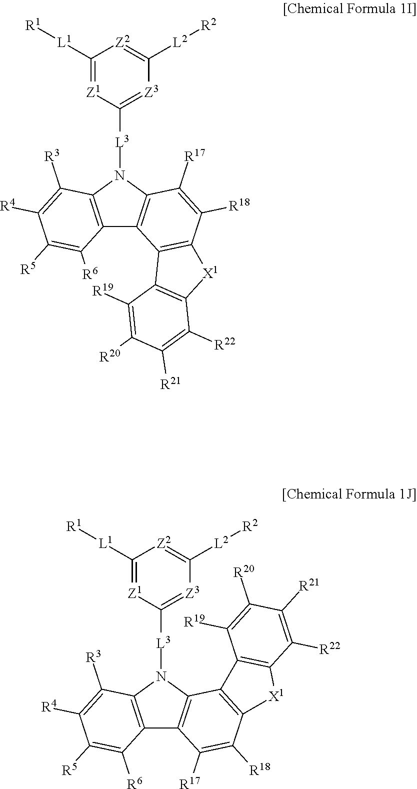

In Chemical Formula 1A to Chemical Formula 1J, the definitions of Z¹ to Z³, L¹ to L³, R¹ to R²², and X¹ are the same as described above.

Specifically, R³ to R¹⁰ in Chemical Formula 1A may each independently be hydrogen, deuterium, a substituted or unsubstituted phenyl group, a substituted or unsubstituted biphenyl group, a substituted or unsubstituted terphenyl group, a substituted or unsubstituted carbazolyl group, a substituted or unsubstituted indolocarbazolyl group, a substituted or unsubstituted dibenzofuranyl group, or a substituted or unsubstituted dibenzothiophenyl group.

For example, R³ to R¹⁰ in Chemical Formula 1A may each independently be hydrogen, deuterium, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

For example, R³ to R⁶ and R¹¹ to R¹⁶ in Chemical Formula 1B to Chemical Formula 1D may each independently be hydrogen, deuterium, or a substituted or unsubstituted phenyl group.

For example, R³ to R⁶ and R¹⁷ to R²² in Chemical Formula 1E to Chemical Formula 1J may each independently be hydrogen, deuterium, or a substituted or unsubstituted phenyl group.

For example, the first compound may be represented by any one of Chemical Formula 1A and Chemical Formula 1E to Chemical Formula 1H.

As a specific example, the first compound may be represented by Chemical Formula 1A or Chemical Formula 1E.

For example, the first compound may be represented by Chemical Formula 1A.

According to a specific embodiment of the present invention, in Chemical Formula 1A, L¹ to L³ may each independently be a single bond or a substituted or unsubstituted phenylene group, R¹ and R² may each independently be a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group, and R³ to R¹⁰ may each independently be hydrogen, deuterium, or a substituted or unsubstituted phenyl group, but are not limited thereto.

The first compound may be, for example, one selected from the compounds listed in Group 1.

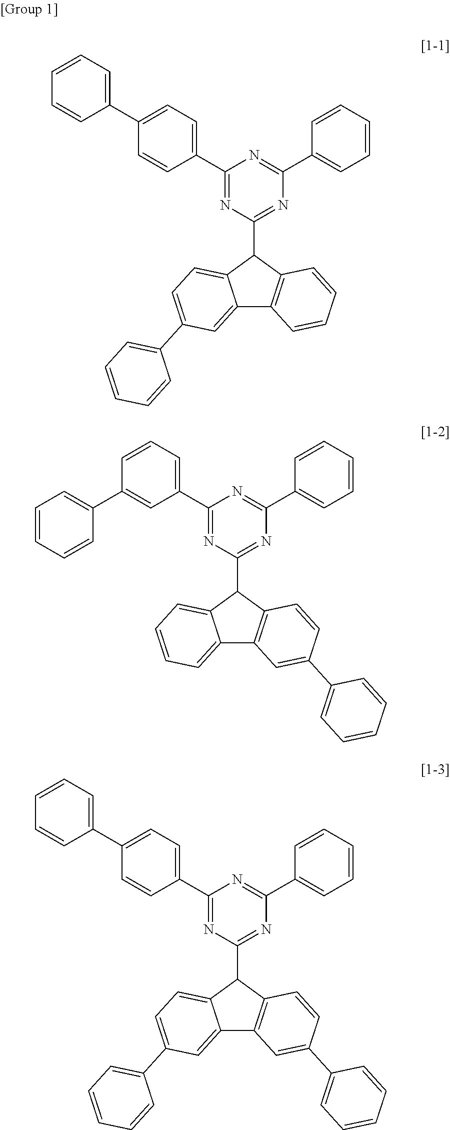

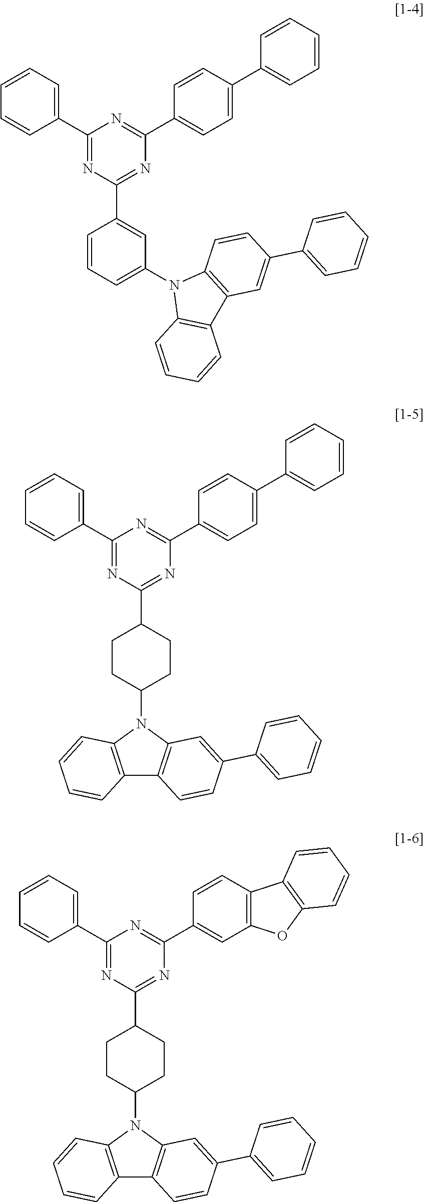 [SMILES: c1ccc(-c2ccc(-c3nc(-c4ccccc4)nc(-c4cccc(-n5c6ccccc6c6cc(-c7ccccc7)ccc65)c4)n3)cc2)cc1 ; c1ccc(-c2ccc(-c3nc(-c4ccccc4)nc(C4CCC(n5c6ccccc6c6ccc(-c7ccccc7)cc65)CC4)n3)cc2)cc1 ; c1ccc(-c2ccc3c4ccccc4n(C4CCC(c5nc(-c6ccccc6)nc(-c6ccc7c(c6)oc6ccccc67)n5)CC4)c3c2)cc1]

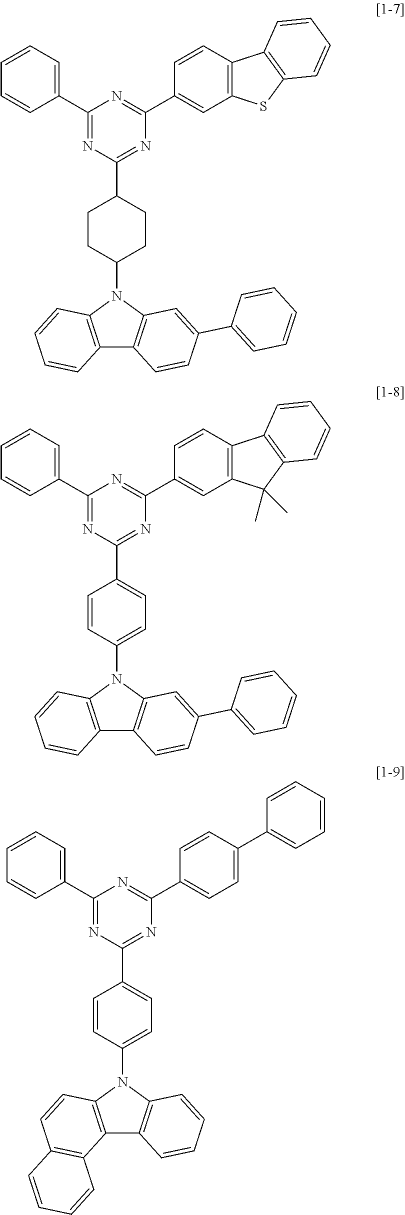 [SMILES: c1ccc(-c2ccc3c4ccccc4n(C4CCC(c5nc(-c6ccccc6)nc(-c6ccc7c(c6)sc6ccccc67)n5)CC4)c3c2)cc1 ; CC1(C)c2ccccc2-c2ccc(-c3nc(-c4ccccc4)nc(-c4ccc(-n5c6ccccc6c6ccc(-c7ccccc7)cc65)cc4)n3)cc21 ; c1ccc(-c2ccc(-c3nc(-c4ccccc4)nc(-c4ccc(-n5c6ccccc6c6c7ccccc7ccc65)cc4)n3)cc2)cc1]

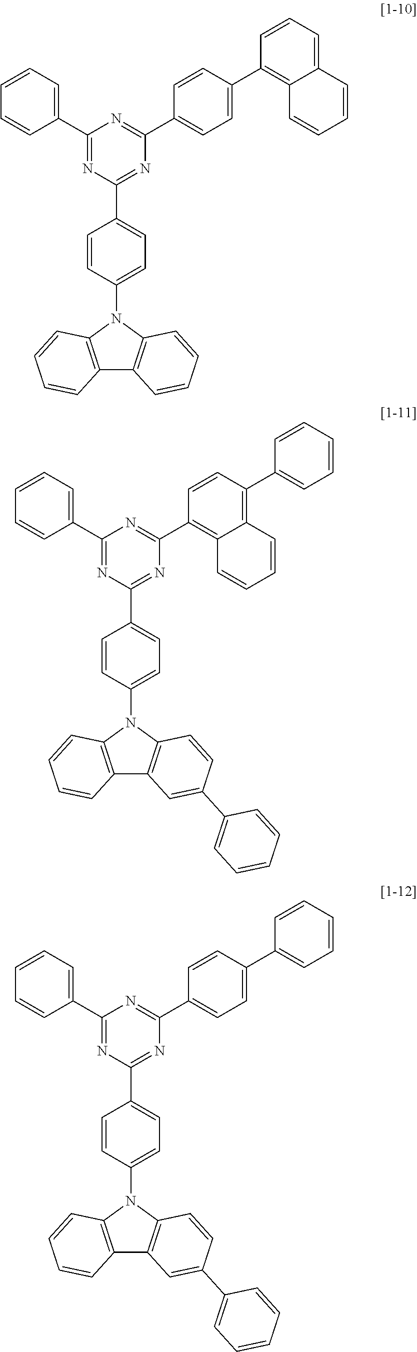 [SMILES: c1ccc(-c2nc(-c3ccc(-c4cccc5ccccc45)cc3)nc(-c3ccc(-n4c5ccccc5c5ccccc54)cc3)n2)cc1 ; c1ccc(-c2ccc3c(c2)c2ccccc2n3-c2ccc(-c3nc(-c4ccccc4)nc(-c4ccc(-c5ccccc5)c5ccccc45)n3)cc2)cc1 ; c1ccc(-c2ccc(-c3nc(-c4ccccc4)nc(-c4ccc(-n5c6ccccc6c6cc(-c7ccccc7)ccc65)cc4)n3)cc2)cc1]

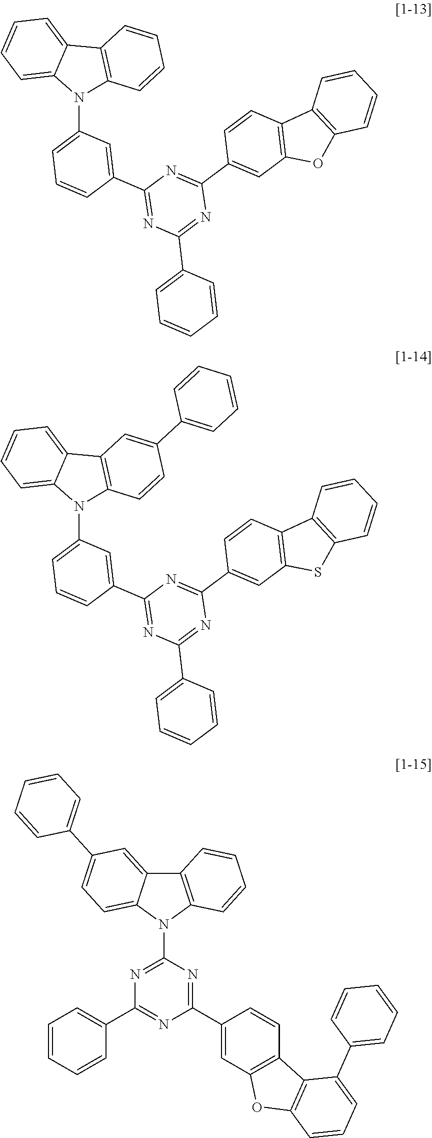

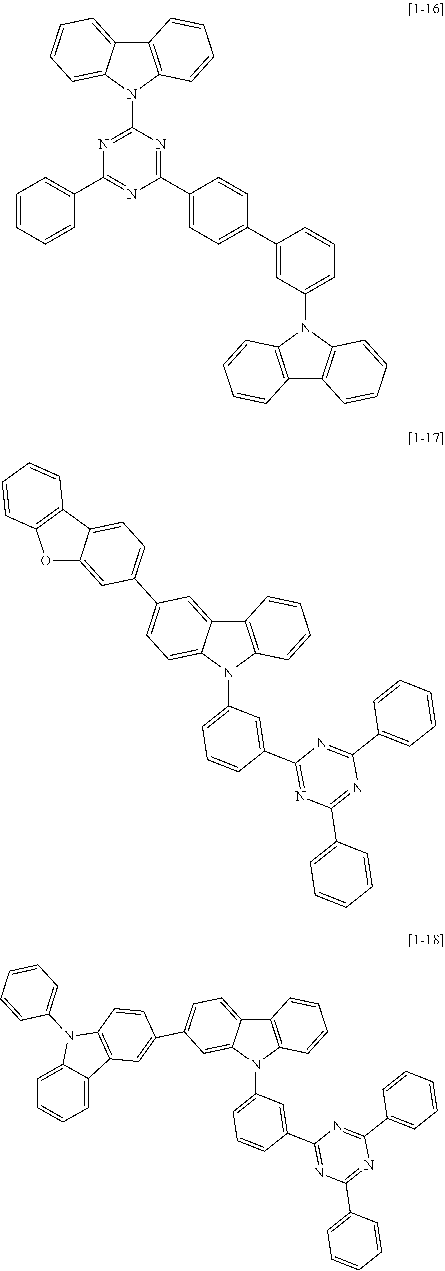 [SMILES: c1ccc(-c2nc(-c3ccc(-c4cccc(-n5c6ccccc6c6ccccc65)c4)cc3)nc(-n3c4ccccc4c4ccccc43)n2)cc1 ; c1ccc(-c2nc(-c3ccccc3)nc(-c3cccc(-n4c5ccccc5c5cc(-c6ccc7c(c6)oc6ccccc67)ccc54)c3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

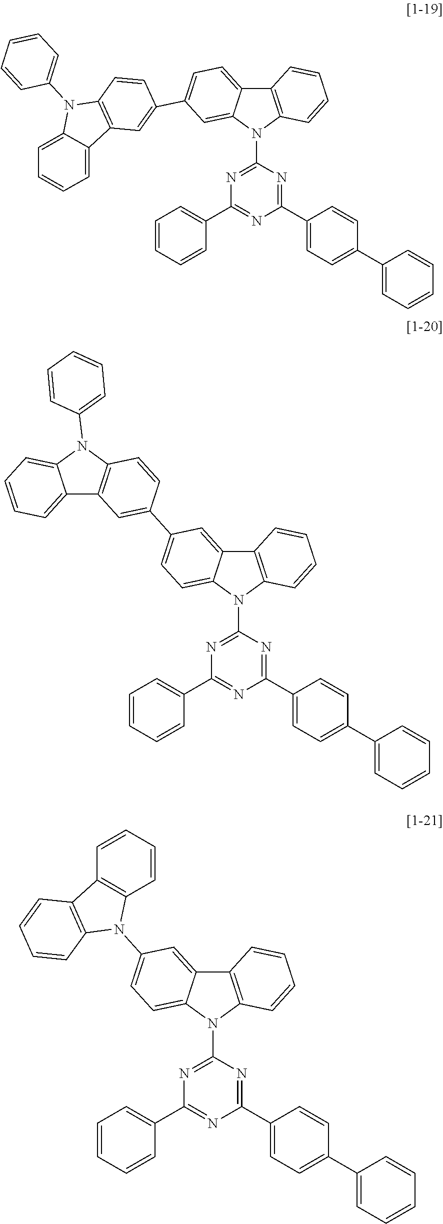 [SMILES: c1ccc(-c2ccc(-c3nc(-c4ccccc4)nc(-n4c5ccccc5c5ccc(-c6ccc7c(c6)c6ccccc6n7-c6ccccc6)cc54)n3)cc2)cc1 ; c1ccc(-c2ccc(-c3nc(-c4ccccc4)nc(-n4c5ccccc5c5cc(-c6ccc7c(c6)c6ccccc6n7-c6ccccc6)ccc54)n3)cc2)cc1 ; c1ccc(-c2ccc(-c3nc(-c4ccccc4)nc(-n4c5ccccc5c5cc(-n6c7ccccc7c7ccccc76)ccc54)n3)cc2)cc1]

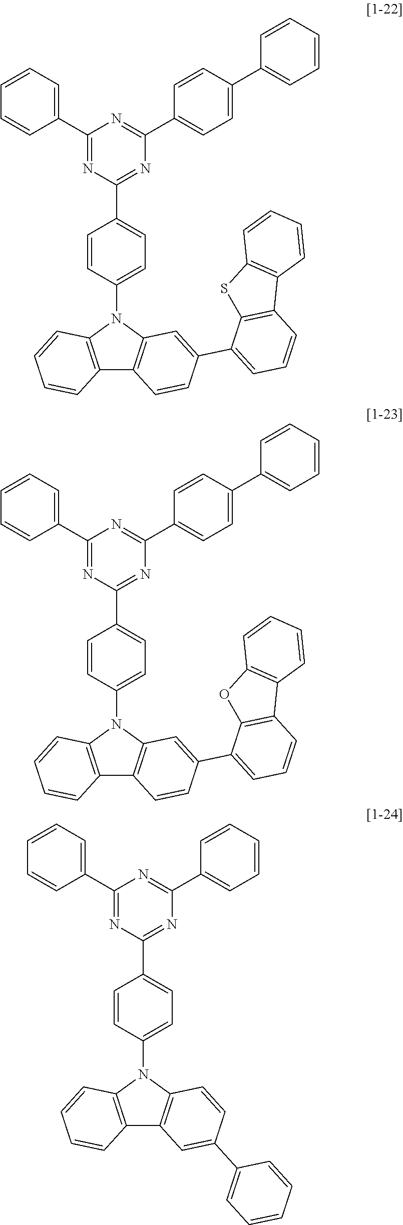

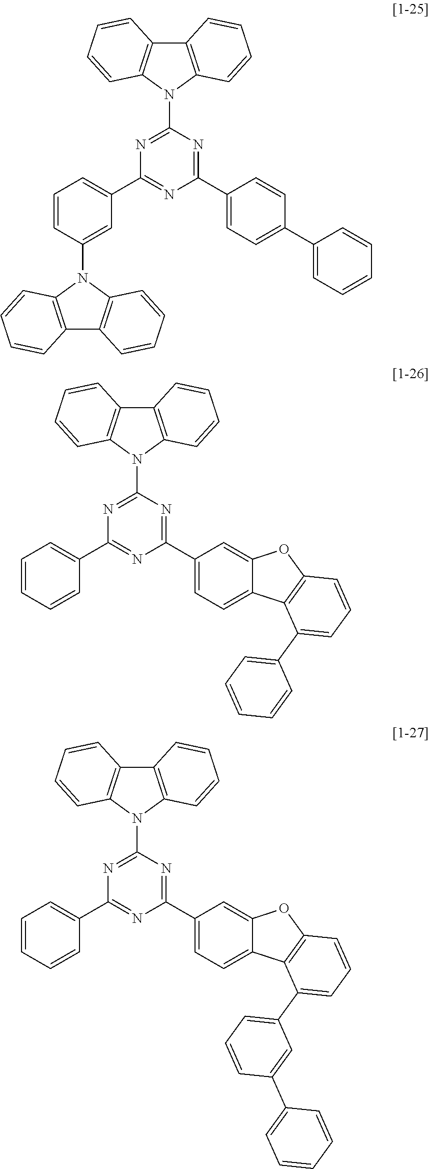

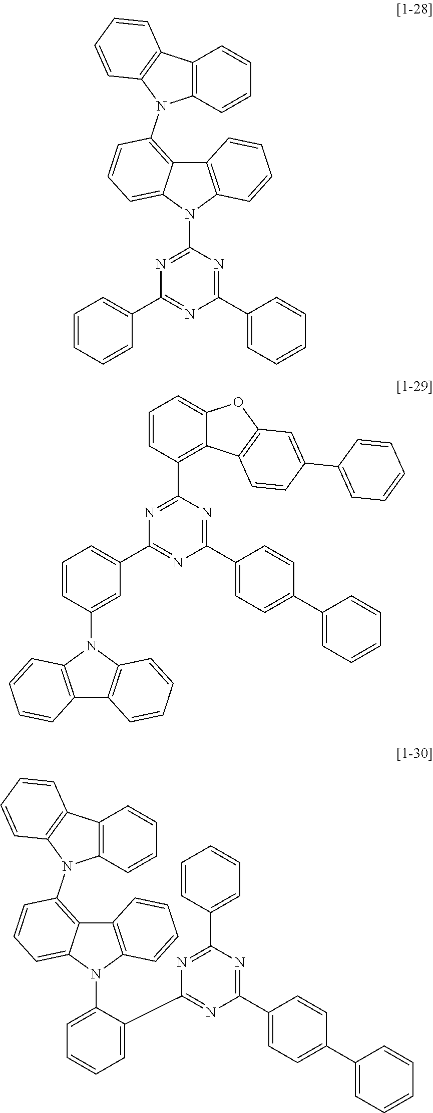 [SMILES: c1ccc(-c2nc(-c3ccccc3)nc(-n3c4ccccc4c4c(-n5c6ccccc6c6ccccc65)cccc43)n2)cc1 ; c1ccc(-c2ccc(-c3nc(-c4cccc(-n5c6ccccc6c6ccccc65)c4)nc(-c4cccc5oc6cc(-c7ccccc7)ccc6c45)n3)cc2)cc1 ; c1ccc(-c2ccc(-c3nc(-c4ccccc4)nc(-c4ccccc4-n4c5ccccc5c5c(-n6c7ccccc7c7ccccc76)cccc54)n3)cc2)cc1]

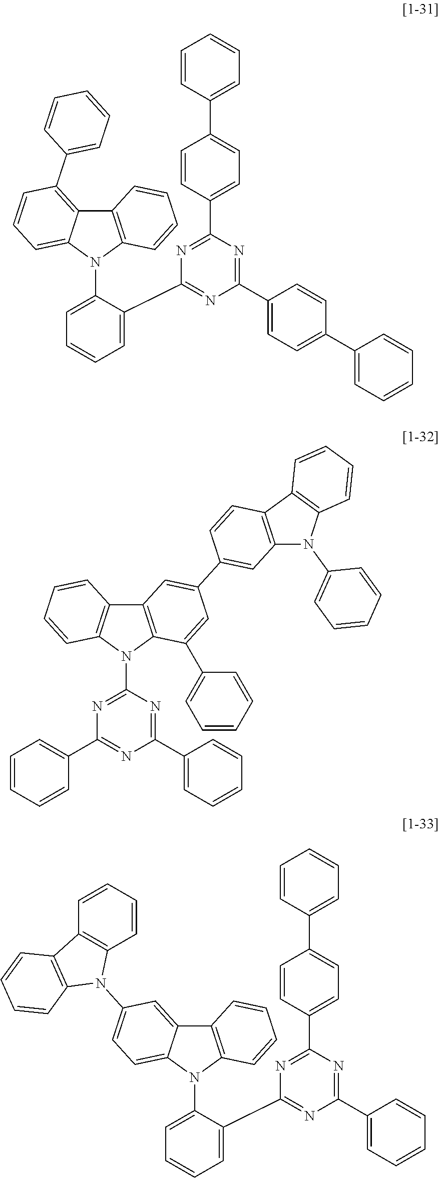 [SMILES: c1ccc(-c2ccc(-c3nc(-c4ccc(-c5ccccc5)cc4)nc(-c4ccccc4-n4c5ccccc5c5c(-c6ccccc6)cccc54)n3)cc2)cc1 ; c1ccc(-c2nc(-c3ccccc3)nc(-n3c4ccccc4c4cc(-c5ccc6c7ccccc7n(-c7ccccc7)c6c5)cc(-c5ccccc5)c43)n2)cc1 ; c1ccc(-c2ccc(-c3nc(-c4ccccc4)nc(-c4ccccc4-n4c5ccccc5c5cc(-n6c7ccccc7c7ccccc76)ccc54)n3)cc2)cc1]

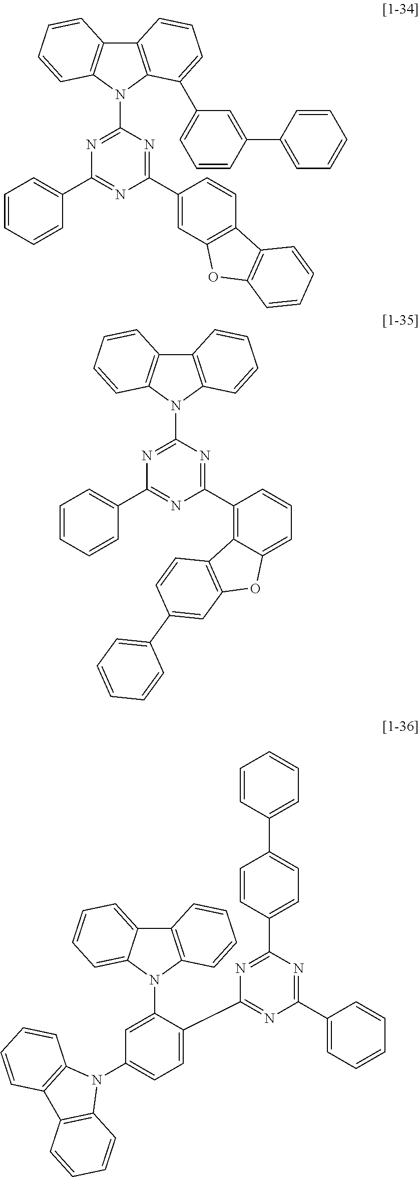

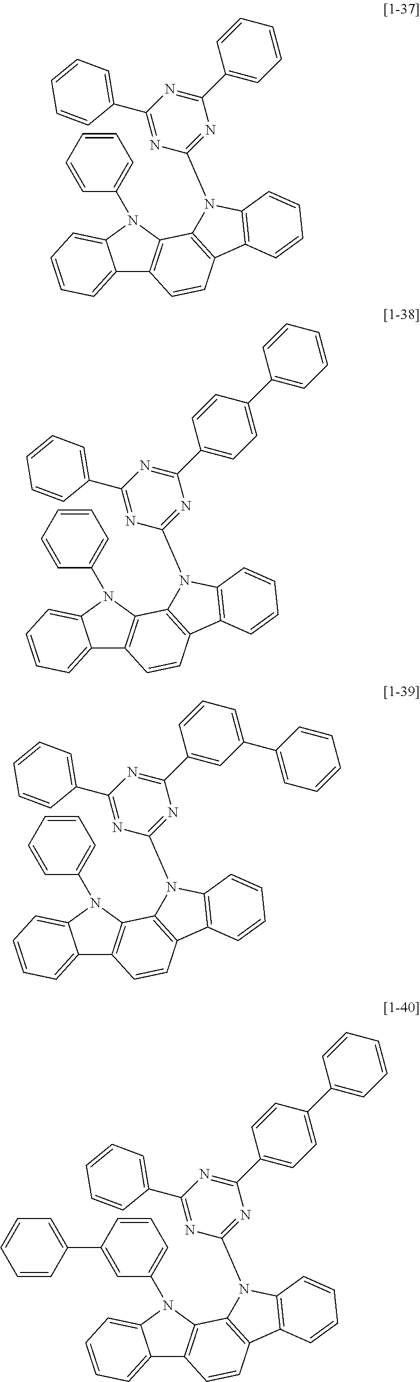

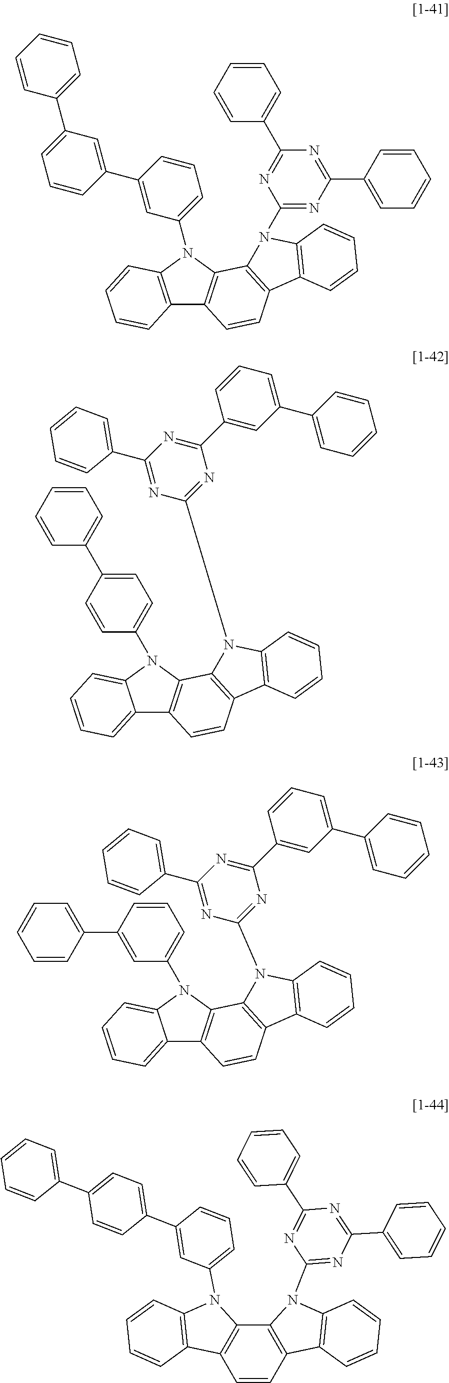

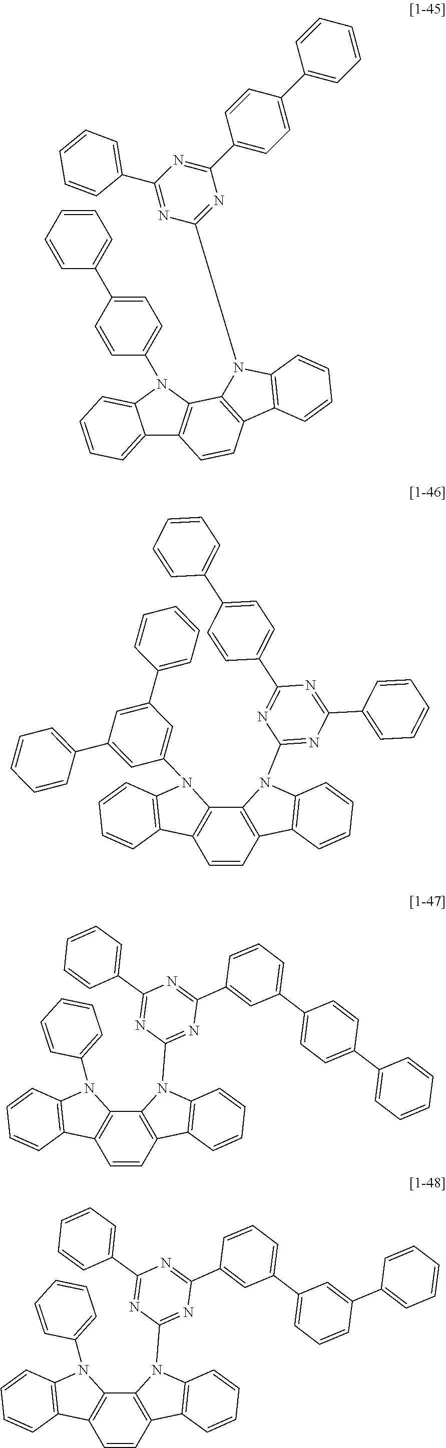

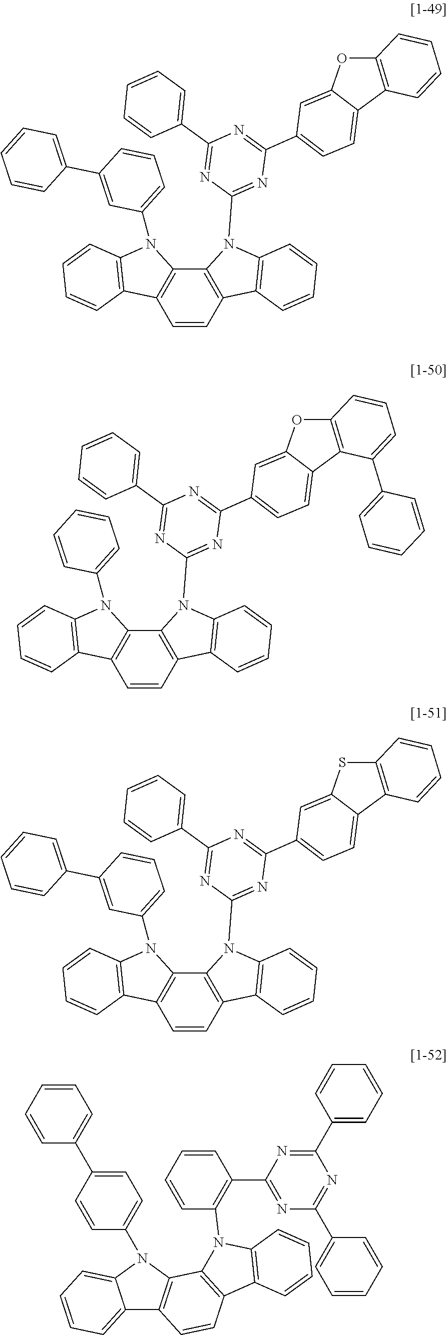 [SMILES: c1ccc(-c2cccc(-n3c4ccccc4c4ccc5c6ccccc6n(-c6nc(-c7ccccc7)nc(-c7ccc8c(c7)oc7ccccc78)n6)c5c43)c2)cc1 ; c1ccc(-c2nc(-c3ccc4c(c3)oc3cccc(-c5ccccc5)c34)nc(-n3c4ccccc4c4ccc5c6ccccc6n(-c6ccccc6)c5c43)n2)cc1 ; c1ccc(-c2cccc(-n3c4ccccc4c4ccc5c6ccccc6n(-c6nc(-c7ccccc7)nc(-c7ccc8c(c7)sc7ccccc78)n6)c5c43)c2)cc1 ; c1ccc(-c2ccc(-n3c4ccccc4c4ccc5c6ccccc6n(-c6ccccc6-c6nc(-c7ccccc7)nc(-c7ccccc7)n6)c5c43)cc2)cc1]

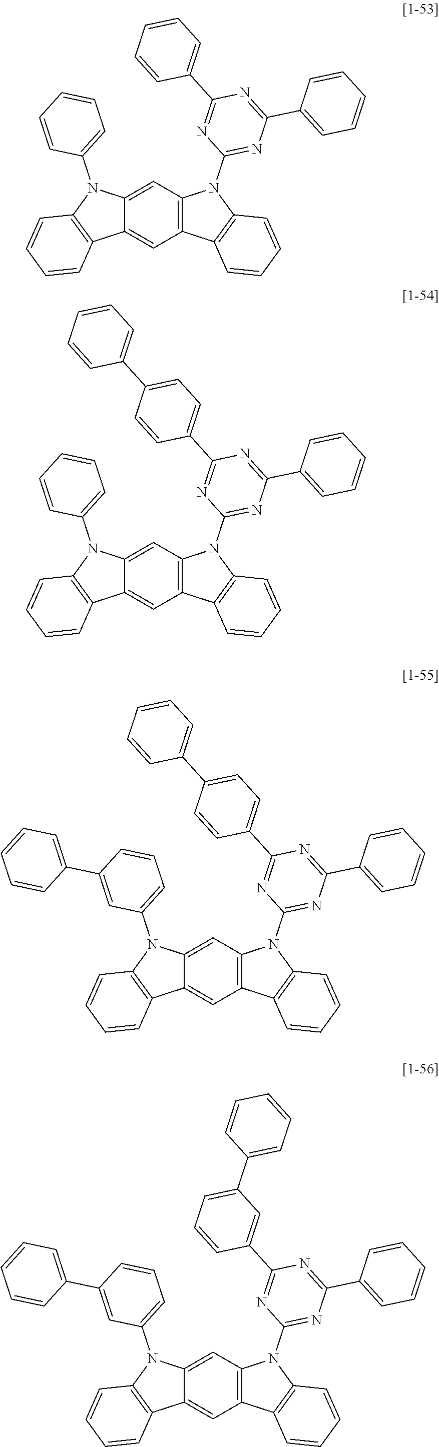

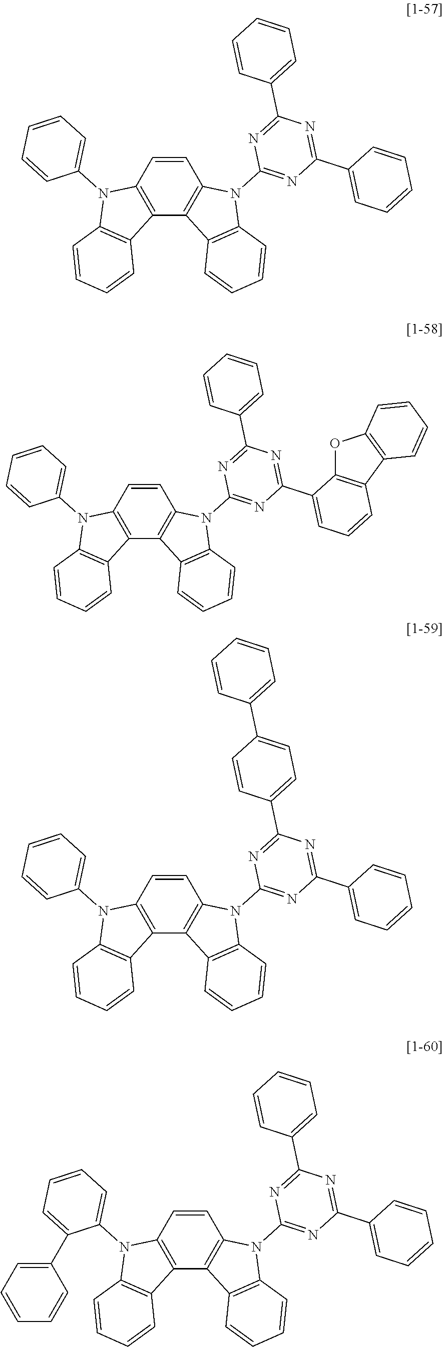

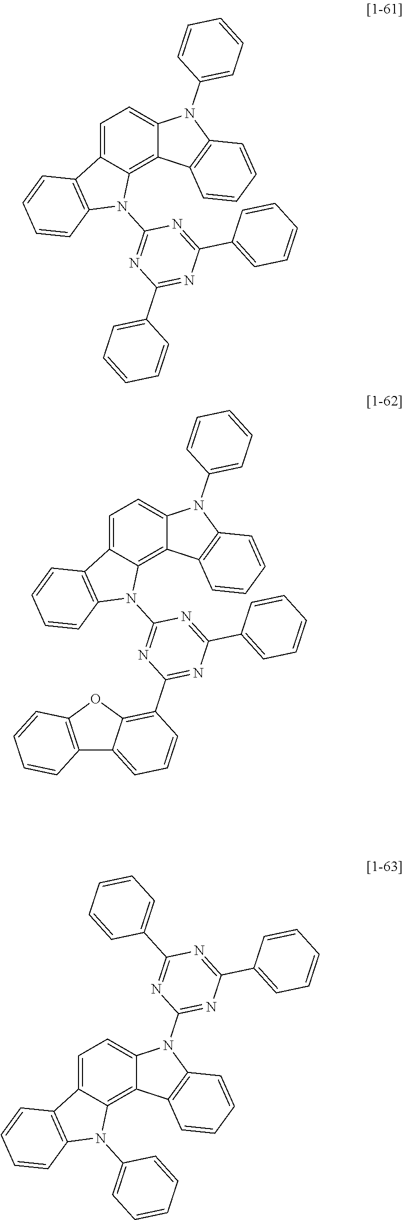 [SMILES: c1ccc(-c2nc(-c3ccccc3)nc(-n3c4ccccc4c4ccc5c(c6ccccc6n5-c5ccccc5)c43)n2)cc1 ; c1ccc(-c2nc(-c3cccc4c3oc3ccccc34)nc(-n3c4ccccc4c4ccc5c(c6ccccc6n5-c5ccccc5)c43)n2)cc1 ; c1ccc(-c2nc(-c3ccccc3)nc(-n3c4ccccc4c4c3ccc3c5ccccc5n(-c5ccccc5)c34)n2)cc1]

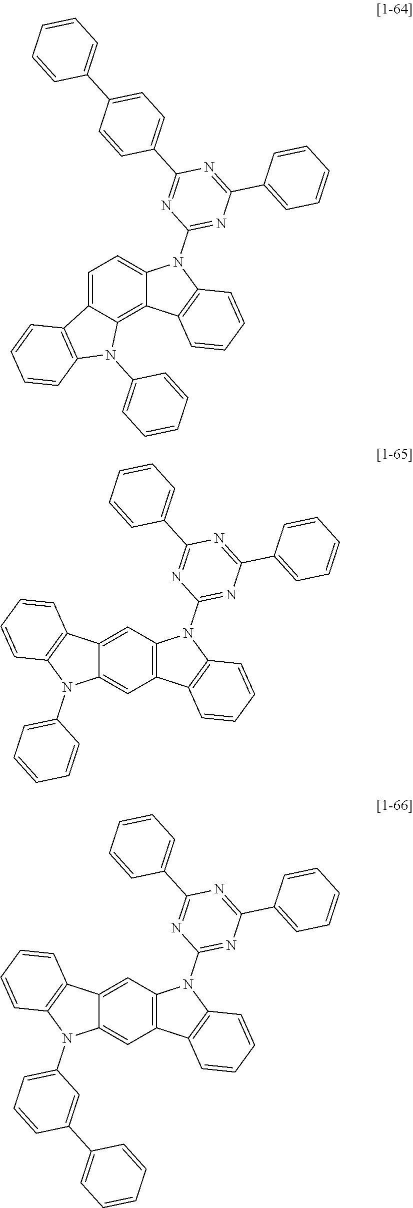

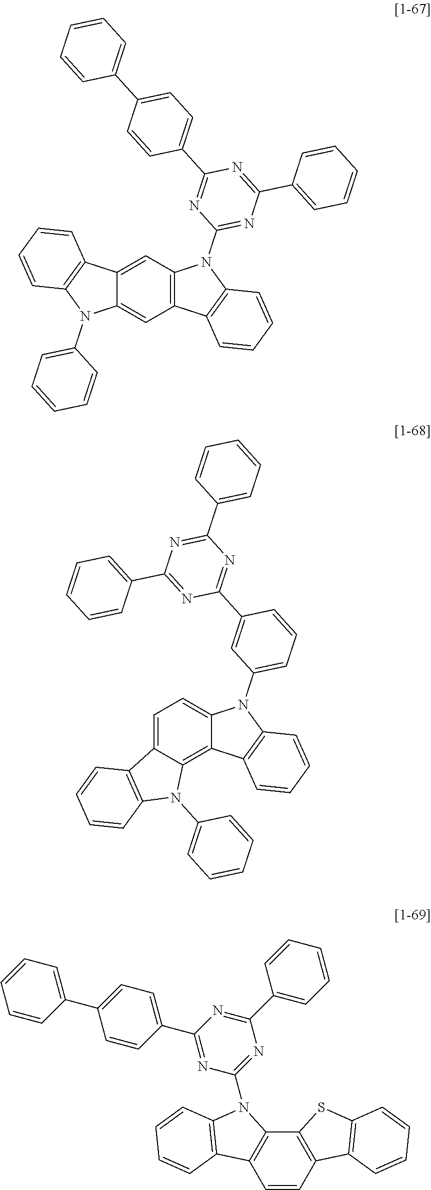 [SMILES: c1ccc(-c2ccc(-c3nc(-c4ccccc4)nc(-n4c5ccccc5c5cc6c(cc54)c4ccccc4n6-c4ccccc4)n3)cc2)cc1 ; c1ccc(-c2nc(-c3ccccc3)nc(-c3cccc(-n4c5ccccc5c5c4ccc4c6ccccc6n(-c6ccccc6)c45)c3)n2)cc1 ; c1ccc(-c2ccc(-c3nc(-c4ccccc4)nc(-n4c5ccccc5c5ccc6c7ccccc7sc6c54)n3)cc2)cc1]

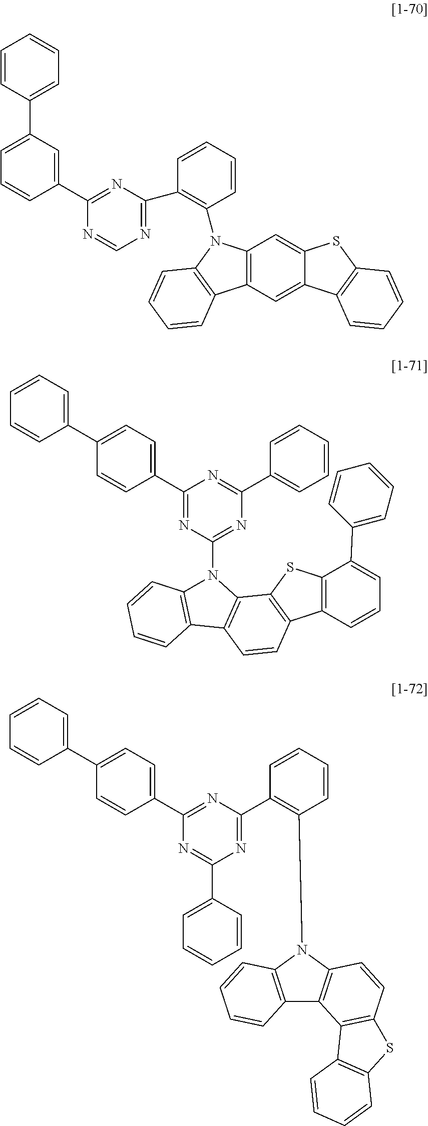 [SMILES: c1ccc(-c2cccc(-c3ncnc(-c4ccccc4-n4c5ccccc5c5cc6c(cc54)sc4ccccc46)n3)c2)cc1 ; c1ccc(-c2ccc(-c3nc(-c4ccccc4)nc(-n4c5ccccc5c5ccc6c7cccc(-c8ccccc8)c7sc6c54)n3)cc2)cc1 ; c1ccc(-c2ccc(-c3nc(-c4ccccc4)nc(-c4ccccc4-n4c5ccccc5c5c6c(ccc54)sc4ccccc46)n3)cc2)cc1]

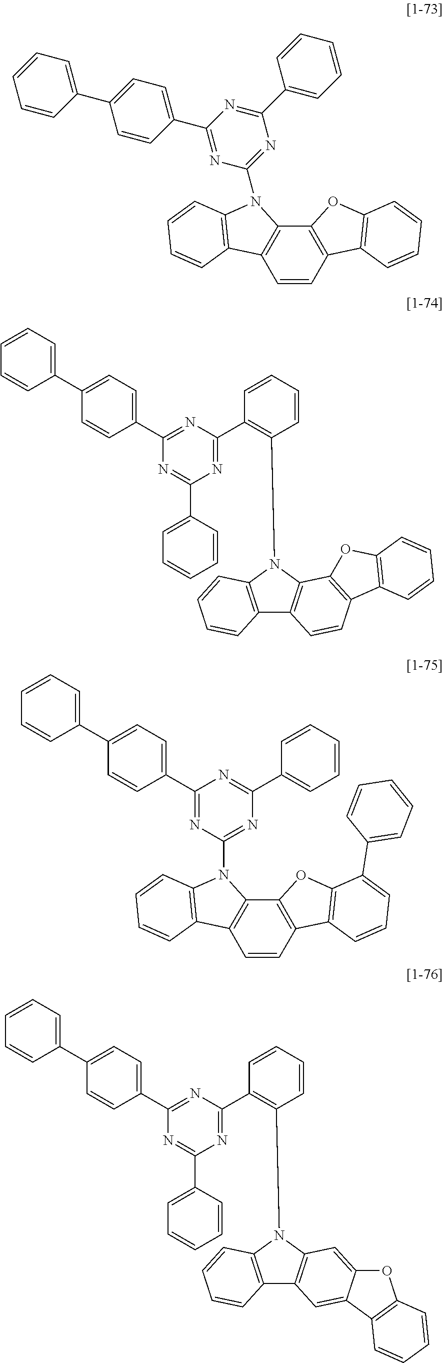 [SMILES: c1ccc(-c2ccc(-c3nc(-c4ccccc4)nc(-n4c5ccccc5c5ccc6c7ccccc7oc6c54)n3)cc2)cc1 ; c1ccc(-c2ccc(-c3nc(-c4ccccc4)nc(-c4ccccc4-n4c5ccccc5c5ccc6c7ccccc7oc6c54)n3)cc2)cc1 ; c1ccc(-c2ccc(-c3nc(-c4ccccc4)nc(-n4c5ccccc5c5ccc6c7cccc(-c8ccccc8)c7oc6c54)n3)cc2)cc1 ; c1ccc(-c2ccc(-c3nc(-c4ccccc4)nc(-c4ccccc4-n4c5ccccc5c5cc6c(cc54)oc4ccccc46)n3)cc2)cc1]

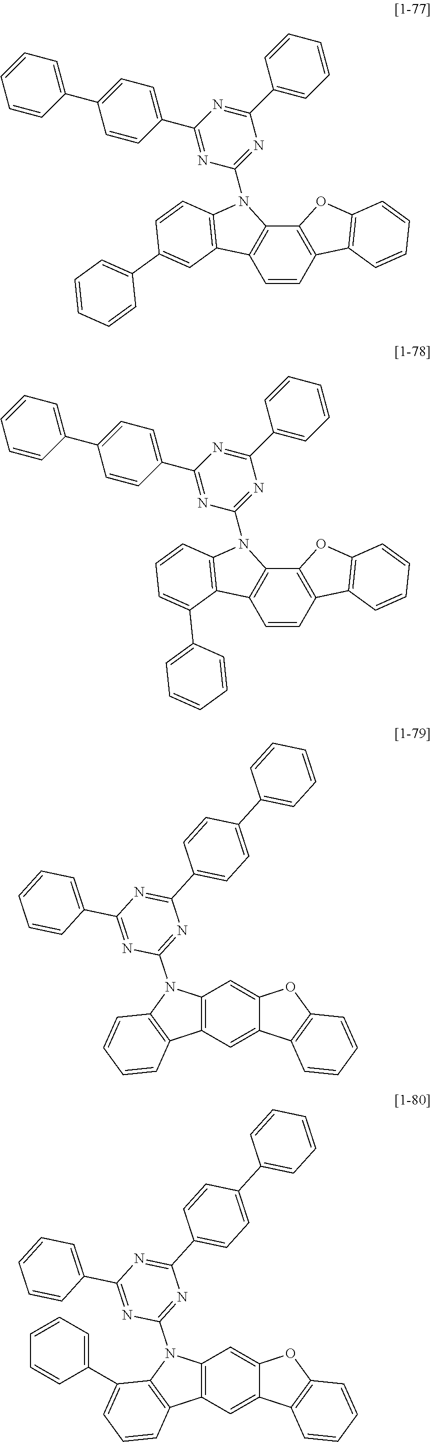

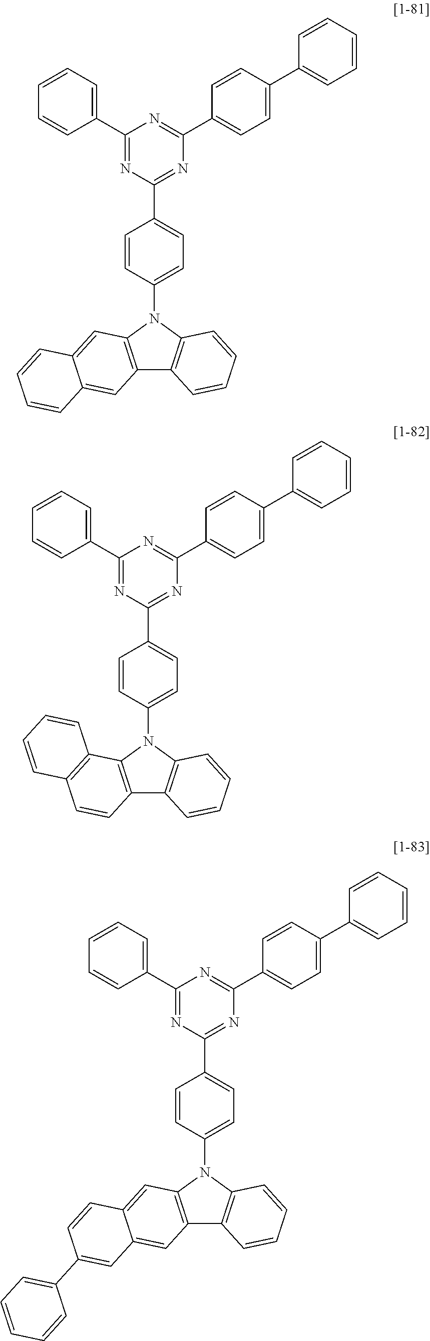 [SMILES: c1ccc(-c2ccc(-c3nc(-c4ccccc4)nc(-c4ccc(-n5c6ccccc6c6cc7ccccc7cc65)cc4)n3)cc2)cc1 ; c1ccc(-c2ccc(-c3nc(-c4ccccc4)nc(-c4ccc(-n5c6ccccc6c6ccc7ccccc7c65)cc4)n3)cc2)cc1 ; c1ccc(-c2ccc(-c3nc(-c4ccccc4)nc(-c4ccc(-n5c6ccccc6c6cc7cc(-c8ccccc8)ccc7cc65)cc4)n3)cc2)cc1]

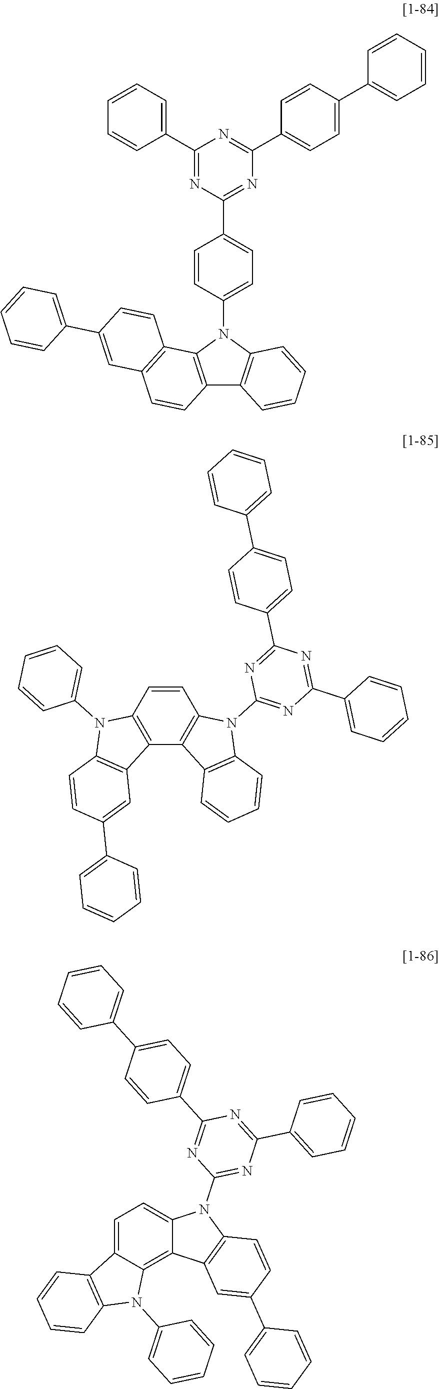

The second compound having the hole characteristics has a structure in which carbazole or a carbazole derivative is substituted with a substituted or unsubstituted C6 to C30 aryl group, or a substituted or unsubstituted C2 to C30 heterocyclic group, and may be represented by, for example, Chemical Formula 2 or a combination of Chemical Formula 3 and Chemical Formula 4. [Chemical Formula 2]

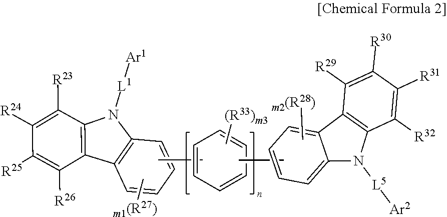

In Chemical Formula 2,
Ar¹ and Ar² are each independently a substituted or unsubstituted C6 to C30 aryl group or a substituted or unsubstituted C2 to C30 heterocyclic group,
L⁴ and L⁵ are each independently a single bond or a substituted or unsubstituted C6 to C20 arylene group,
R²³ to R³³ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group,
m1 and m2 are each independently one of integers of 1 to 3,
m3 is one of integers of 1 to 4, and
n is one of integers of 0 to 2;

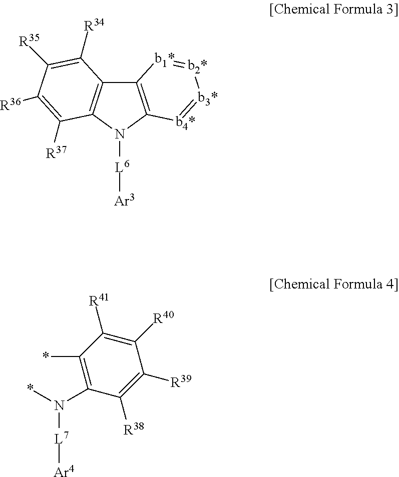

wherein, in Chemical Formulas 3 and 4,
Ar³ and Ar⁴ are each independently a substituted or unsubstituted C6 to C30 aryl group or a substituted or unsubstituted C2 to C30 heterocyclic group,
among b₁* to b₄* in Chemical Formula 3, two adjacent ones are each a linking carbon (C) that is linked to * in Chemical Formula 4,
among b₁* to b₄* in Chemical Formula 3, the remaining two that are not linked to * in Chemical Formula 4 are each independently C-L^{b}-R^{c},
L^{b}, L⁶, and L⁷ are each independently a single bond or a substituted or unsubstituted C6 to C20 arylene group, and
R^{c} and R³⁴ to R⁴¹ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group.

For example, in Chemical Formula 2, Ar¹ and Ar² may each independently be a substituted or unsubstituted C6 to C20 aryl group, or a substituted or unsubstituted C2 to C20 heterocyclic group.

For example, in Chemical Formula 2, Ar¹ and Ar² may each independently be a substituted or unsubstituted C6 to C20 aryl group, or a substituted or unsubstituted C2 to C20 heterocyclic group, provided that at least one of Ar¹ and Ar² may be a C6 to C20 aryl group substituted with one or more deuterium or a C2 to C20 heterocyclic group substituted with one or more deuterium.

For example, in Chemical Formula 2, R²³ to R³³ may each independently be hydrogen, deuterium, a cyano group, a halogen, a substituted or unsubstituted amine group, a substituted or unsubstituted C1 to C10 alkyl group, a substituted or unsubstituted C6 to C20 aryl group, or a substituted or unsubstituted C2 to C20 heterocyclic group.

For example, in Chemical Formula 2, R²³ to R³³ may each independently be hydrogen, deuterium, a cyano group, a halogen, a substituted or unsubstituted amine group, a substituted or unsubstituted C1 to C10 alkyl group, a substituted or unsubstituted C6 to C20 aryl group, or a substituted or unsubstituted C2 to C20 heterocyclic group, provided at least one of R²³ to R³³ may be deuterium, a C1 to C10 alkyl group substituted with one or more deuterium, a C6 to C20 aryl group substituted with one or more deuterium, or a C2 to C20 heterocyclic group substituted with one or more deuterium.

For example, in Chemical Formula 2, at least one of Ar¹ and Ar² may be a C6 to C20 aryl group substituted with one or more deuterium, or a C2 to C20 heterocyclic group substituted with one or more deuterium, and at least one of R²³ to R³³ may be deuterium, a C1 to C10 alkyl group substituted with one or more deuterium, a C6 to C20 aryl group substituted with one or more deuterium, or a C2 to C20 heterocyclic group substituted with one or more deuterium.

For specific example, in Chemical Formula 2, Ar¹ and Ar² may each independently be a substituted or unsubstituted C6 to C20 aryl group, a substituted or unsubstituted dibenzofuranyl group, a substituted or unsubstituted dibenzothiophenyl group, or a substituted or unsubstituted carbazolyl group.

For specific example, in Chemical Formula 2, Ar¹ and Ar² may each independently be a substituted or unsubstituted C6 to C20 aryl group, a substituted or unsubstituted dibenzofuranyl group, a substituted or unsubstituted dibenzothiophenyl group, or a substituted or unsubstituted carbazolyl group, provided that at least one of Ar¹ and Ar² may be a C6 to C20 aryl group substituted with one or more deuterium, a dibenzofuranyl group substituted with one or more deuterium, a dibenzothiophenyl group substituted with one or more deuterium, or a carbazolyl group substituted with one or more deuterium.

For specific example, in Chemical Formula 2, at least one of Ar¹ and Ar² may be a C6 to C20 aryl group substituted with one or more deuterium, a dibenzofuranyl group substituted with one or more deuterium, a dibenzothiophenyl group substituted with one or more deuterium, or a carbazolyl group substituted with one or more deuterium, and at least one of R²³ to R³³ may be deuterium, a C1 to C10 alkyl group substituted with one or more deuterium, a C6 to C20 aryl group substituted with one or more deuterium, or a C2 to C20 heterocyclic group substituted with one or more deuterium.

For example, in Chemical Formula 3 and Chemical Formula 4, Ar³ and Ar⁴ may each independently be a substituted or unsubstituted C6 to C20 aryl group, or a substituted or unsubstituted C2 to C20 heterocyclic group.

For example, in Chemical Formula 3 and Chemical Formula 4, Ar³ and Ar⁴ may each independently be a substituted or unsubstituted C6 to C20 aryl group, or a substituted or unsubstituted C2 to C20 heterocyclic group, provided that at least one of Ar³ and Ar⁴ may be a C6 to C20 aryl group substituted with one or more deuterium, or a C2 to C20 heterocyclic group substituted with one or more deuterium.

For example, in Chemical Formula 3 and Chemical Formula 4, R^{c} and R³⁴ to R⁴¹ may each independently be hydrogen, deuterium, a cyano group, a halogen, a substituted or unsubstituted amine group, a substituted or unsubstituted C1 to C10 alkyl group, a substituted or unsubstituted C6 to C20 aryl group, or a substituted or unsubstituted C2 to C20 heterocyclic group.

For example, in Chemical Formula 3 and Chemical Formula 4, R^{c} and R³⁴ to R⁴¹ may each independently be hydrogen, deuterium, a cyano group, a halogen, a substituted or unsubstituted amine group, a substituted or unsubstituted C1 to C10 alkyl group, a substituted or unsubstituted C6 to C20 aryl group, or a substituted or unsubstituted C2 to C20 heterocyclic group, provided that at least one of R^{c} and R³⁴ to R⁴¹ may be deuterium, a C1 to C10 alkyl group substituted with one or more deuterium, a C6 to C20 aryl group substituted with one or more deuterium, or a C2 to C20 heterocyclic group substituted with one or more deuterium.

For example, in Chemical Formula 3 and Chemical Formula 4, at least one of Ar³ and Ar⁴ may be a C6 to C20 aryl group substituted with one or more deuterium, or a C2 to C20 heterocyclic group substituted with one or more deuterium, and at least one of R^{c} and R³⁴ to R⁴¹ may be deuterium, a C1 to C10 alkyl group substituted with one or more deuterium, a C6 to C20 aryl group substituted with one or more deuterium, or a C2 to C20 heterocyclic group substituted with one or more deuterium.

For specific example, in Chemical Formula 3 and Chemical Formula 4, Ar³ and Ar⁴ are each independently a substituted or unsubstituted C6 to C20 aryl group, a substituted or unsubstituted dibenzofuranyl group, a substituted or unsubstituted dibenzothiophenyl group, or a substituted or unsubstituted carbazolyl group.

For specific example, in Chemical Formula 3 and Chemical Formula 4, Ar³ and Ar⁴ may each independently be a substituted or unsubstituted C6 to C20 aryl group, a substituted or unsubstituted dibenzofuranyl group, a substituted or unsubstituted dibenzothiophenyl group, or a substituted or unsubstituted carbazolyl group, provided that at least one of Ar³ and Ar⁴ may be a C6 to C20 aryl group substituted with one or more deuterium, a dibenzofuranyl group substituted with one or more deuterium, a dibenzothiophenyl group substituted with one or more deuterium, or a carbazolyl group substituted with one or more deuterium.

For specific example, in Chemical Formula 3 and Chemical Formula 4, at least one of Ar³ and Ar⁴ may be a C6 to C20 aryl group substituted with one or more deuterium, a dibenzofuranyl group substituted with one or more deuterium, a dibenzothiophenyl group substituted with one or more deuterium, or a carbazolyl group substituted with one or more deuterium, and at least one of R^{c} and R³⁴ to R⁴¹ may be deuterium, a C1 to C10 alkyl group substituted with one or more deuterium, a C6 to C20 aryl group substituted with one or more deuterium, or a C2 to C20 heterocyclic group substituted with one or more deuterium.

For more specific example, in Chemical Formula 2, Ar¹ and Ar² may each independently be a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylenyl group, a substituted or unsubstituted carbazolyl group, a substituted or unsubstituted dibenzothiophenyl group, a substituted or unsubstituted dibenzofuranyl group, or a substituted or unsubstituted fluorenyl group,
in Chemical Formula 2, L⁴ and L⁵ may each independently be a single bond, a substituted or unsubstituted phenylene group, a substituted or unsubstituted biphenylene group, or a substituted or unsubstituted naphthalenylene group,
in Chemical Formula 2, R²³ to R³³ may each independently be hydrogen, deuterium, a substituted or unsubstituted C6 to C12 aryl group, a substituted or unsubstituted carbazolyl group, a substituted or unsubstituted dibenzofuranyl group, or a substituted or unsubstituted dibenzothiophenyl group, and
n may be 0 or 1.

For example, in Chemical Formula 2, Ar¹ and Ar² may each independently be a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylenyl group, a substituted or unsubstituted carbazolyl group, a substituted or unsubstituted dibenzothiophenyl group, a substituted or unsubstituted dibenzofuranyl group, or a substituted or unsubstituted fluorenyl group, and

at least one of Ar¹ and Ar² may be a phenyl group substituted with one or more deuterium, a biphenyl group substituted with one or more deuterium, a terphenyl group substituted with one or more deuterium, a naphthyl group substituted with one or more deuterium, an anthracenyl group substituted with one or more deuterium, one or more substituted or unsubstituted phenanthrenyl group, a triphenylenyl group substituted with one or more deuterium, a carbazolyl group substituted with one or more deuterium, a dibenzothiophenyl group substituted with one or more deuterium, a dibenzofuranyl group substituted with one or more deuterium, or a fluorenyl group substituted with one or more deuterium.

For example, in Chemical Formula 2, R²³ to R³³ may each independently be hydrogen, deuterium, a substituted or unsubstituted C6 to C12 aryl group, a substituted or unsubstituted carbazolyl group, a substituted or unsubstituted dibenzofuranyl group, or a substituted or unsubstituted dibenzothiophenyl group, and at least one of R²³ to R³³ may be deuterium, a C6 to C12 aryl group substituted with one or more deuterium, a carbazolyl group substituted with one or more deuterium, a dibenzofuranyl group substituted with one or more deuterium, or a dibenzothiophenyl group substituted with one or more deuterium.

For example, in Chemical Formula 2, at least one of Ar¹ and Ar² may be a phenyl group substituted with one or more deuterium, a biphenyl group substituted with one or more deuterium, a terphenyl group substituted with one or more deuterium, a naphthyl group substituted with one or more deuterium, an anthracenyl group substituted with one or more deuterium, a phenanthrenyl group substituted with one or more deuterium, a triphenylenyl group substituted with one or more deuterium, a carbazolyl group substituted with one or more deuterium, a dibenzothiophenyl group substituted with one or more deuterium, a dibenzofuranyl group substituted with one or more deuterium, or a fluorenyl group substituted with one or more deuterium, and
in Chemical Formula 2, at least one of R²³ to R³³ may be deuterium, a C6 to C12 aryl group substituted with one or more deuterium, a carbazolyl group substituted with one or more deuterium, a dibenzofuranyl group substituted with one or more deuterium, or a dibenzothiophenyl group substituted with one or more deuterium.

For example, in Chemical Formula 2, “substituted” refers to replacement of at least one hydrogen by deuterium, a C1 to C4 alkyl group, a C6 to C18 aryl group, or a C2 to C30 heteroaryl group.

In a specific embodiment of the present invention, Chemical Formula 2 may be represented by one of Chemical Formula 2-1 to Chemical Formula 2-15.

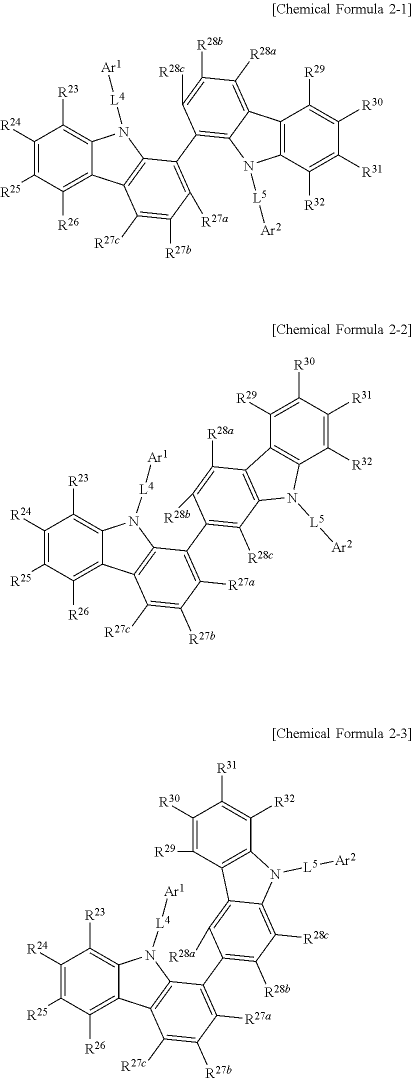

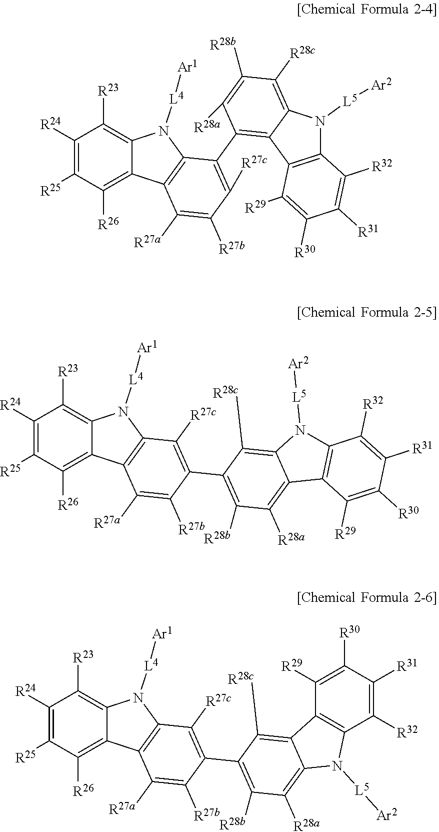

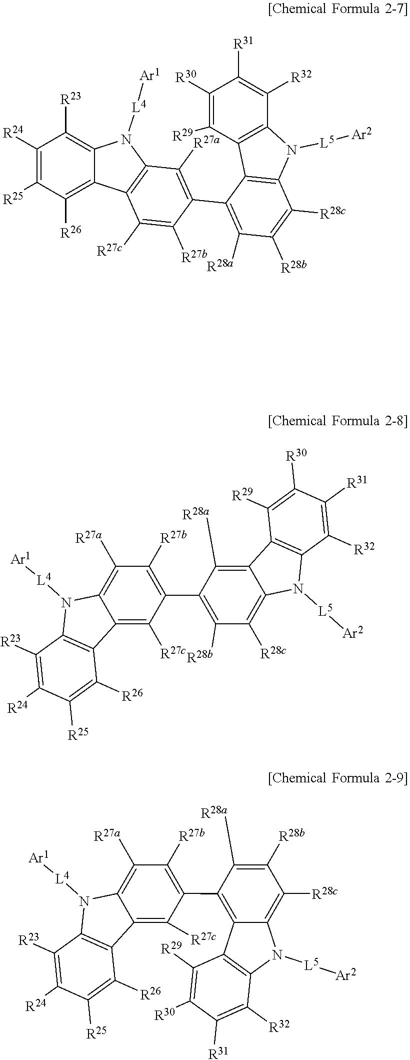

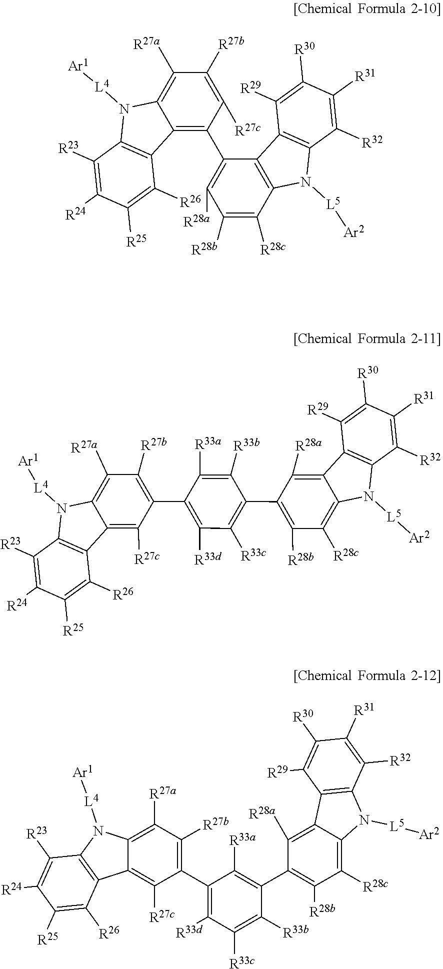

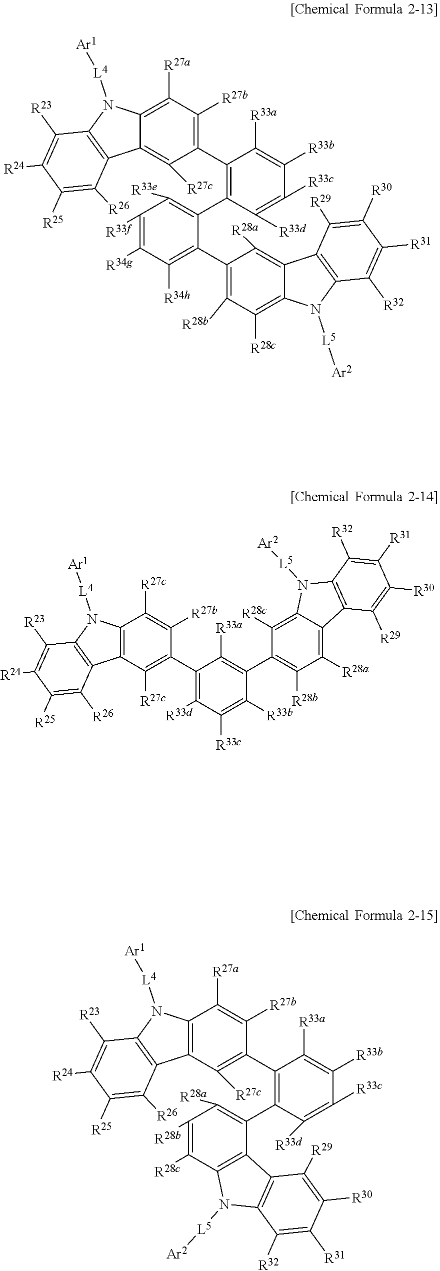

In Chemical Formula 2-1 to Chemical Formula 2-15, R²³ to R²⁶, R^{27a}, R^{27b}, R²⁷, R^{28a}, R^{28b}, R^{28c}, R²⁹ to R³², R^{33a}, R^{33b}, R^{33c}, R^{33d}, R^{33c}, R^{33f}, R^{33g}, and R^{33h} may each independently be hydrogen, deuterium, a substituted or unsubstituted C6 to C12 aryl group, a substituted or unsubstituted carbazolyl group, a substituted or unsubstituted dibenzofuranyl group, or a substituted or unsubstituted dibenzothiophenyl group, and *-L⁴-Ar¹ and *-L⁵-Ar² may each independently be one of the substituents listed in Group II.

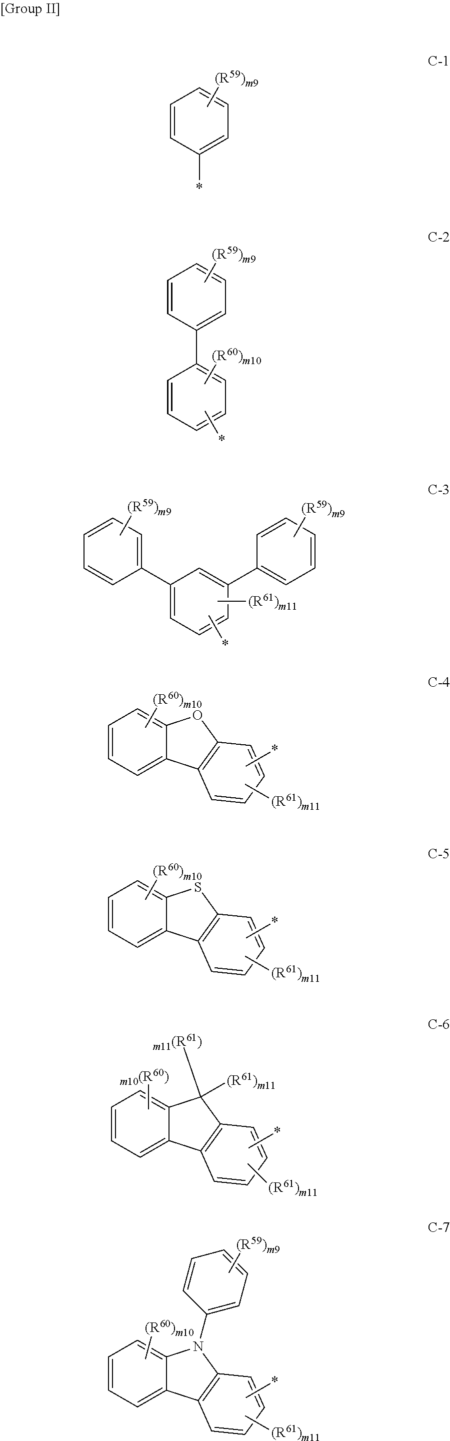

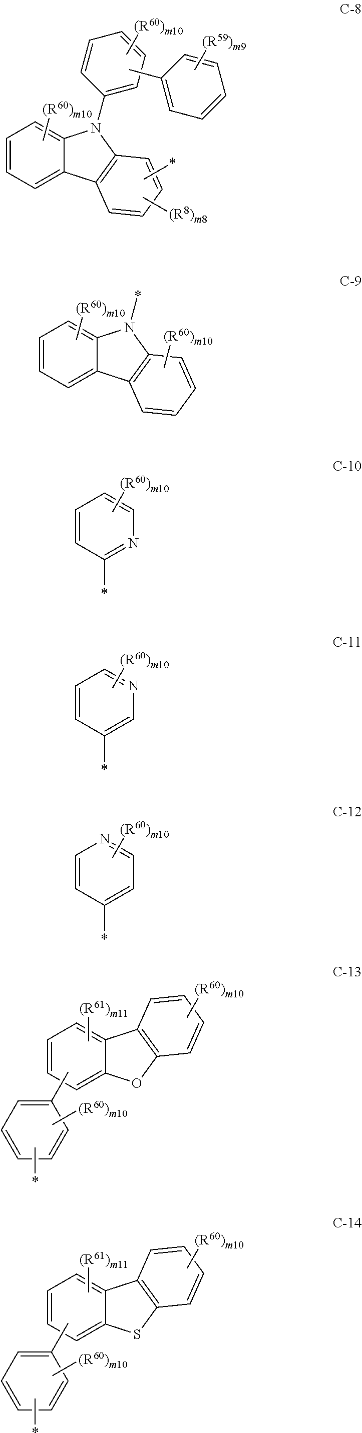

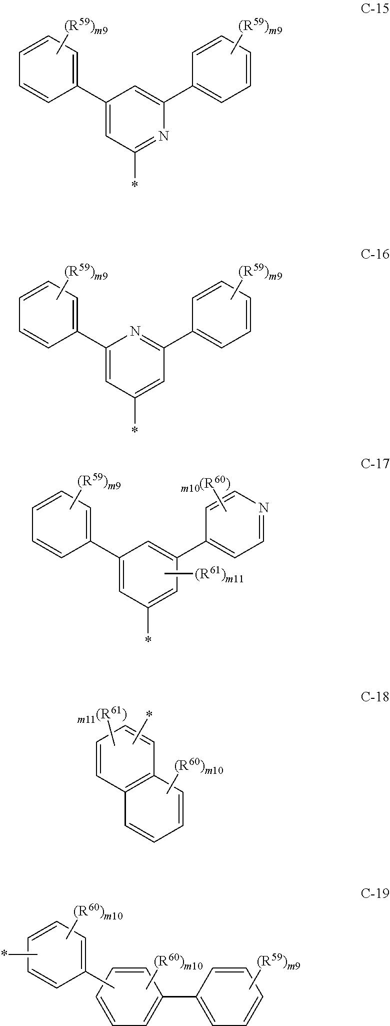

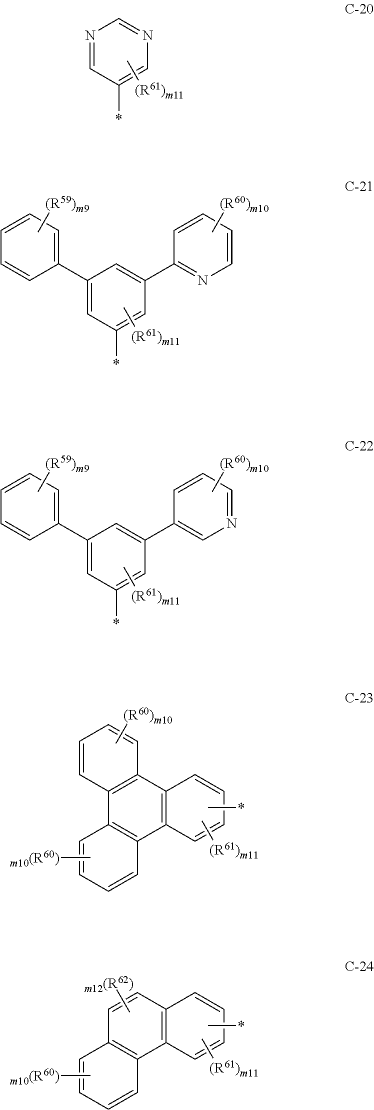

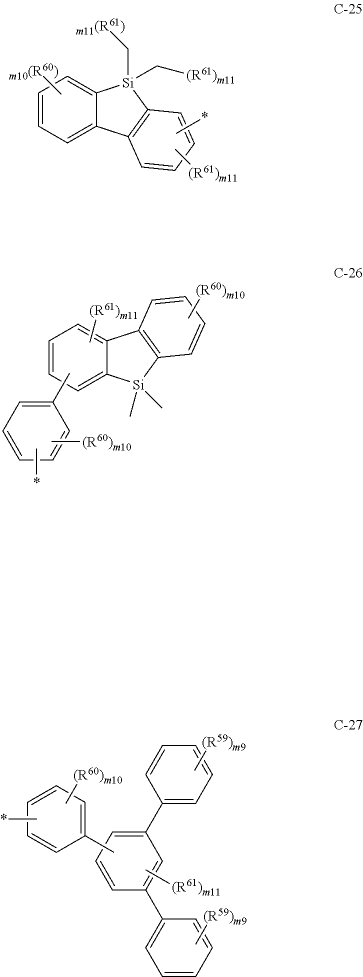

### In Group II

R⁵⁹ to R⁶² are each independently hydrogen, deuterium, a C1 to C4 alkyl group, a C6 to
C18 aryl group, or a C2 to C30 heteroaryl group,
m9 is one of integers of 1 to 5,
m10 is one of integers of 1 to 4,
m11 is one of integers of 1 to 3,
m12 is an integer of 1 or 2, and
* is a linking point.

In an embodiment, Chemical Formula 2 may be represented by Chemical Formula 2-8.

In addition, in Chemical Formula 2-8*-L⁴-Ar¹ and *-L⁵-Ar² may each independently be selected from Group II, and may be, for example, any one of C-1, C-2, C-3, C-4, C-7, C-8, and C-9.

For example, the second compound represented by the combination of Chemical Formula 3 and Chemical Formula 4 may be represented by any one of Chemical Formula Chemical Formula 3A, Chemical Formula 3B, Chemical Formula 3C, Chemical Formula 3D, and Chemical Formula 3E.

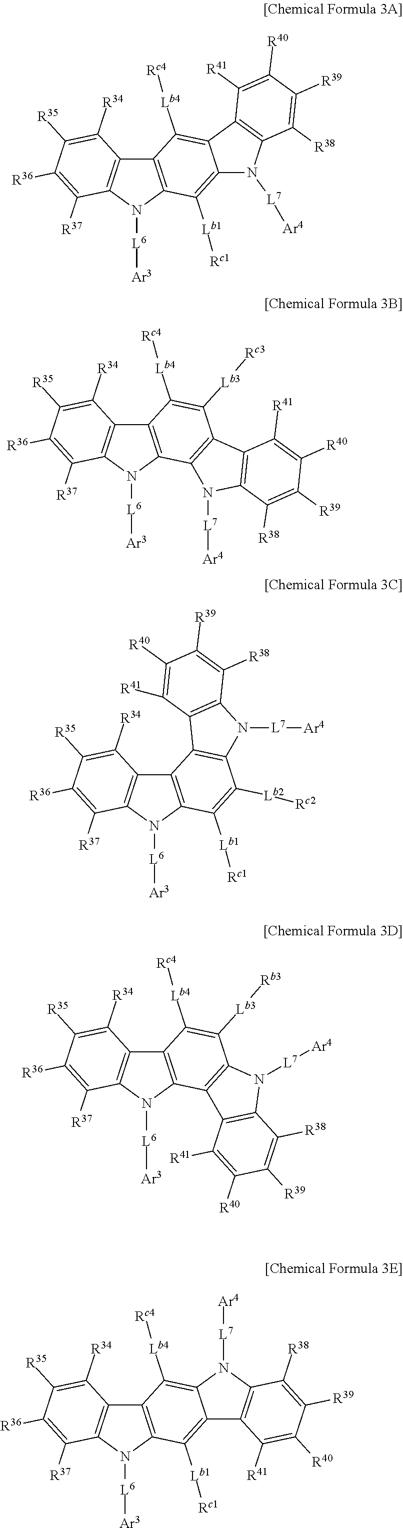

In Chemical Formula 3A to Chemical Formula 3E, Ar³, Ar⁴, L⁶, L⁷, and R³⁴ to R⁴¹ are the same as described above,
L^{b1} to L^{b4} are defined as L⁶ and L⁷ described above, and
R^{c1} to R^{c4} are defined as R³⁴ to R⁴¹ described above.

For example, in Chemical Formulas 3 and 4, Ar³ and Ar⁴ may each independently be a substituted or unsubstituted phenyl group, a substituted or unsubstituted biphenyl group, a substituted or unsubstituted naphthyl group, a substituted or unsubstituted triphenylene group, a substituted or unsubstituted carbazolyl group, a substituted or unsubstituted dibenzofuranyl group, or a substituted or unsubstituted dibenzothiophenyl group, and

R^{c1} to R^{c4} and R³⁴ to R⁴¹ may each independently be hydrogen, deuterium, a cyano group, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

In a specific embodiment of the present invention, in Chemical Formulas 3 and 4, *-L⁶-Ar³ and *-L⁷-Ar⁴ may each independently be selected from the substituents listed in Group II.

In an embodiment, R^{c1} to R^{c4} and R³⁴ to R⁴¹ may each independently be hydrogen, deuterium, a cyano group, a substituted or unsubstituted phenyl group, a substituted or unsubstituted biphenyl group, a substituted or unsubstituted naphthyl group, a substituted or unsubstituted triphenylene group, a substituted or unsubstituted carbazolyl group, a substituted or unsubstituted dibenzofuranyl group, or a substituted or unsubstituted dibenzothiophenyl group.

For example, R^{c1} to R^{c4} and R³⁴ to R⁴¹ may each independently be hydrogen, deuterium, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group, and

in a specific embodiment, R^{c1} to R^{c4} and R³⁴ to R⁴¹ may each independently be hydrogen, deuterium, a phenyl group, a carbazolyl group, a dibenzofuranyl group, or a dibenzothiophenyl group.

For example, in Chemical Formulas 3 and 4, Ar³ and Ar⁴ may each independently be a substituted or unsubstituted phenyl group, a substituted or unsubstituted biphenyl group, a substituted or unsubstituted naphthyl group, a substituted or unsubstituted triphenylene group, a substituted or unsubstituted carbazolyl group, a substituted or unsubstituted dibenzofuranyl group, or a substituted or unsubstituted dibenzothiophenyl group, and

at least one of Ar³ and Ar⁴ may be a phenyl group substituted with one or more deuterium, a biphenyl group substituted with one or more deuterium, a naphthyl group substituted with one or more deuterium, a triphenylene group substituted with one or more deuterium, a carbazolyl group substituted with one or more deuterium, a dibenzofuranyl group substituted with one or more deuterium, or a dibenzothiophenyl group substituted with one or more deuterium.

For example, in Chemical Formulas 3 and 4, R^{c} to R^{c4} and R³⁴ to R⁴¹ may each independently be hydrogen, deuterium, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group, and

at least one of R^{c1} to R^{c4} and R³⁴ to R⁴¹ may be deuterium, a phenyl group substituted with one or more deuterium, a biphenyl group substituted with one or more deuterium, a carbazolyl group substituted with one or more deuterium, a dibenzofuranyl group substituted with one or more deuterium, or a dibenzothiophenyl group substituted with one or more deuterium.

For example, in Chemical Formulas 3 and 4, at least one of Ar³ and Ar⁴ may be a phenyl group substituted with one or more deuterium, a biphenyl group substituted with one or more deuterium, a naphthyl group substituted with one or more deuterium, a triphenylene group substituted with one or more deuterium, a carbazolyl group substituted with one or more deuterium, a dibenzofuranyl group substituted with one or more deuterium, or a dibenzothiophenyl group substituted with one or more deuterium, and

at least one of R^{c1} to R^{c4} and R³⁴ to R⁴¹ may be deuterium, a phenyl group substituted with one or more deuterium, a biphenyl group substituted with one or more deuterium, a carbazolyl group substituted with one or more deuterium, a dibenzofuranyl group substituted with one or more deuterium, or a dibenzothiophenyl group substituted with one or more deuterium.

In a specific embodiment of the present invention, the second compound may be represented by Chemical Formula 2-8, wherein in Chemical Formula 2-8, Ar¹ and Ar² may each independently be a substituted or unsubstituted phenyl group, a substituted or unsubstituted biphenyl group, a substituted or unsubstituted terphenyl group, a substituted or unsubstituted naphthyl group, a substituted or unsubstituted anthracenyl group, a substituted or unsubstituted phenanthrenyl group, a substituted or unsubstituted triphenylenyl group, a substituted or unsubstituted carbazolyl group, a substituted or unsubstituted dibenzothiophenyl group, a substituted or unsubstituted dibenzofuranyl group, or a substituted or unsubstituted fluorenyl group, L⁴ and L⁵ may each independently be a single bond, or a substituted or unsubstituted C6 to C20 arylene group, and R²³ to R³³ may each independently be hydrogen, deuterium, a cyano group, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

In another specific embodiment of the present invention, the second compound may be represented by Chemical Formula 3C, wherein in Chemical Formula 3C, L^{b1} and L^{b2} may be a single bond, L⁶ and L⁷ may each independently be a single bond or a substituted or unsubstituted C6 to C12 arylene group, R^{c1}, R^{d2} and R³⁴ to R⁴¹ may each be hydrogen, deuterium, a phenyl group, a triphenylene group, a carbazolyl group, a dibenzofuranyl group, or a dibenzothiophenyl group, Ar³ and Ar⁴ may each independently be a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

For example, the second compound may be one selected from the compounds listed in Group 2, but is not limited thereto.

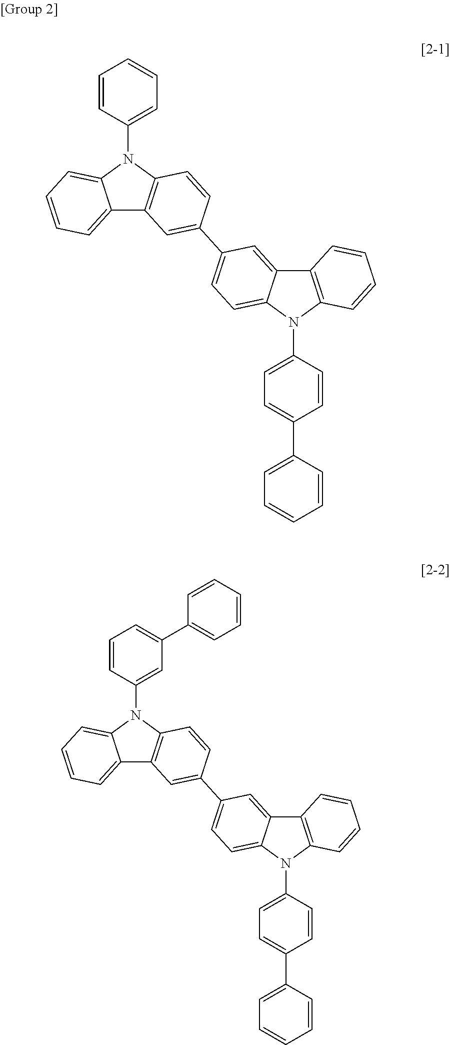 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

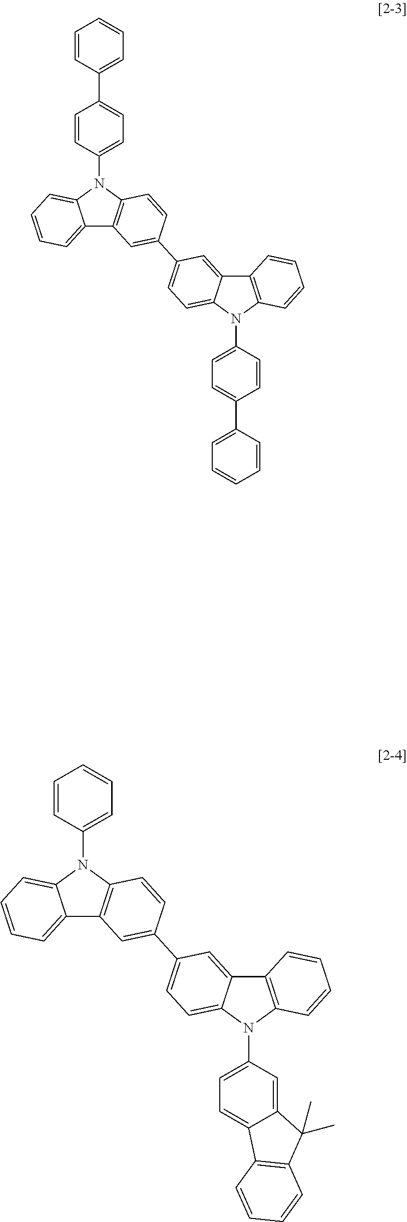 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21]

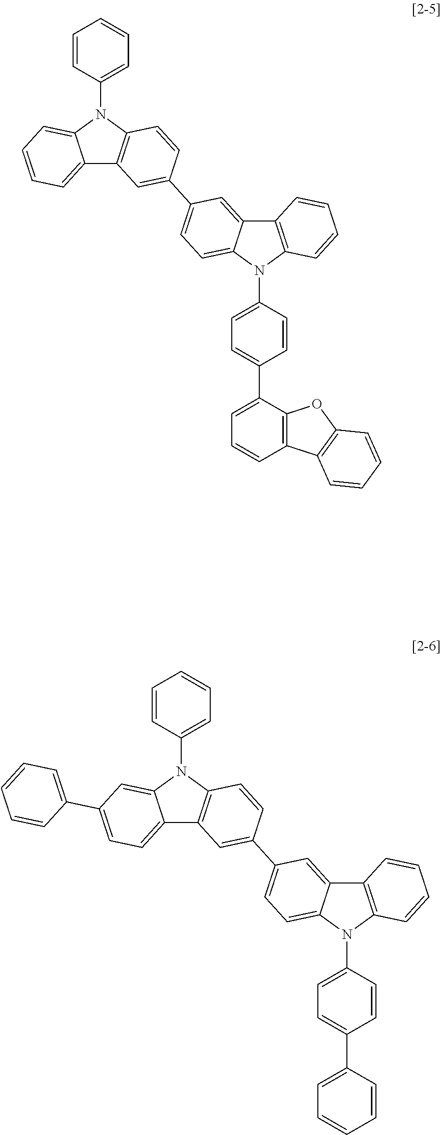 [SMILES: c1ccc(-n2c3ccccc3c3cc(-c4ccc5c(c4)c4ccccc4n5-c4ccc(-c5cccc6c5oc5ccccc56)cc4)ccc32)cc1 ; c1ccc(-c2ccc(-n3c4ccccc4c4cc(-c5ccc6c(c5)c5ccc(-c7ccccc7)cc5n6-c5ccccc5)ccc43)cc2)cc1]

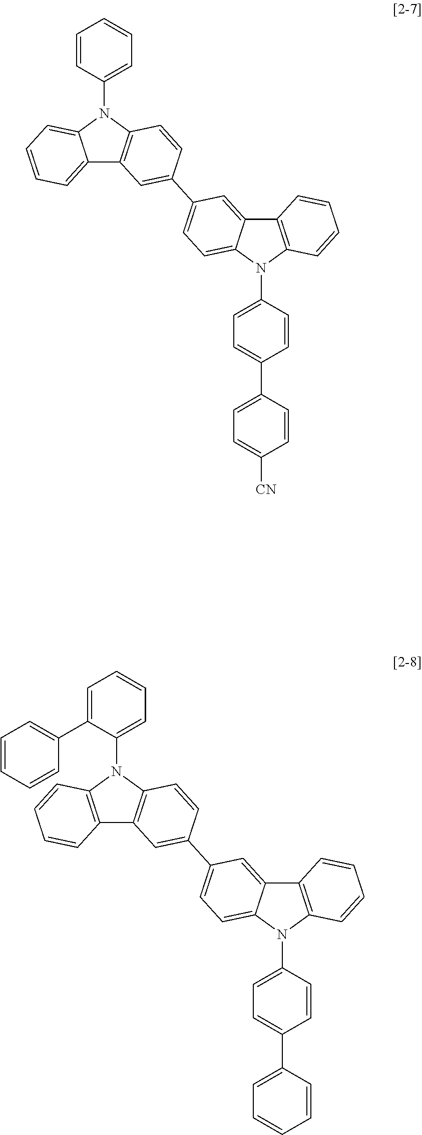 [SMILES: N#Cc1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1]

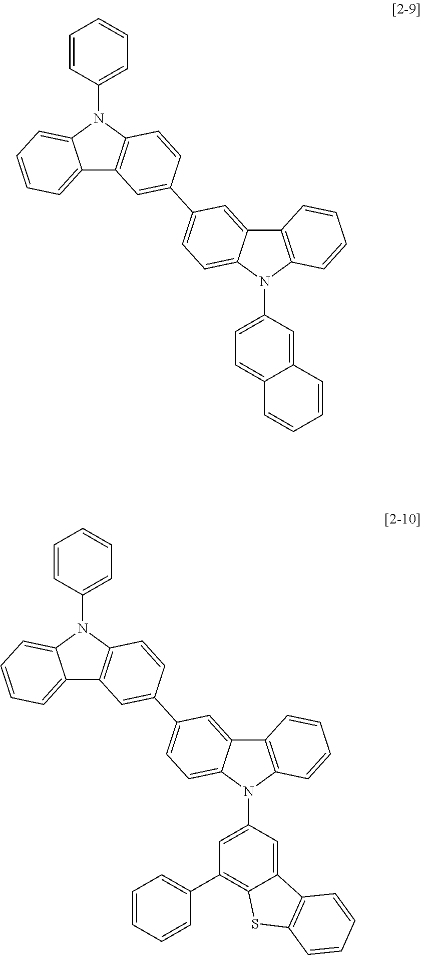 [SMILES: c1ccc(-n2c3ccccc3c3cc(-c4ccc5c(c4)c4ccccc4n5-c4ccc5ccccc5c4)ccc32)cc1 ; c1ccc(-c2cc(-n3c4ccccc4c4cc(-c5ccc6c(c5)c5ccccc5n6-c5ccccc5)ccc43)cc3c2sc2ccccc23)cc1]

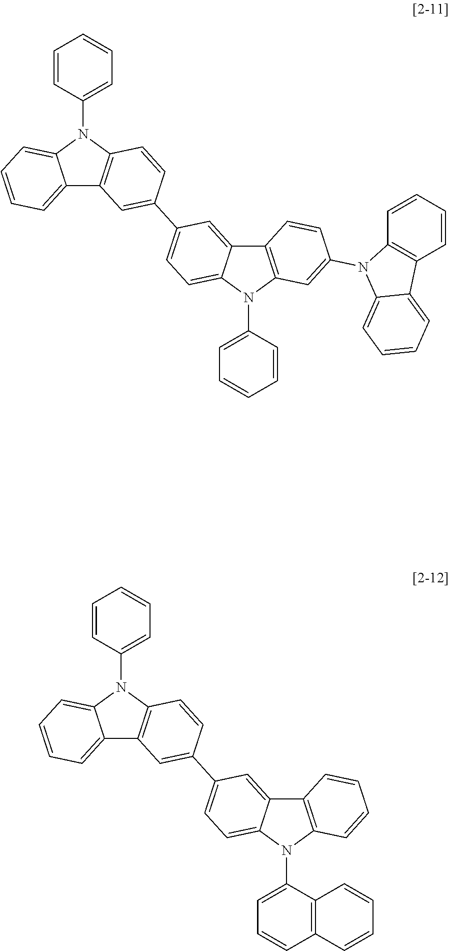 [SMILES: c1ccc(-n2c3ccccc3c3cc(-c4ccc5c(c4)c4ccc(-n6c7ccccc7c7ccccc76)cc4n5-c4ccccc4)ccc32)cc1 ; c1ccc(-n2c3ccccc3c3cc(-c4ccc5c(c4)c4ccccc4n5-c4cccc5ccccc45)ccc32)cc1]

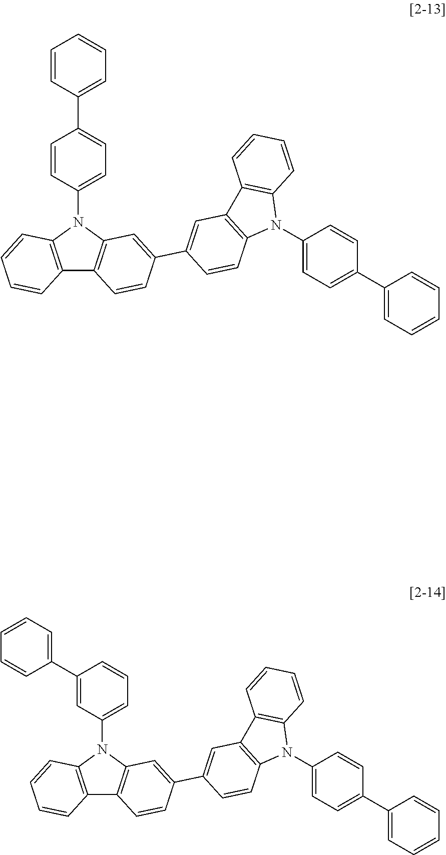 [SMILES: c1ccc(-c2ccc(-n3c4ccccc4c4cc(-c5ccc6c7ccccc7n(-c7ccc(-c8ccccc8)cc7)c6c5)ccc43)cc2)cc1 ; c1ccc(-c2ccc(-n3c4ccccc4c4cc(-c5ccc6c7ccccc7n(-c7cccc(-c8ccccc8)c7)c6c5)ccc43)cc2)cc1]

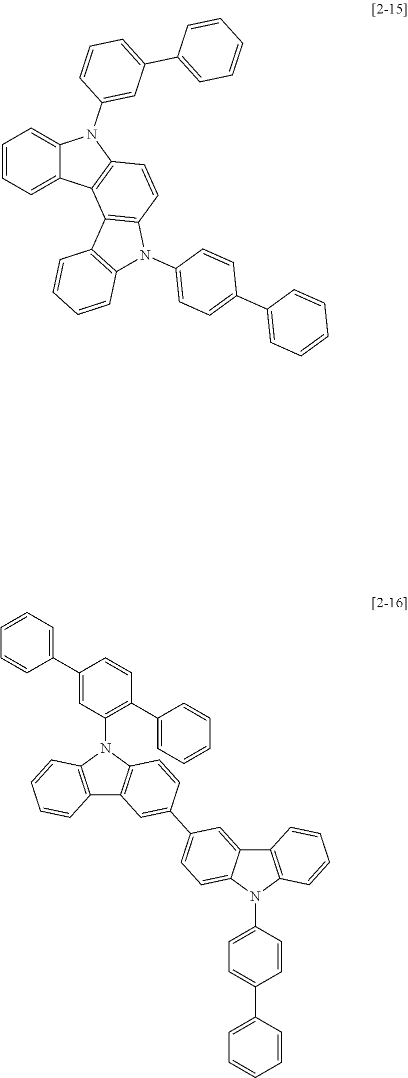 [SMILES: c1ccc(-c2ccc(-n3c4ccccc4c4c5c6ccccc6n(-c6cccc(-c7ccccc7)c6)c5ccc43)cc2)cc1 ; c1ccc(-c2ccc(-n3c4ccccc4c4cc(-c5ccc6c(c5)c5ccccc5n6-c5cc(-c6ccccc6)ccc5-c5ccccc5)ccc43)cc2)cc1]

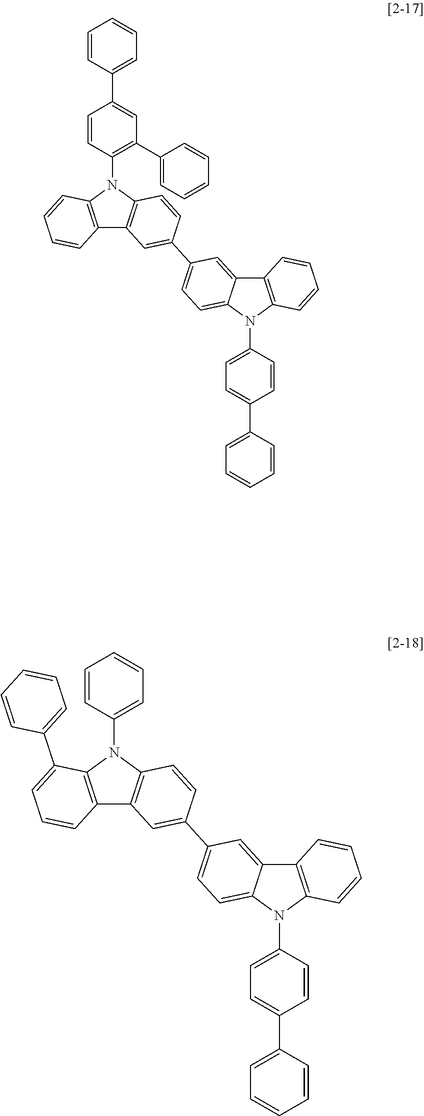 [SMILES: c1ccc(-c2ccc(-n3c4ccccc4c4cc(-c5ccc6c(c5)c5ccccc5n6-c5ccc(-c6ccccc6)cc5-c5ccccc5)ccc43)cc2)cc1 ; c1ccc(-c2ccc(-n3c4ccccc4c4cc(-c5ccc6c(c5)c5cccc(-c7ccccc7)c5n6-c5ccccc5)ccc43)cc2)cc1]

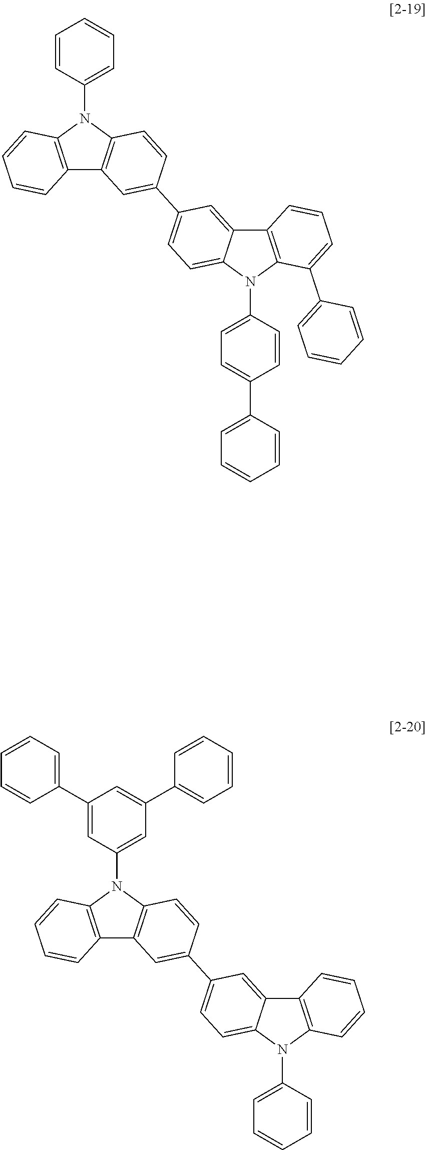 [SMILES: c1ccc(-c2ccc(-n3c4ccc(-c5ccc6c(c5)c5ccccc5n6-c5ccccc5)cc4c4cccc(-c5ccccc5)c43)cc2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

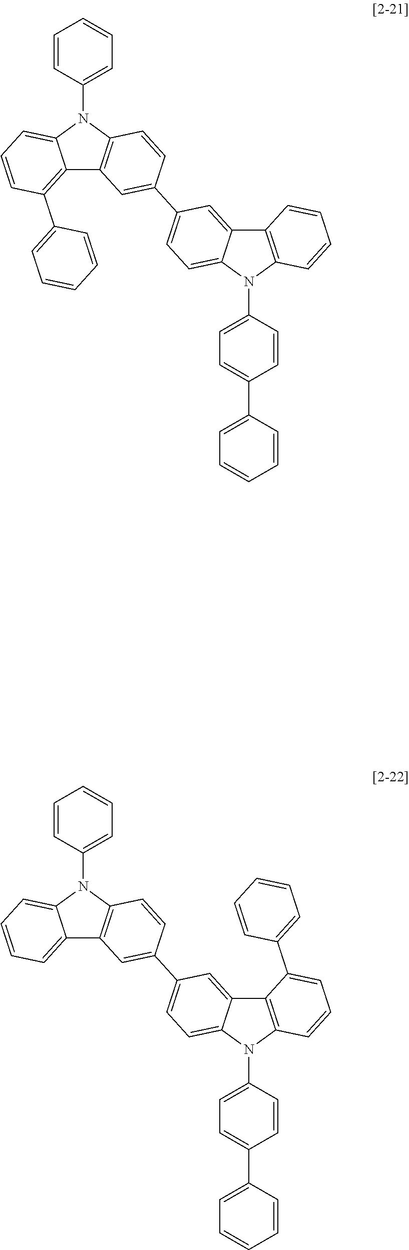 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

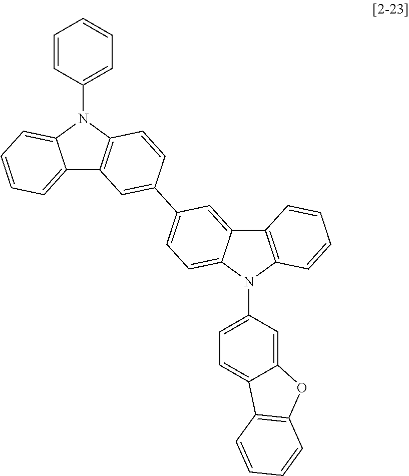 [SMILES: c1ccc(-n2c3ccccc3c3cc(-c4ccc5c(c4)c4ccccc4n5-c4ccc5c(c4)oc4ccccc45)ccc32)cc1]

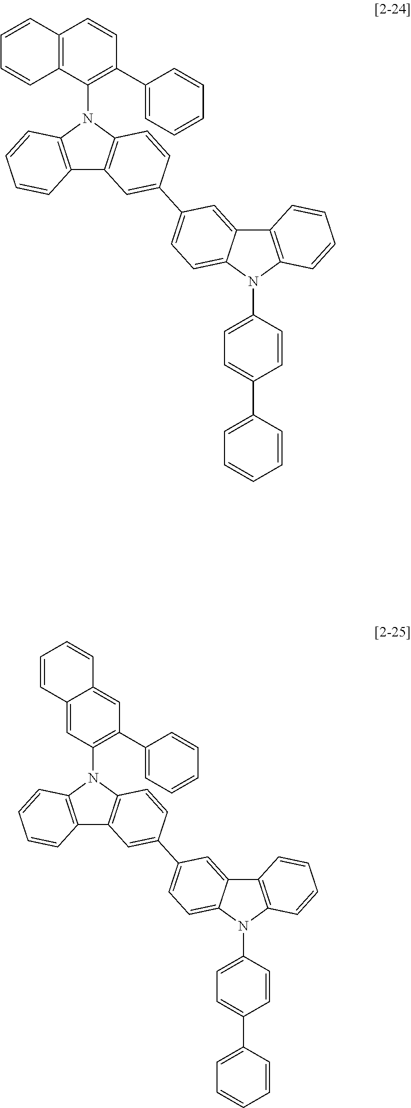 [SMILES: c1ccc(-c2ccc(-n3c4ccccc4c4cc(-c5ccc6c(c5)c5ccccc5n6-c5c(-c6ccccc6)ccc6ccccc56)ccc43)cc2)cc1 ; c1ccc(-c2ccc(-n3c4ccccc4c4cc(-c5ccc6c(c5)c5ccccc5n6-c5cc6ccccc6cc5-c5ccccc5)ccc43)cc2)cc1]

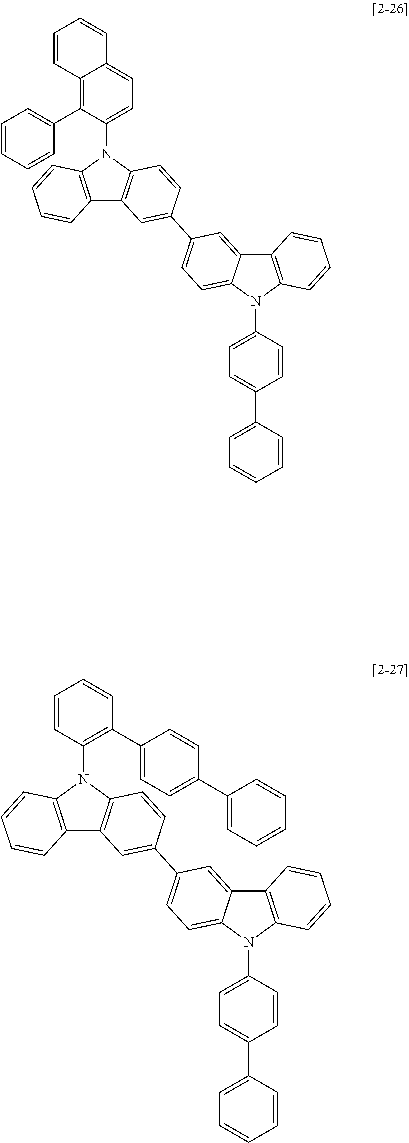 [SMILES: c1ccc(-c2ccc(-n3c4ccccc4c4cc(-c5ccc6c(c5)c5ccccc5n6-c5ccc6ccccc6c5-c5ccccc5)ccc43)cc2)cc1 ; c1ccc(-c2ccc(-c3ccccc3-n3c4ccccc4c4cc(-c5ccc6c(c5)c5ccccc5n6-c5ccc(-c6ccccc6)cc5)ccc43)cc2)cc1]

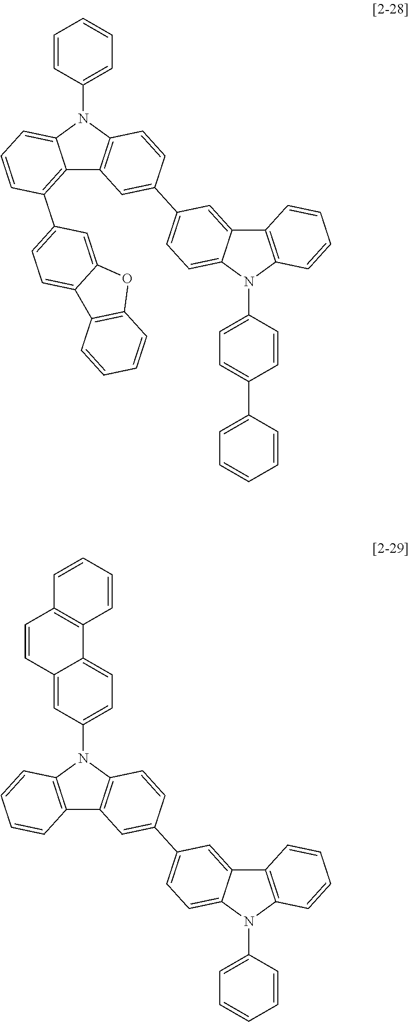 [SMILES: c1ccc(-c2ccc(-n3c4ccccc4c4cc(-c5ccc6c(c5)c5c(-c7ccc8c(c7)oc7ccccc78)cccc5n6-c5ccccc5)ccc43)cc2)cc1 ; c1ccc(-n2c3ccccc3c3cc(-c4ccc5c(c4)c4ccccc4n5-c4ccc5c(ccc6ccccc65)c4)ccc32)cc1]

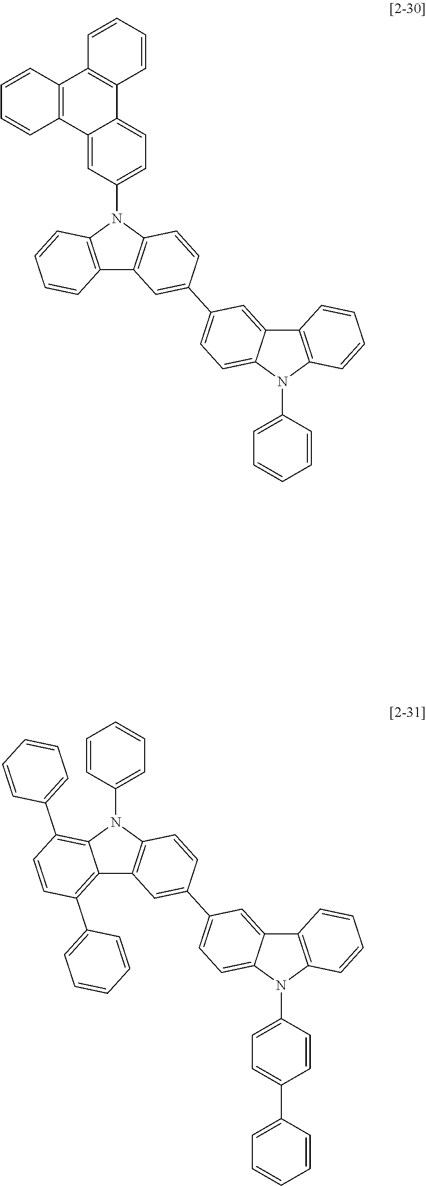 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-n3c4ccccc4c4cc(-c5ccc6c(c5)c5c(-c7ccccc7)ccc(-c7ccccc7)c5n6-c5ccccc5)ccc43)cc2)cc1]

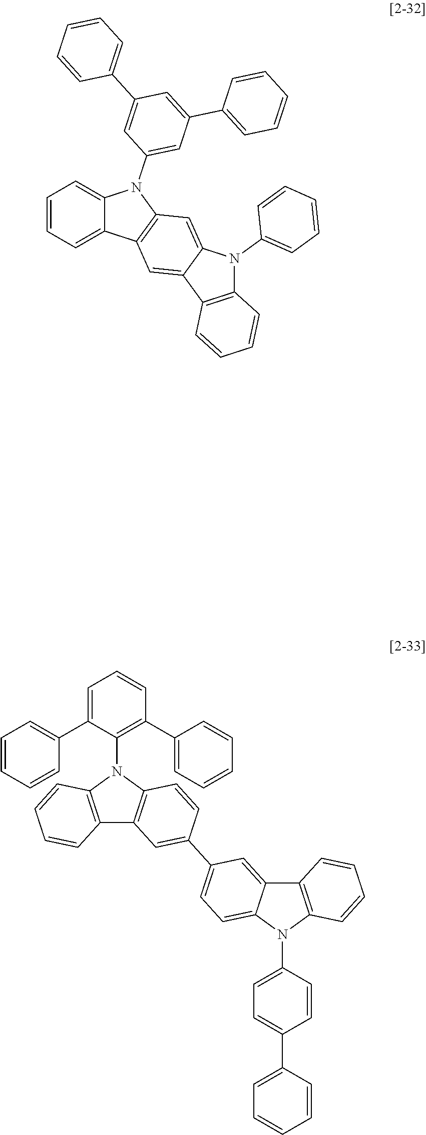 [SMILES: c1ccc(-c2cc(-c3ccccc3)cc(-n3c4ccccc4c4cc5c6ccccc6n(-c6ccccc6)c5cc43)c2)cc1 ; c1ccc(-c2ccc(-n3c4ccccc4c4cc(-c5ccc6c(c5)c5ccccc5n6-c5c(-c6ccccc6)cccc5-c5ccccc5)ccc43)cc2)cc1]

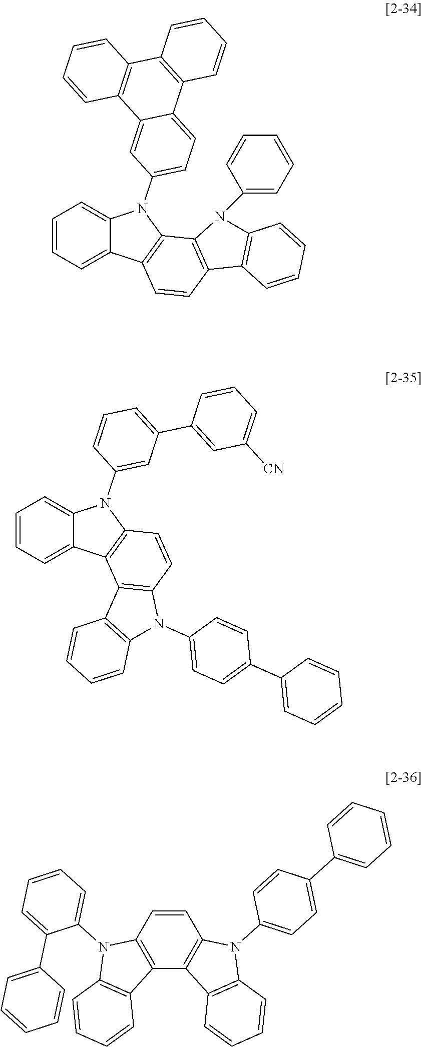 [SMILES: c1ccc(-n2c3ccccc3c3ccc4c5ccccc5n(-c5ccc6c7ccccc7c7ccccc7c6c5)c4c32)cc1 ; N#Cc1cccc(-c2cccc(-n3c4ccccc4c4c5c6ccccc6n(-c6ccc(-c7ccccc7)cc6)c5ccc43)c2)c1 ; c1ccc(-c2ccc(-n3c4ccccc4c4c5c6ccccc6n(-c6ccccc6-c6ccccc6)c5ccc43)cc2)cc1]

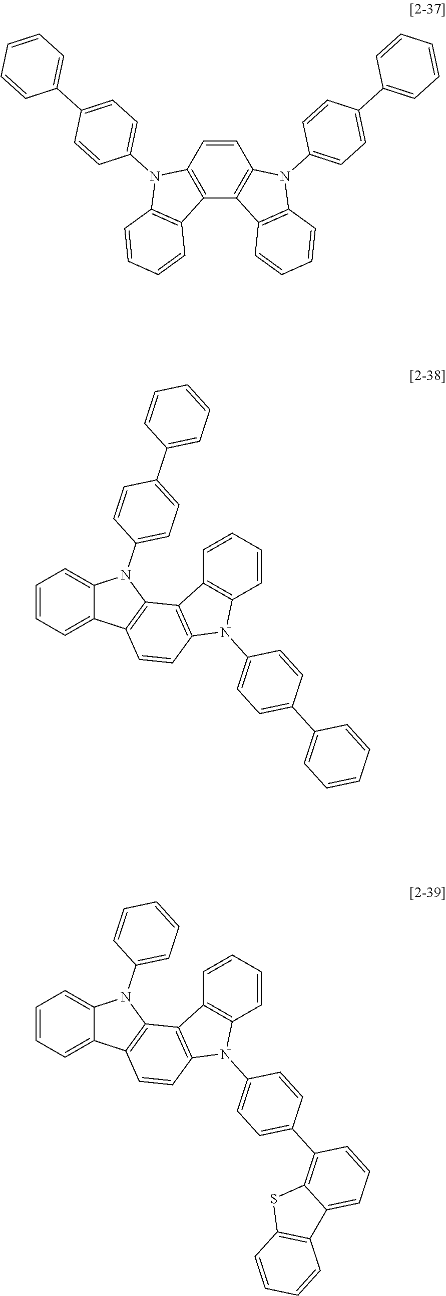 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c3ccc3c5ccccc5n(-c5ccc(-c6ccccc6)cc5)c34)cc2)cc1 ; c1ccc(-n2c3ccccc3c3ccc4c(c5ccccc5n4-c4ccc(-c5cccc6c5sc5ccccc56)cc4)c32)cc1]

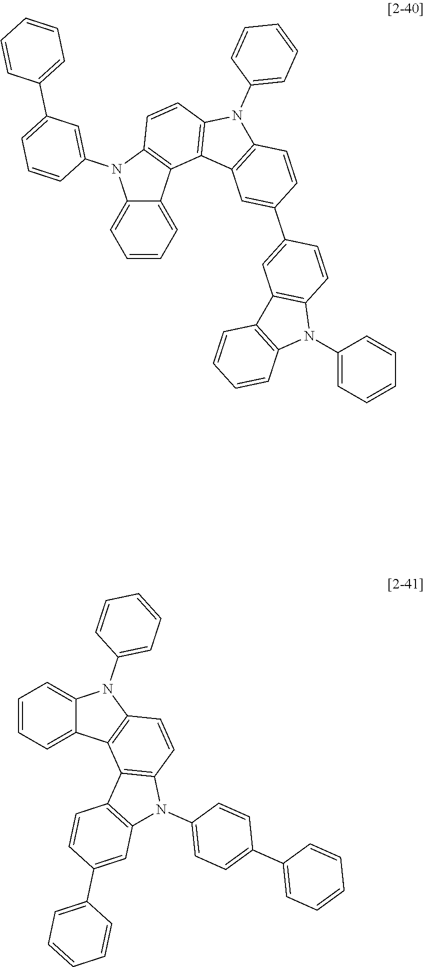 [SMILES: c1ccc(-c2cccc(-n3c4ccccc4c4c5c6cc(-c7ccc8c(c7)c7ccccc7n8-c7ccccc7)ccc6n(-c6ccccc6)c5ccc43)c2)cc1 ; c1ccc(-c2ccc(-n3c4cc(-c5ccccc5)ccc4c4c5c6ccccc6n(-c6ccccc6)c5ccc43)cc2)cc1]

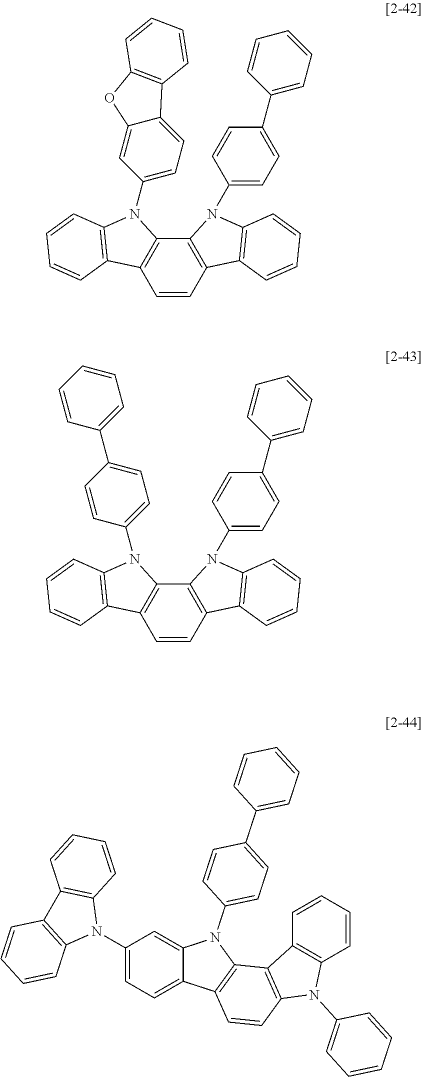 [SMILES: c1ccc(-c2ccc(-n3c4ccccc4c4ccc5c6ccccc6n(-c6ccc7c(c6)oc6ccccc67)c5c43)cc2)cc1 ; c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4cc(-n5c6ccccc6c6ccccc65)ccc4c4ccc5c(c6ccccc6n5-c5ccccc5)c43)cc2)cc1]

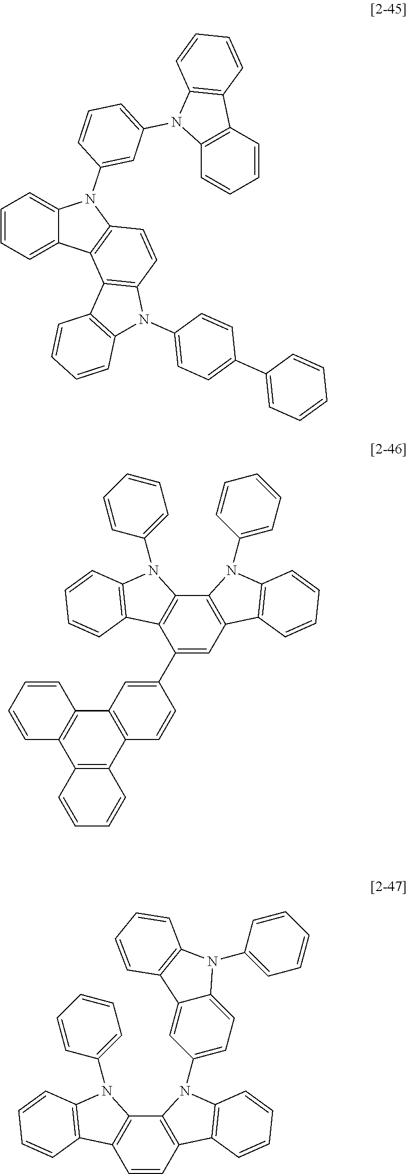 [SMILES: c1ccc(-c2ccc(-n3c4ccccc4c4c5c6ccccc6n(-c6cccc(-n7c8ccccc8c8ccccc87)c6)c5ccc43)cc2)cc1 ; c1ccc(-n2c3ccccc3c3cc(-c4ccc5c6ccccc6c6ccccc6c5c4)c4c5ccccc5n(-c5ccccc5)c4c32)cc1 ; c1ccc(-n2c3ccccc3c3cc(-n4c5ccccc5c5ccc6c7ccccc7n(-c7ccccc7)c6c54)ccc32)cc1]

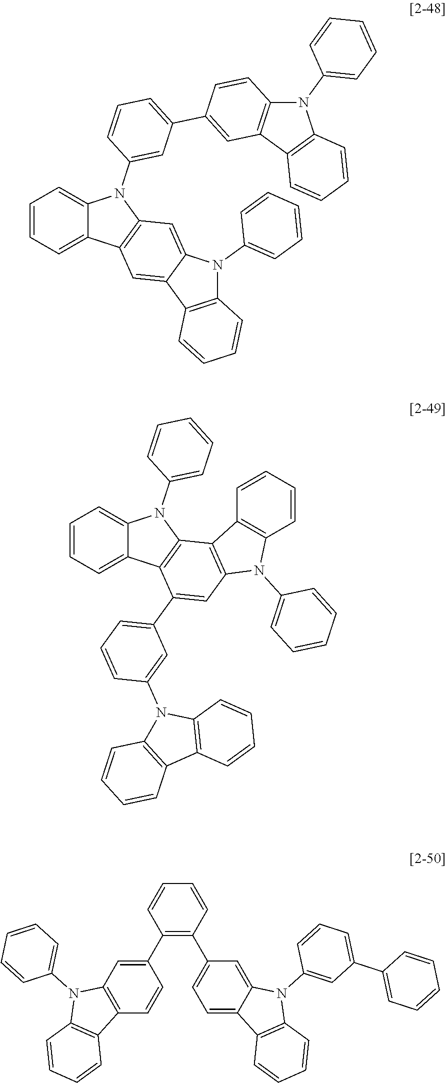 [SMILES: c1ccc(-n2c3ccccc3c3cc(-c4cccc(-n5c6ccccc6c6cc7c8ccccc8n(-c8ccccc8)c7cc65)c4)ccc32)cc1 ; c1ccc(-n2c3ccccc3c3c2cc(-c2cccc(-n4c5ccccc5c5ccccc54)c2)c2c4ccccc4n(-c4ccccc4)c23)cc1 ; c1ccc(-c2cccc(-n3c4ccccc4c4ccc(-c5ccccc5-c5ccc6c7ccccc7n(-c7ccccc7)c6c5)cc43)c2)cc1]

The third compound having buffer characteristics has a structure in which triphenylene is substituted with 9-carbazole and is represented by Chemical Formula 5.

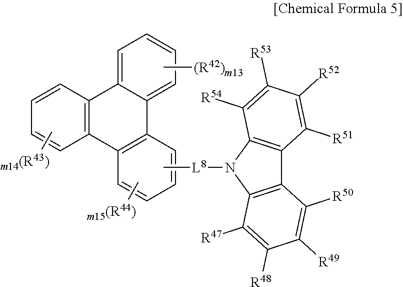

In Chemical Formula 5,
R⁴² to R⁴⁴ and R⁴⁷ to R⁵⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
m13 and m14 are each independently one of integers of 1 to 4,
m15 is one of integers of 1 to 3, and
L⁸ is a single bond, or a substituted or unsubstituted C6 to C20 arylene group including at least one of a meta-phenylene group and a para-phenylene group.

Specifically, L⁸ may be a single bond, a substituted or unsubstituted phenylene group including at least one of a meta-phenylene group and a para-phenylene group, a substituted or unsubstituted biphenylene group including at least one of a meta-phenylene group and a para-phenylene group, or a substituted or unsubstituted terphenylene group including at least one of a meta-phenylene group and a para-phenylene group.

For example, L⁸ may be a single bond or selected from the linking groups listed in Group I.

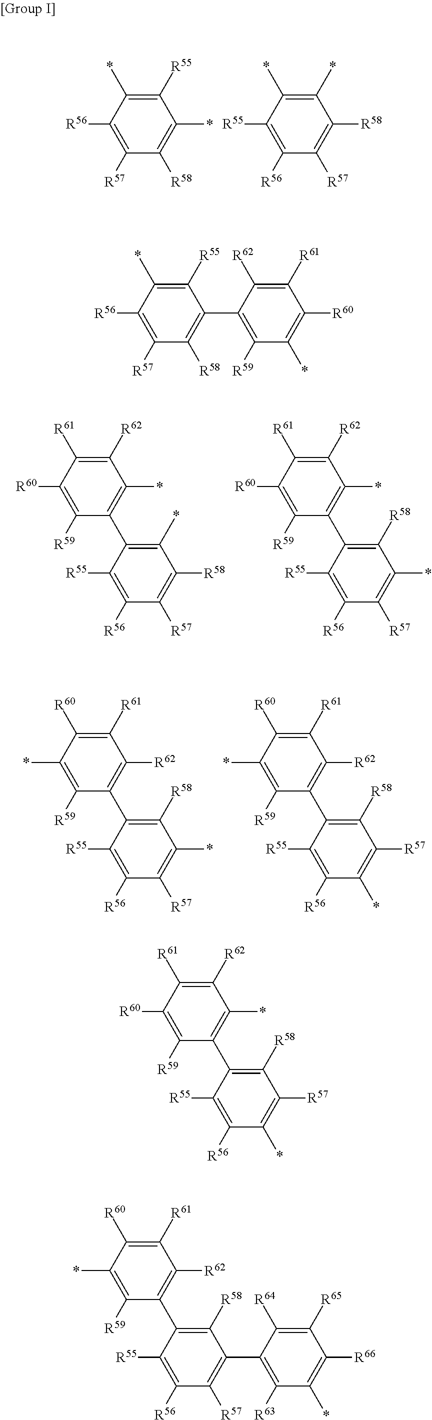

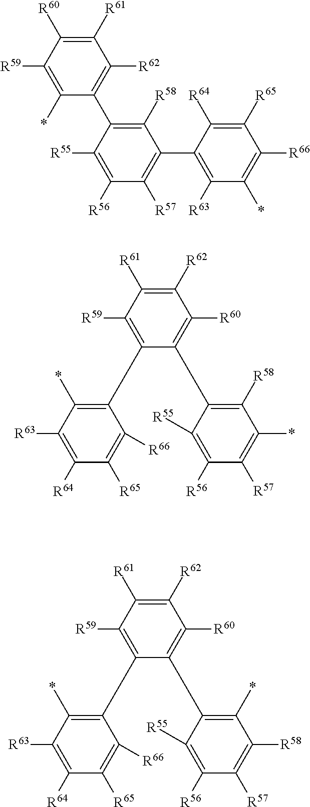

In Group I,
R⁵⁵ to R⁶⁶ are each independently hydrogen, deuterium, a C1 to C10 alkyl group, a substituted or unsubstituted C6 to C12 aryl group, a halogen, a cyano group, or a combination thereof, and
* is a linking point.

In an embodiment, the third compound may be represented by any one of Chemical Formula 5-I to Chemical Formula 5-III.

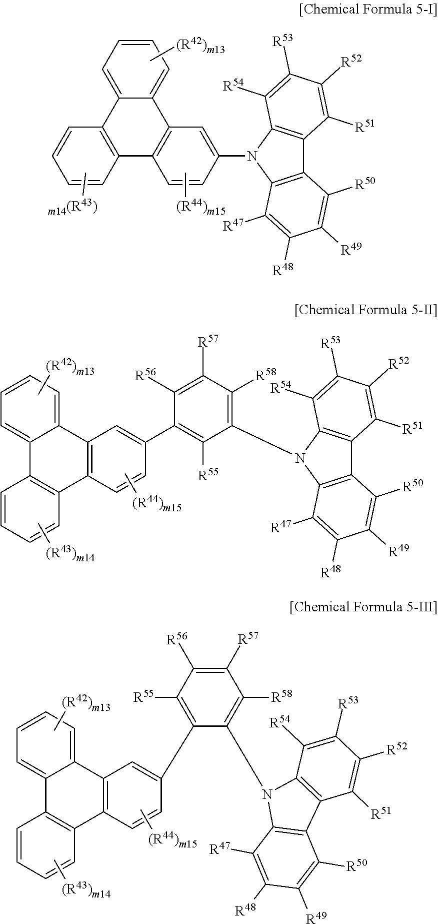

In Chemical Formula 5-I to Chemical Formula 5-III, R⁴² to R⁴⁴, R⁴⁷ to R⁵⁸ and m13 to m15 are the same as described above.

For example, the third compound may be represented by Chemical Formula 5-II.

Specifically, in Chemical Formula 5, R⁴² to R⁴⁴ may each independently be hydrogen, deuterium, a substituted or unsubstituted phenyl group, or a substituted or unsubstituted biphenyl group.

Specifically, in Chemical Formula 5, R⁴⁷ to R⁵⁴ may each independently be hydrogen, deuterium, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

The third compound may be, for example, one selected from the compounds listed in Group 3.

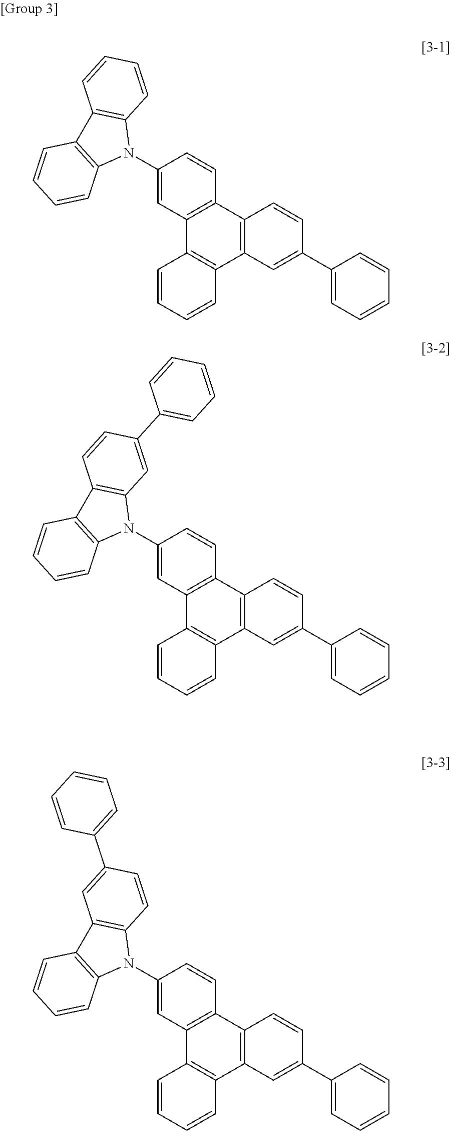

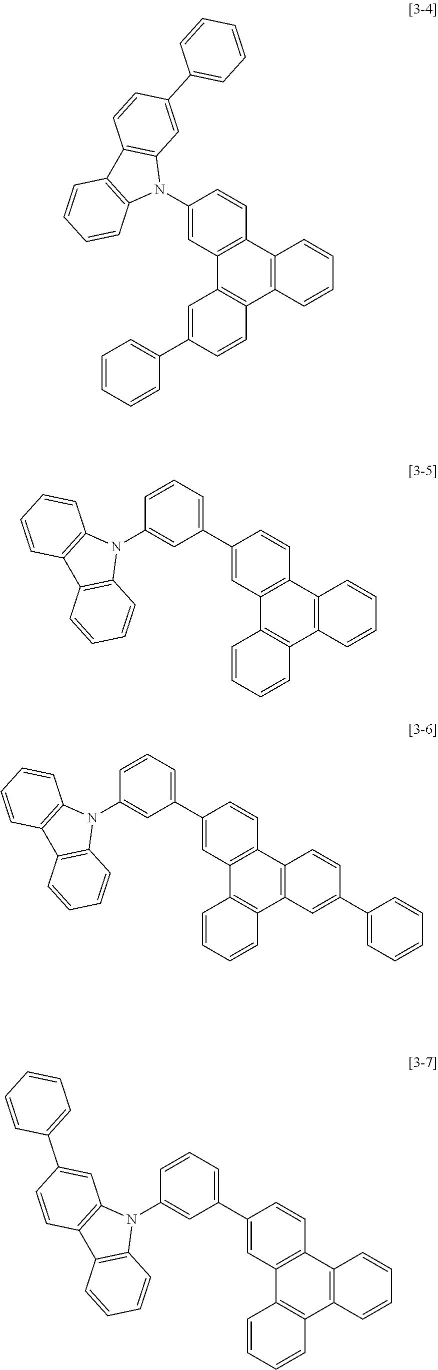 [SMILES: c1ccc(-c2ccc3c4ccccc4c4ccc(-n5c6ccccc6c6ccc(-c7ccccc7)cc65)cc4c3c2)cc1 ; c1cc(-c2ccc3c4ccccc4c4ccccc4c3c2)cc(-n2c3ccccc3c3ccccc32)c1 ; c1ccc(-c2ccc3c4ccc(-c5cccc(-n6c7ccccc7c7ccccc76)c5)cc4c4ccccc4c3c2)cc1 ; c1ccc(-c2ccc3c4ccccc4n(-c4cccc(-c5ccc6c7ccccc7c7ccccc7c6c5)c4)c3c2)cc1]

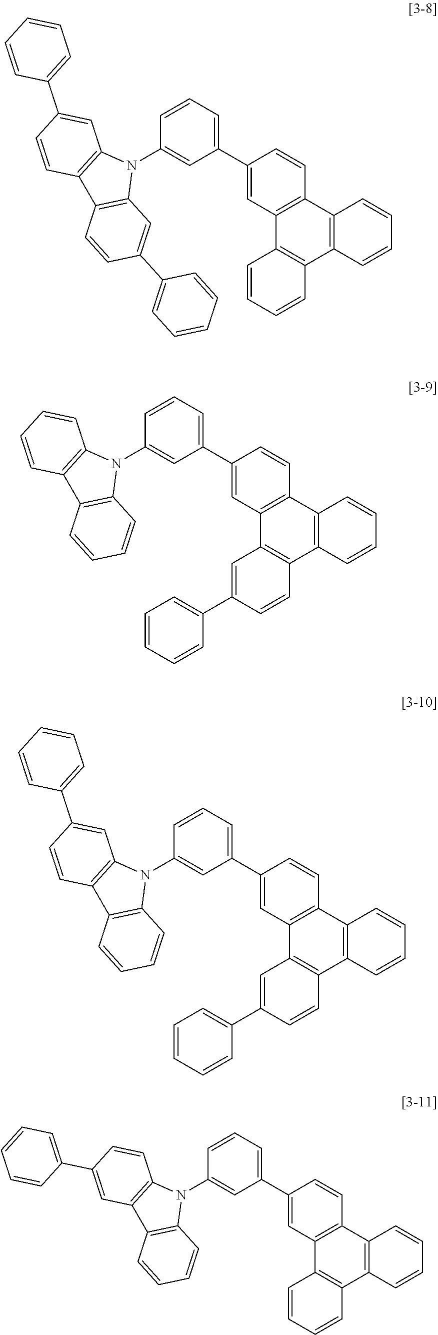 [SMILES: c1ccc(-c2ccc3c4ccc(-c5ccccc5)cc4n(-c4cccc(-c5ccc6c7ccccc7c7ccccc7c6c5)c4)c3c2)cc1 ; c1ccc(-c2ccc3c4ccccc4c4ccc(-c5cccc(-n6c7ccccc7c7ccccc76)c5)cc4c3c2)cc1 ; c1ccc(-c2ccc3c4ccccc4c4ccc(-c5cccc(-n6c7ccccc7c7ccc(-c8ccccc8)cc76)c5)cc4c3c2)cc1 ; c1ccc(-c2ccc3c(c2)c2ccccc2n3-c2cccc(-c3ccc4c5ccccc5c5ccccc5c4c3)c2)cc1]

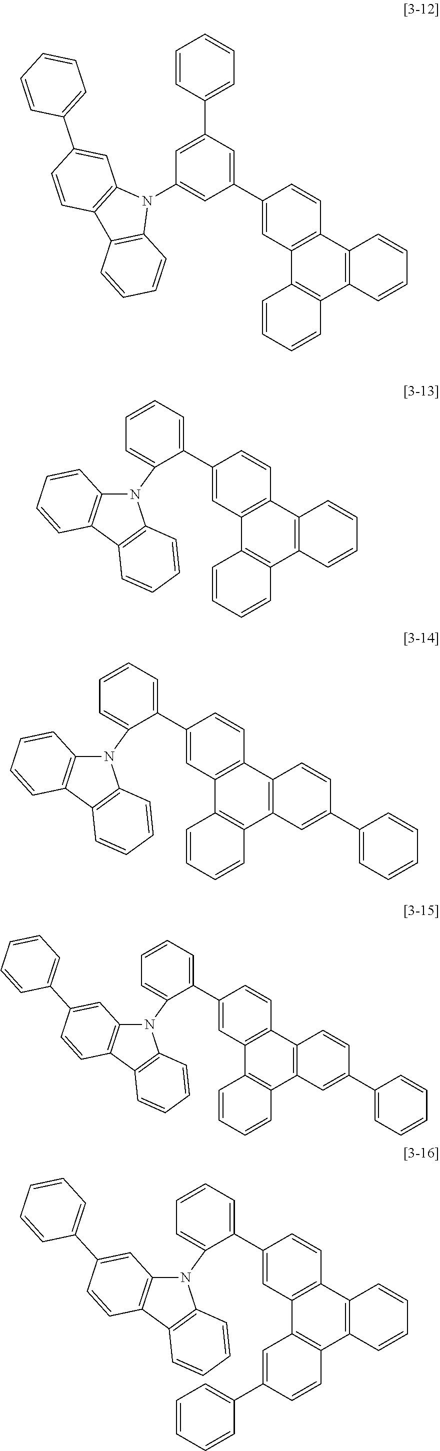 [SMILES: c1ccc(-c2cc(-c3ccc4c5ccccc5c5ccccc5c4c3)cc(-n3c4ccccc4c4ccc(-c5ccccc5)cc43)c2)cc1 ; c1ccc(-n2c3ccccc3c3ccccc32)c(-c2ccc3c4ccccc4c4ccccc4c3c2)c1 ; c1ccc(-c2ccc3c4ccc(-c5ccccc5-n5c6ccccc6c6ccccc65)cc4c4ccccc4c3c2)cc1 ; c1ccc(-c2ccc3c4ccc(-c5ccccc5-n5c6ccccc6c6ccc(-c7ccccc7)cc65)cc4c4ccccc4c3c2)cc1 ; c1ccc(-c2ccc3c4ccccc4c4ccc(-c5ccccc5-n5c6ccccc6c6ccc(-c7ccccc7)cc65)cc4c3c2)cc1]

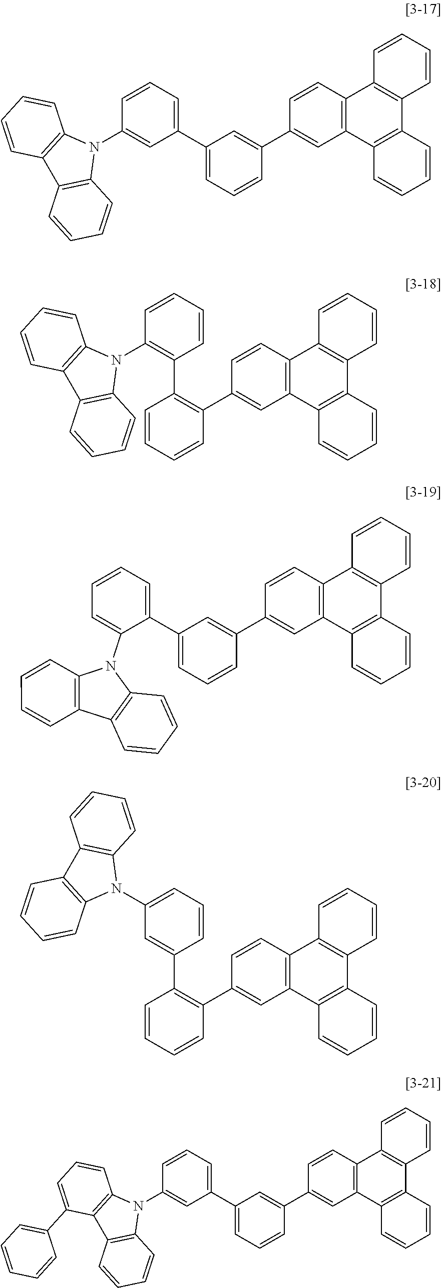 [SMILES: c1cc(-c2cccc(-n3c4ccccc4c4ccccc43)c2)cc(-c2ccc3c4ccccc4c4ccccc4c3c2)c1 ; c1ccc(-c2ccccc2-n2c3ccccc3c3ccccc32)c(-c2ccc3c4ccccc4c4ccccc4c3c2)c1 ; c1cc(-c2ccc3c4ccccc4c4ccccc4c3c2)cc(-c2ccccc2-n2c3ccccc3c3ccccc32)c1 ; c1cc(-c2ccccc2-c2ccc3c4ccccc4c4ccccc4c3c2)cc(-n2c3ccccc3c3ccccc32)c1 ; c1ccc(-c2cccc3c2c2ccccc2n3-c2cccc(-c3cccc(-c4ccc5c6ccccc6c6ccccc6c5c4)c3)c2)cc1]

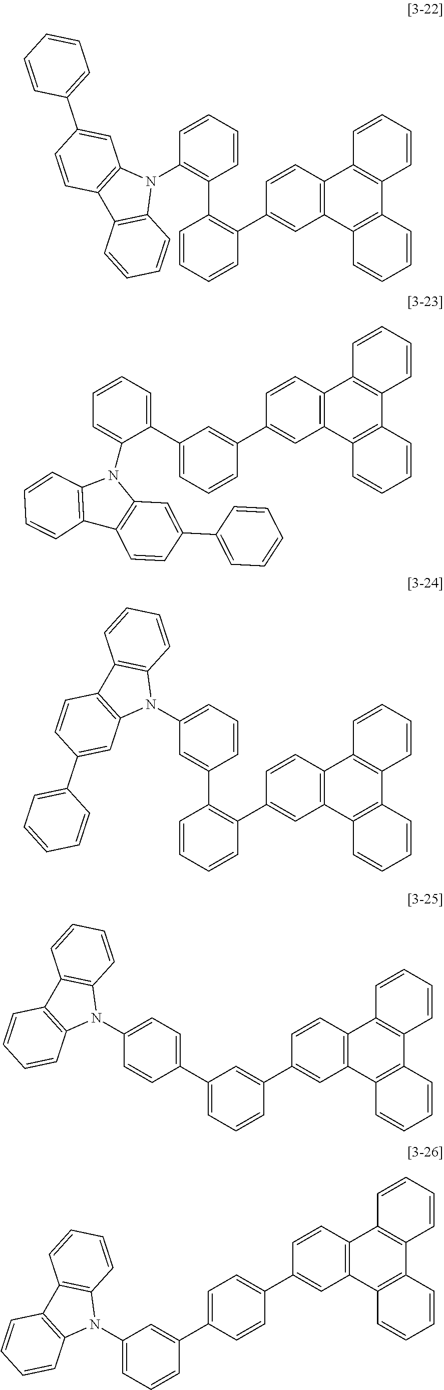

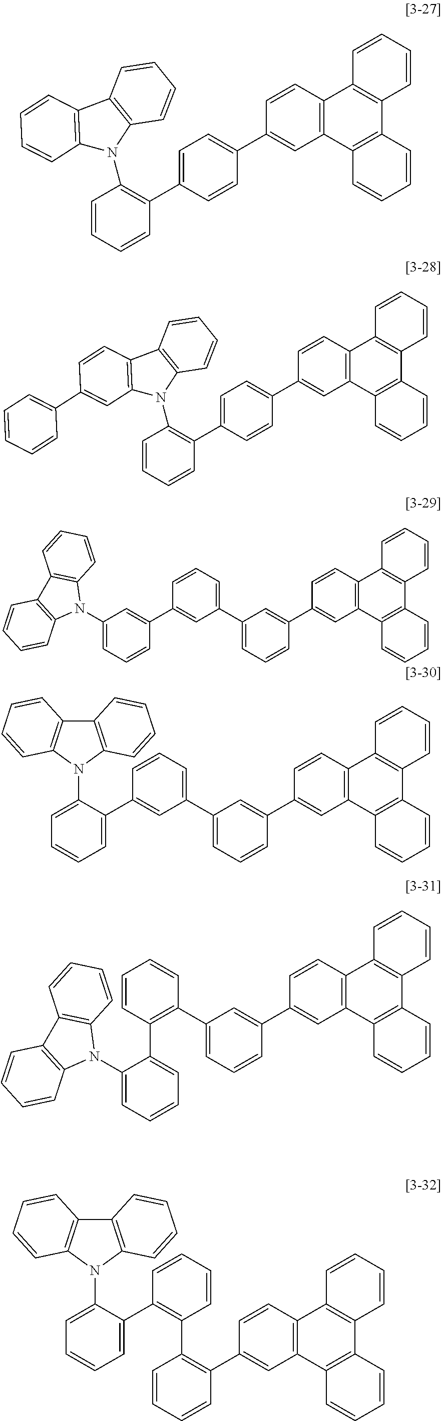

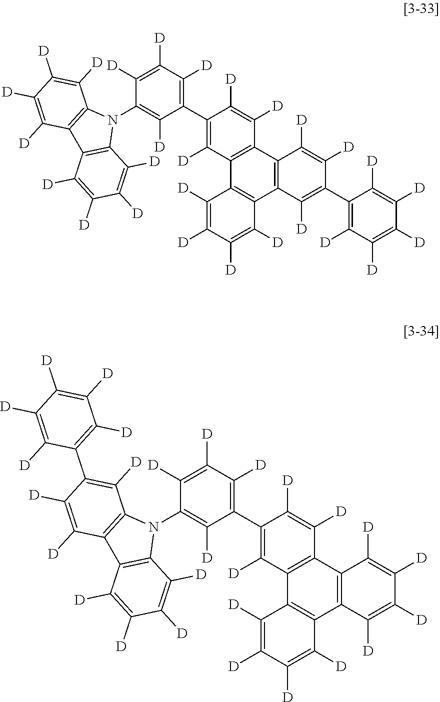 [SMILES: [2H]c1c([2H])c([2H])c(-c2c([2H])c([2H])c3c4c([2H])c([2H])c(-c5c([2H])c([2H])c([2H])c(-n6c7c([2H])c([2H])c([2H])c([2H])c7c7c([2H])c([2H])c([2H])c([2H])c76)c5[2H])c([2H])c4c4c([2H])c([2H])c([2H])c([2H])c4c3c2[2H])c([2H])c1[2H] ; [2H]c1c([2H])c([2H])c(-c2c([2H])c([2H])c3c4c([2H])c([2H])c([2H])c([2H])c4n(-c4c([2H])c([2H])c([2H])c(-c5c([2H])c([2H])c6c7c([2H])c([2H])c([2H])c([2H])c7c7c([2H])c([2H])c([2H])c([2H])c7c6c5[2H])c4[2H])c3c2[2H])c([2H])c1[2H]]

The first compound includes a nitrogen-containing 6-membered ring having high electron transport characteristics, and thus electrons may be stably and effectively transported to lower a driving voltage, to increase current efficiency, and to implement long life-span characteristics of a device.

The second compound has a structure including carbazole having high HOMO energy, and thus can effectively inject and transport holes, thereby contributing to improvement of device characteristics.

The third compound has a wide HOMO-LUMO band gap, thereby controlling the movement rate of holes and electrons of the first compound and the second compound, and thus hole trapping and exciton quenching may be prevented through relative movement of the light emitting layer region, which contributes to the improvement of the life-span characteristics of the device.

The three-host composition including the first compound, the second compound, and the third compound may achieve an optimum balance achieved by more finely adjusting electron/hole characteristics in the device stack compared with the composition, and may improve device characteristics greatly due to an appropriate balance of charges, compared with two-host composition such as a composition including the first compound and the second compound or a composition including the first compound and the third compound.

In addition, the life-span and efficiency characteristics may be further improved by optimally controlling a balance of electron/hole characteristics compared to other combinations of 3-host compositions.

In the most specific embodiment of the present invention, the first compound may be represented by Chemical Formula 1A, the second compound may be represented by any one of Chemical Formula 2-6, Chemical Formula 2-8, and Chemical Formula 3C, and the third compound may be represented by the Chemical Formula 5-II.

The composition in which the first compound, the second compound, and the third compound are mixed may be included in a light emitting layer of an organic light emitting diode to be described later, for example, as a phosphorescent host.

In the composition for an organic optoelectronic device, the first compound may be included in an amount of about 20 wt % to 50 wt % based on a total weight of the first compound, the second compound, and the third compound, the second compound may be included in an amount of about 40 wt % to 60 wt % based on a total weight of the first compound, the second compound, and the third compound, and the third compound may be included in an amount of about 10 wt % to 30 wt % based on a total weight of the first compound, the second compound, and the third compound.

Within the above range, for example, the first compound for an organic optoelectronic device may be included in an amount of about 25 wt % to 45 wt % based on a total weight of the first compound for an organic optoelectronic device, the second compound for an organic optoelectronic device, and the third compound for an organic optoelectronic device included in weight, the second compound for an organic optoelectronic device may be included in an amount of about 45 wt % to 60 wt % based on a total weight of the first compound for an organic optoelectronic device, the second compound for an organic optoelectronic device, and the third compound for an organic optoelectronic device, and the third compound for an organic optoelectronic device may be included in an amount of about 10 wt % to 25 wt % based on a total weight of the first compound for an organic optoelectronic device, the second compound for an organic optoelectronic device, and the third compound for an organic optoelectronic device.

In addition, as a specific example, the first compound may be included in an amount of about 30 wt % to 40 wt % based on a total weight of the first compound, the second compound, and the third compound, the second compound may be included in an amount of about 45 wt % to 55 wt % based on a total weight of the first compound, the second compound, and the third compound, and the third compound may be included in an amount of about 10 wt % to 20 wt % based on a total weight of the first compound, the second compound, and the third compound.

As a more specific example, the composition for the organic optoelectronic device may include the first compound: the second compound:the third compound in a weight ratio of about 35:55:10, or about 32:48:20. Within the above range, the electron transport capability of the first compound, the hole transport capability of the second compound, and the buffering capability of the third compound are properly harmonized to improve efficiency and life-span of the device.

The composition for an organic optoelectronic device may further include one or more compounds in addition to the first compound, the second compound, and the third compound.

The composition for an organic optoelectronic device may further include a dopant. The dopant may be, for example, a phosphorescent dopant, such as a red, green, or blue phosphorescent dopant, and may be, for example, a green phosphorescent dopant.

The dopant is a material mixed with the first compound, second compound, and third compound in a trace amount to cause light emission and may be generally a material such as a metal complex that emits light by multiple excitation into a triplet or more. The dopant may be, for example an inorganic, organic, or organic-inorganic compound, and one or more types thereof may be used.

Examples of the dopant may be a phosphorescent dopant and examples of the phosphorescent dopant may be an organic metal compound including Ir, Pt, Os, Ti, Zr, Hf, Eu, Tb, Tm, Fe, Co, Ni, Ru, Rh, Pd, or a combination thereof. The phosphorescent dopant may be for example a compound represented by Chemical Formula Z, but is not limited thereto.

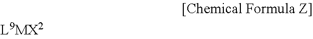

In Chemical Formula Z, M is a metal, and L⁹ and X² are the same or different, and are a ligand to form a complex compound with M.

The M may be for example Ir, Pt, Os, Ti, Zr, Hf, Eu, Tb, Tm, Fe, Co, Ni, Ru, Rh, Pd, or a combination thereof and the L⁹ and X² may be for example a bidentate ligand.

Examples of the ligands represented by L⁹ and X² may be selected from the chemical formulas of Group A, but are not limited thereto.

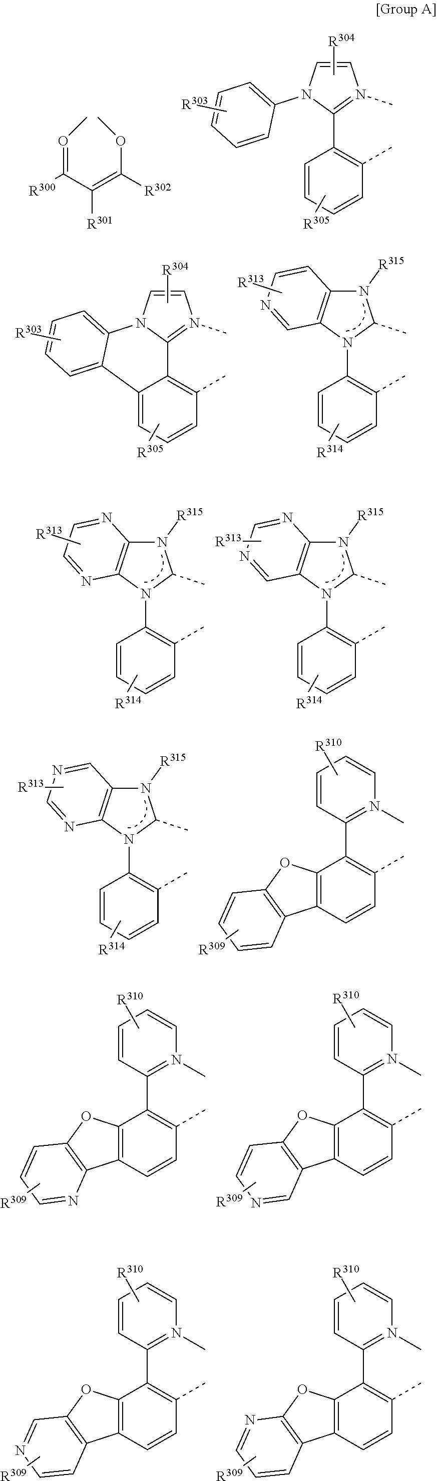

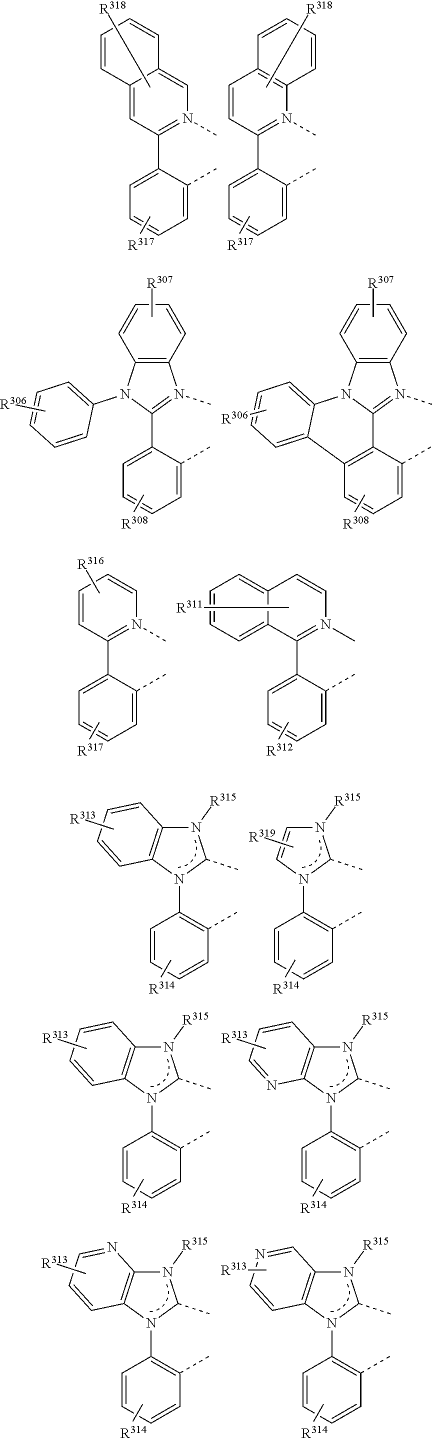

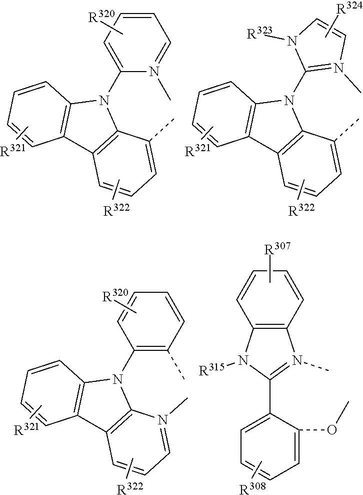

In Group A,
R³⁰⁰ to R³⁰² are each independently hydrogen, deuterium, a C1 to C30 alkyl group that is substituted or unsubstituted with a halogen, a C6 to C30 aryl group that is substituted or unsubstituted with a C1 to C30 alkyl, or a halogen, and
R³⁰³ to R³²⁴ are each independently hydrogen, deuterium, halogen, a substituted or unsubstituted C1 to C30 alkyl group, a substituted or unsubstituted C1 to C30 alkoxy group, a substituted or unsubstituted C3 to C30 cycloalkyl group, a substituted or unsubstituted C2 to C30 alkenyl group, a substituted or unsubstituted C6 to C30 aryl group, a substituted or unsubstituted C1 to C30 heteroaryl group, a substituted or unsubstituted C1 to C30 amino group, a substituted or unsubstituted C6 to C30 arylamino group, SFs, a trialkylsilyl group having a substituted or unsubstituted C1 to C30 alkyl group, a dialkylarylsilyl group having a substituted or unsubstituted C1 to C30 alkyl group and a C6 to C30 aryl group, or a triarylsilyl group having a substituted or unsubstituted C6 to C30 aryl group.

As an example, it may include a dopant represented by Chemical Formula IV.

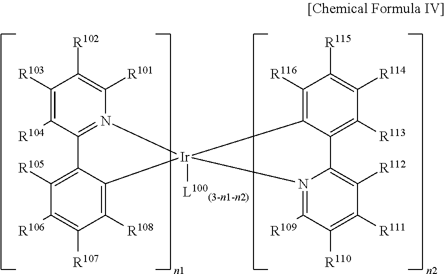

In Chemical Formula IV,
R¹⁰¹ to R¹¹⁶ are each independently hydrogen, deuterium, a substituted or unsubstituted C1 to C10 alkyl group, a substituted or unsubstituted C6 to C20 aryl group, or —SiR¹³²R¹³³R¹³⁴,
R¹³² to R¹³⁴ are each independently a substituted or unsubstituted C1 to C6 alkyl group,
at least one of R¹⁰¹ to R¹¹⁶ is a functional group represented by Chemical Formula IV-1,
L¹⁰⁰ is a bidentate ligand of a monovalent anion, and is a ligand that coordinates to iridium through a lone pair of carbons or heteroatoms, and
n1 and n2 are each independently any one of integers of 0 to 3, and n1+n2 is any one of integers of 1 to 3,

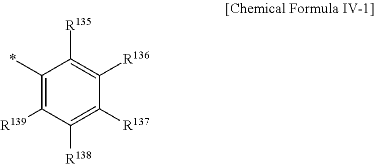

wherein, in Chemical Formula IV-1,
R¹³⁵ to R¹³⁹ are each independently hydrogen, deuterium, a substituted or unsubstituted C1 to C10 alkyl group, a substituted or unsubstituted C6 to C20 aryl group, or —SiR¹³²R¹³³R¹³⁴, and
* refers to a portion linked to a carbon atom.

As an example, a dopant represented by Chemical Formula Z-1 may be included.

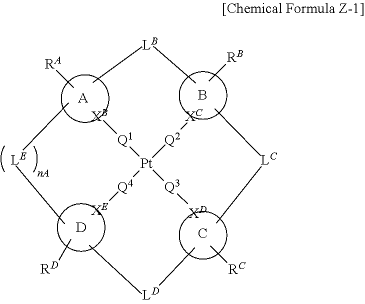

In Chemical Formula Z-1, rings A, B, C, and D independently represent a 5-membered or 6-membered carbocyclic or heterocyclic ring;
R^{A}, R^{B}, R^{C}, and R^{D} independently represent mono-, di-, tri-, or tetra-substitution, or unsubstitution;
L^{B}, L^{C}, and L^{D} are each independent selected from a direct bond, BR, NR, PR, O, S, Se, C═O, S═O, SO₂, CRR′, SiRR′, GeRR′, and a combination thereof,
when nA is 1, L^{E} is selected from a direct bond, BR, NR, PR, O, S, Se, C═O, S═O, SO₂, CRR′, SiRR′, GeRR′, and a combination thereof, when nA is 0, L^{E} does not exist; and
R^{A}, R^{B}, R^{C}, R^{D}, R, and R′ are each independently selected from hydrogen, deuterium, a halogen, alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a carbonyl group, a carboxylic acid group, an ester group, a nitrile group, an isonitrile group, a sulfanyl group, a sulfinyl group, a sulfonyl group, a phosphino group, and a combination thereof, any adjacent R^{A}R^{B}, R^{C}, R^{D}, R, and R′ are optionally linked to each other to provide a ring; X^{B}, X^{c}, X^{D}, and X^{E} are each independently selected from carbon and nitrogen; and Q¹, Q², Q³, and Q⁴ each represent oxygen or a direct bond.

The dopant according to an embodiment may be a platinum complex, and may be, for example, represented by Chemical Formula V.

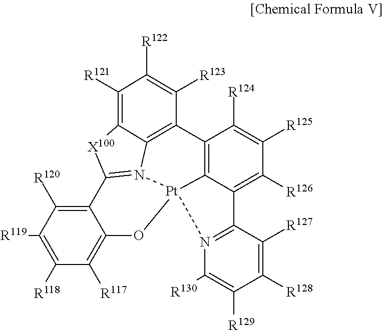

In Chemical Formula V,
X¹⁰⁰ is selected from O, S, and NR¹³¹
R¹¹⁷ to R¹³¹ are each independently hydrogen, deuterium, a substituted or unsubstituted C1 to C10 alkyl group, a substituted or unsubstituted C6 to C20 aryl group, or —SiR¹³²R¹³³R¹³⁴,
R¹³² to R¹³⁴ are each independently a substituted or unsubstituted C1 to C6 alkyl group, and
at least one of R¹¹⁷ to R¹³¹ is —SiR¹³²R¹³³R¹³⁴ or a tert-butyl group.

The composition for an organic optoelectronic device may be formed by a dry film deposition method such as chemical vapor deposition.

Hereinafter, an organic optoelectronic device using the aforementioned composition for an organic optoelectronic device is described.

The organic optoelectronic device may be a suitable device to convert electrical energy into photoenergy and vice versa, e.g., an organic photoelectric device, an organic light emitting diode, an organic solar cell, or an organic photoconductor drum.

Herein, an organic light emitting diode as one example of an organic optoelectronic device is described referring to drawings.

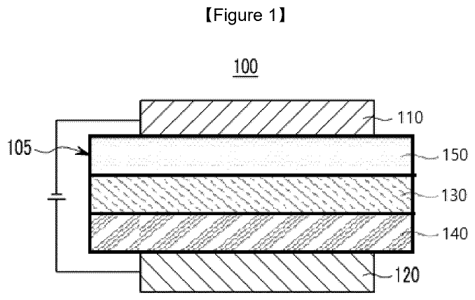

FIG. 1 is a cross-sectional view showing an organic light emitting diode according to an embodiment.

Referring to FIG. 1, an organic light emitting diode 100 according to an embodiment includes an anode 120 and a cathode 110 facing each other and an organic layer 105 disposed between the anode 120 and cathode 110.

The anode 120 may be made of a conductor having a large work function to help hole injection, and may be for example a metal, a metal oxide and/or a conductive polymer. The anode 120 may be, for example a metal such as nickel, platinum, vanadium, chromium, copper, zinc, gold, and the like or an alloy thereof, a metal oxide such as zinc oxide, indium oxide, indium tin oxide (ITO), indium zinc oxide (IZO), and the like; a combination of a metal and an oxide such as ZnO and Al or SnO₂ and Sb; a conductive polymer such as poly(3-methylthiophene), poly(3,4-(ethylene-1,2-dioxy)thiophene) (PEDOT), polypyrrole, and polyaniline, but is not limited thereto.

The cathode 110 may be made of a conductor having a small work function to help electron injection, and may be for example a metal, a metal oxide, and/or a conductive polymer.

The cathode 110 may include a metal such as magnesium, calcium, sodium, potassium, titanium, indium, yttrium, lithium, gadolinium, aluminum, silver, tin, lead, cesium, barium, or an alloy thereof, a multilayer structure material such as LiF/Al, LiO₂/Al, LiF/Ca, and BaF₂/Ca, but is not limited thereto.

The organic layer 105 may include the aforementioned composition for an organic optoelectronic device.

The organic layer 105 may include a light emitting layer 130 and the light emitting layer 130 may include the aforementioned compound for an organic optoelectronic device or composition for an organic optoelectronic device.

The composition for an organic optoelectronic device further including a dopant may be, for example, a green light emitting composition.

The light emitting layer 130 may include, for example, the aforementioned compound for an organic optoelectronic device or composition for an organic optoelectronic device, as a phosphorescent host.

The organic layer may further include a charge transport region in addition to the light emitting layer.

The charge transport region may be, for example, a hole transport region 140.

The hole transport region 140 may further increase hole injection and/or hole mobility between the anode 120 and the light emitting layer 130 and block electrons.

Specifically, the hole transport region 140 may include a hole transport layer between the anode 120 and the light emitting layer 130, and a hole transport auxiliary layer between the light emitting layer 130 and the hole transport layer, and at least one of the compounds of Group B may be included in at least one of the hole transport layer and the hole transport auxiliary layer.

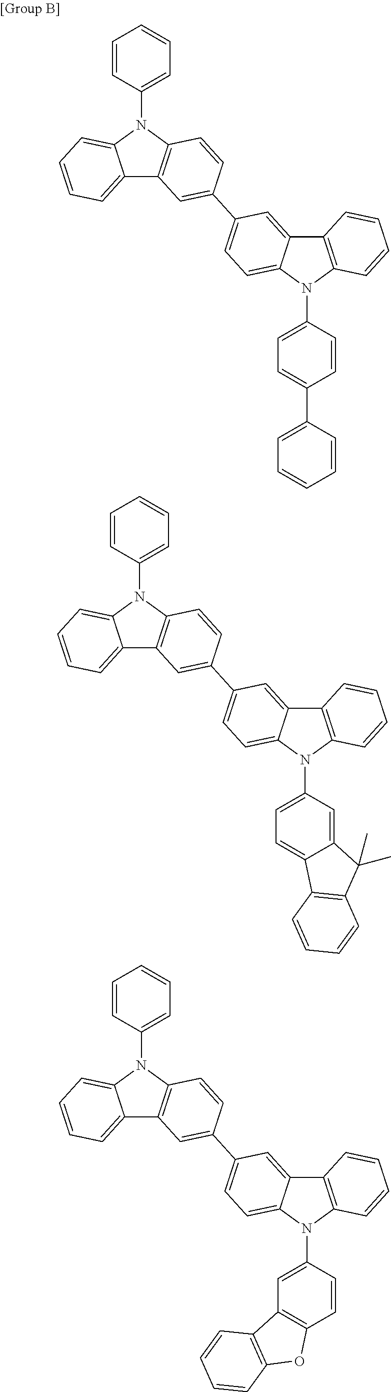 [SMILES: c1ccc(-c2ccc(-n3c4ccccc4c4cc(-c5ccc6c(c5)c5ccccc5n6-c5ccccc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-n2c3ccccc3c3cc(-c4ccc5c(c4)c4ccccc4n5-c4ccc5oc6ccccc6c5c4)ccc32)cc1]

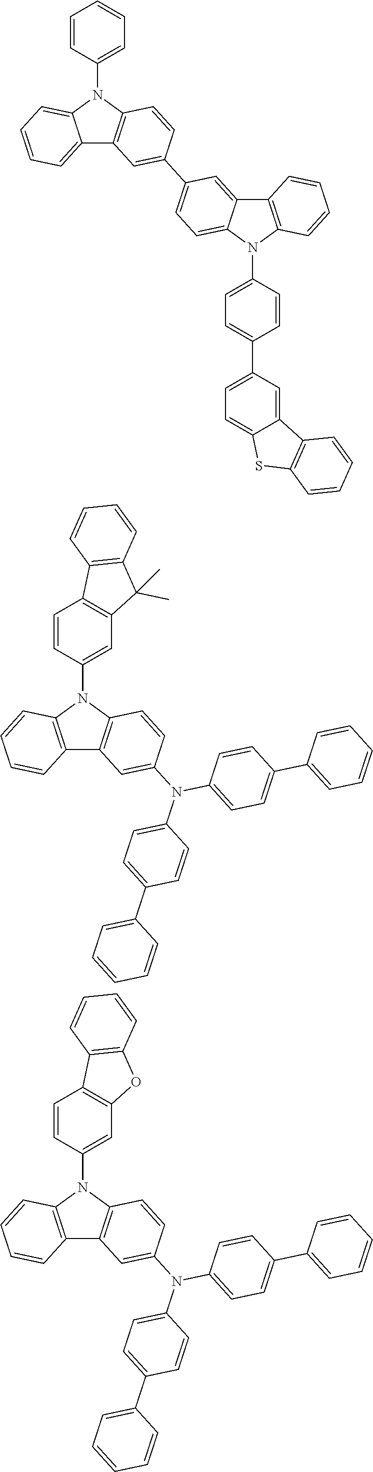

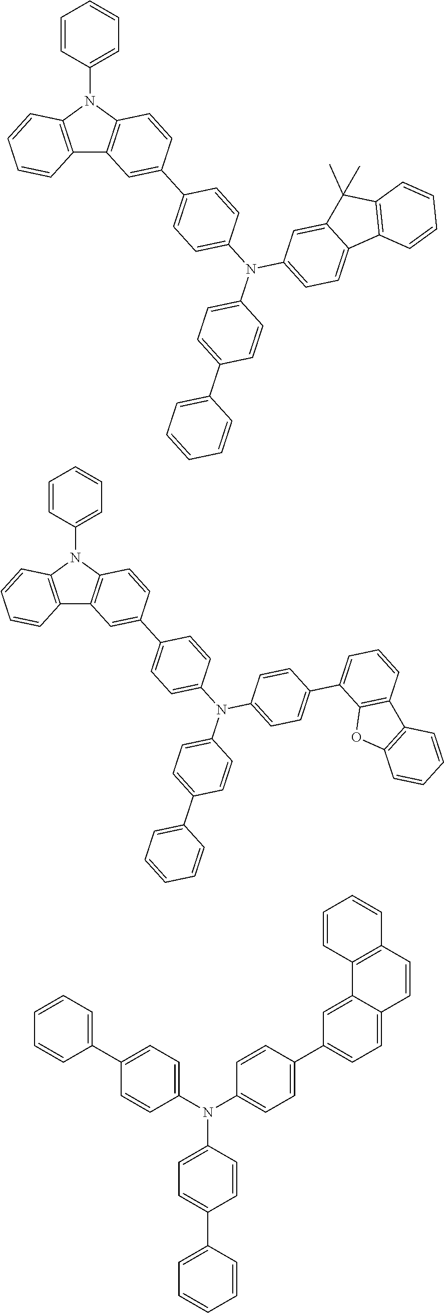 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc(-c4cccc5c4oc4ccccc45)cc3)cc2)cc1 ; c1ccc(-c2ccc(N(c3ccc(-c4ccccc4)cc3)c3ccc(-c4ccc5ccc6ccccc6c5c4)cc3)cc2)cc1]

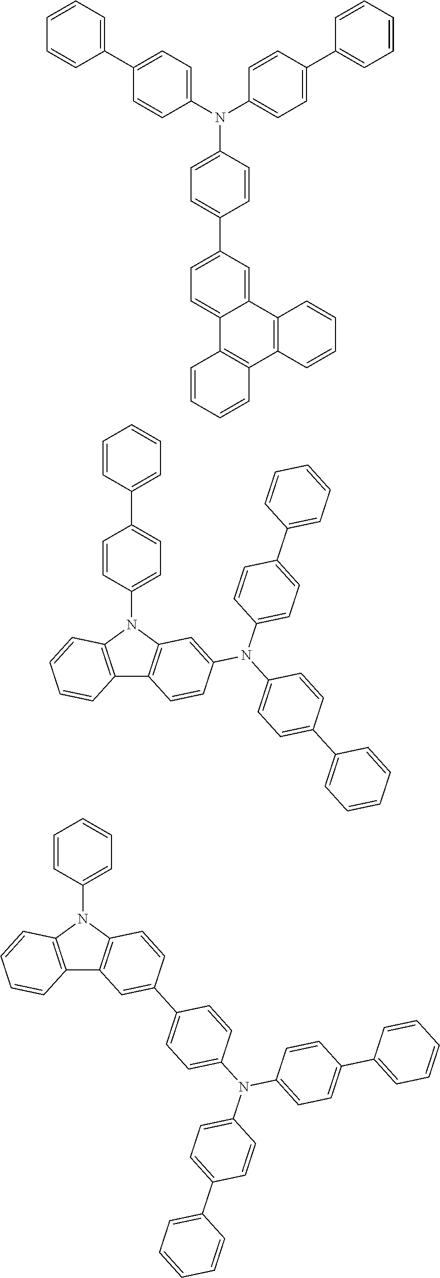 [SMILES: c1ccc(-c2ccc(N(c3ccc(-c4ccccc4)cc3)c3ccc(-c4ccc5c6ccccc6c6ccccc6c5c4)cc3)cc2)cc1 ; c1ccc(-c2ccc(N(c3ccc(-c4ccccc4)cc3)c3ccc4c5ccccc5n(-c5ccc(-c6ccccc6)cc5)c4c3)cc2)cc1 ; c1ccc(-c2ccc(N(c3ccc(-c4ccccc4)cc3)c3ccc(-c4ccc5c(c4)c4ccccc4n5-c4ccccc4)cc3)cc2)cc1]

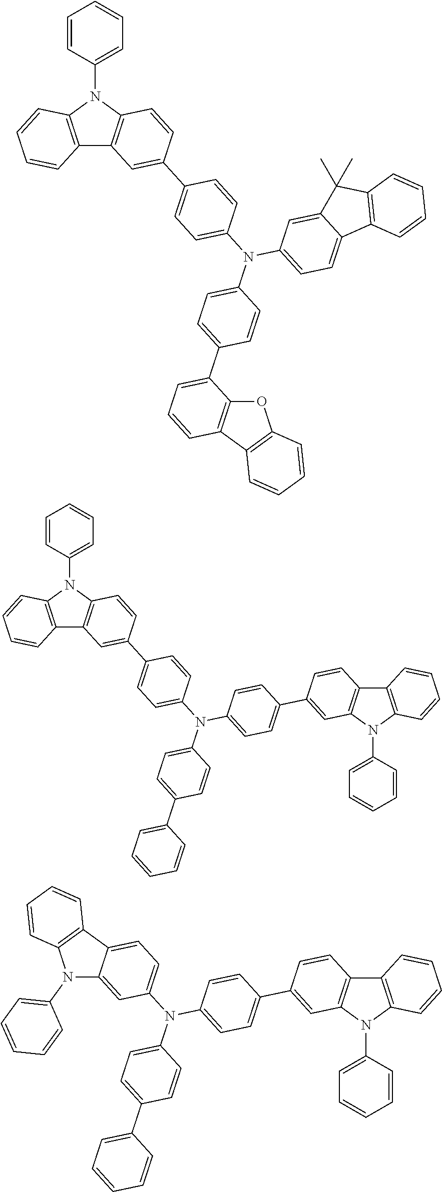 [SMILES: CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21 ; c1ccc(-c2ccc(N(c3ccc(-c4ccc5c(c4)c4ccccc4n5-c4ccccc4)cc3)c3ccc(-c4ccc5c6ccccc6n(-c6ccccc6)c5c4)cc3)cc2)cc1 ; c1ccc(-c2ccc(N(c3ccc(-c4ccc5c6ccccc6n(-c6ccccc6)c5c4)cc3)c3ccc4c5ccccc5n(-c5ccccc5)c4c3)cc2)cc1]

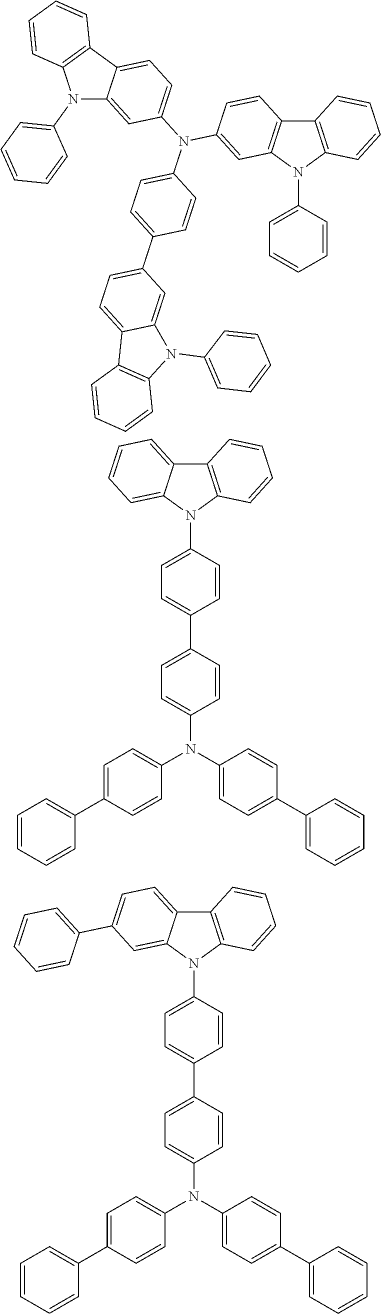

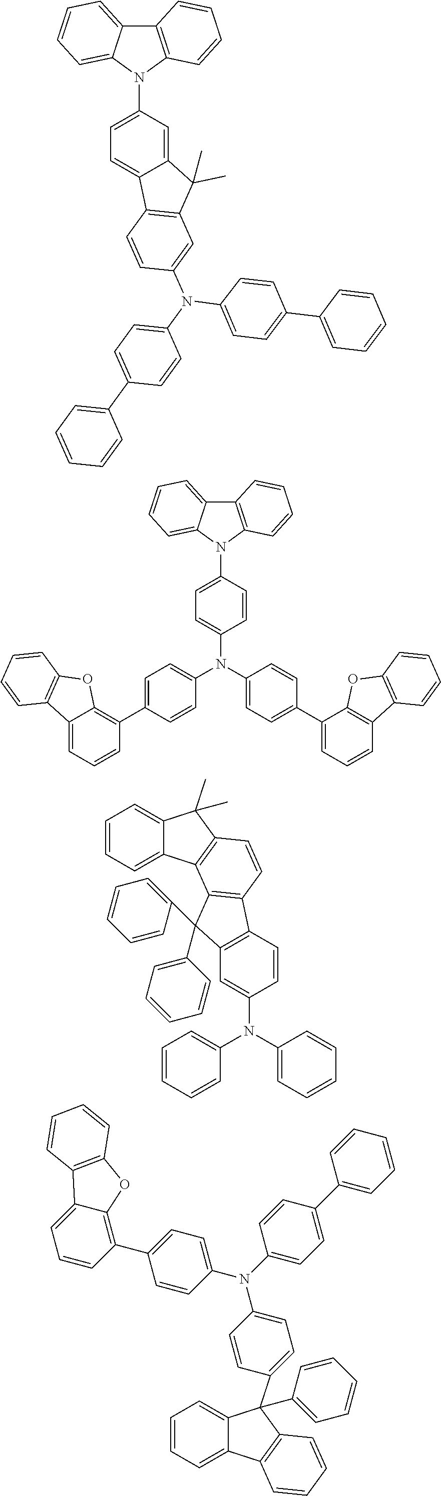 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; c1ccc2c(c1)oc1c(-c3ccc(N(c4ccc(-c5cccc6c5oc5ccccc56)cc4)c4ccc(-n5c6ccccc6c6ccccc65)cc4)cc3)cccc12 ; CC1(C)c2ccccc2-c2c1ccc1c2C(c2ccccc2)(c2ccccc2)c2cc(N(c3ccccc3)c3ccccc3)ccc2-1 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1]

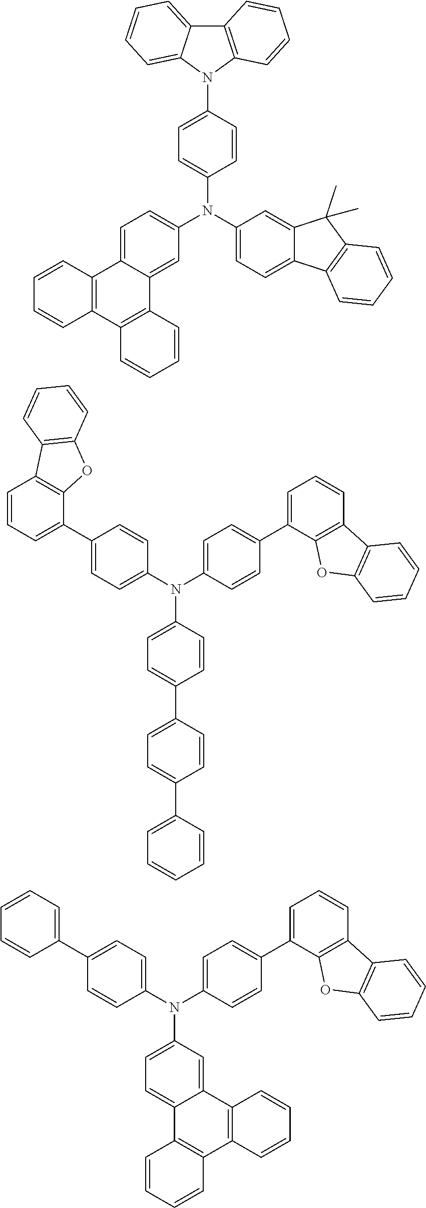 [SMILES: CC1(C)c2ccccc2-c2ccc(N(c3ccc(-n4c5ccccc5c5ccccc54)cc3)c3ccc4c5ccccc5c5ccccc5c4c3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4oc4ccccc45)cc3)c3ccc4c5ccccc5c5ccccc5c4c3)cc2)cc1]

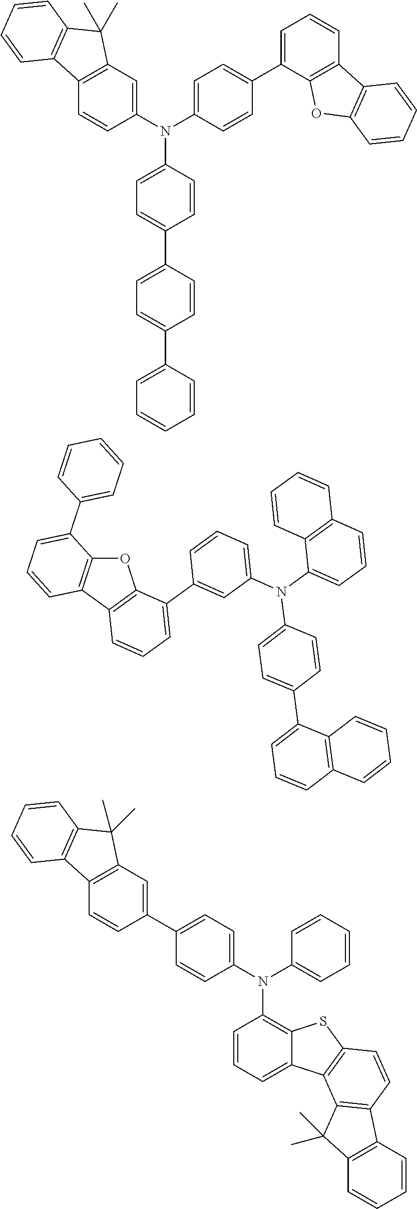

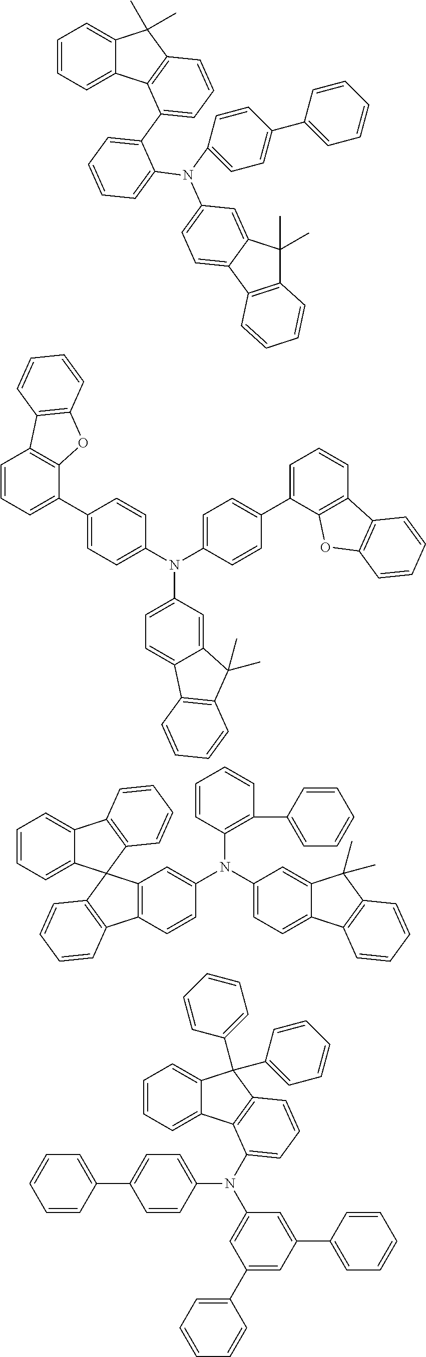

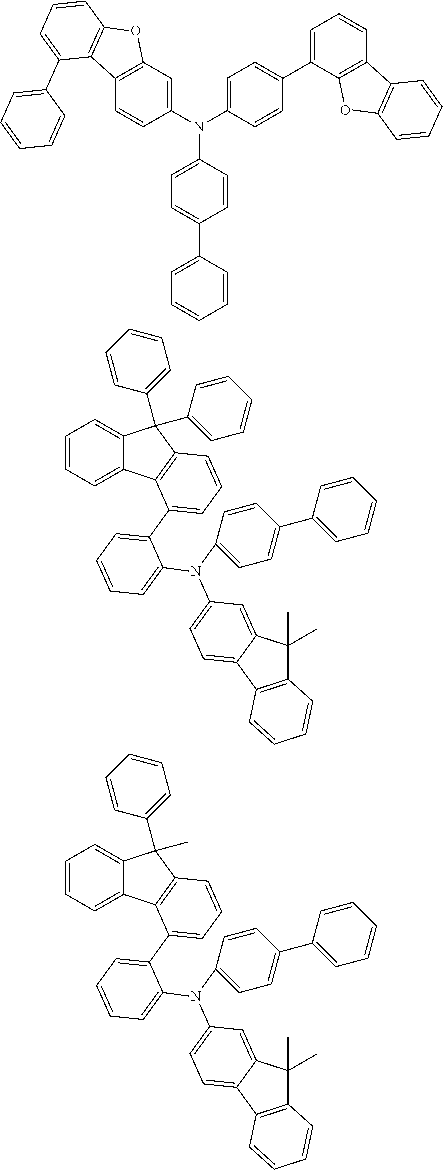

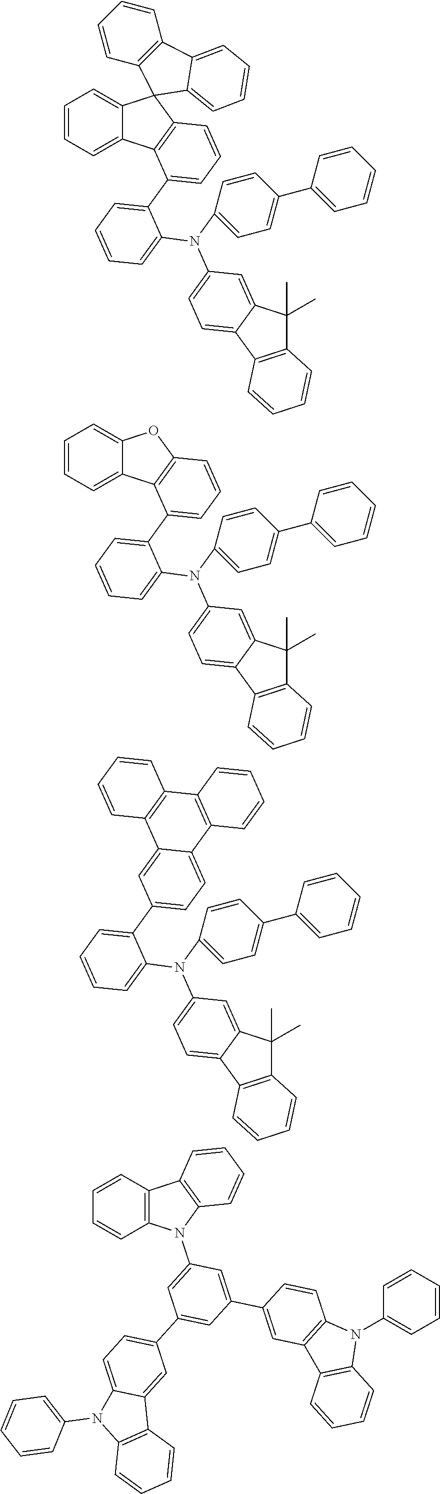

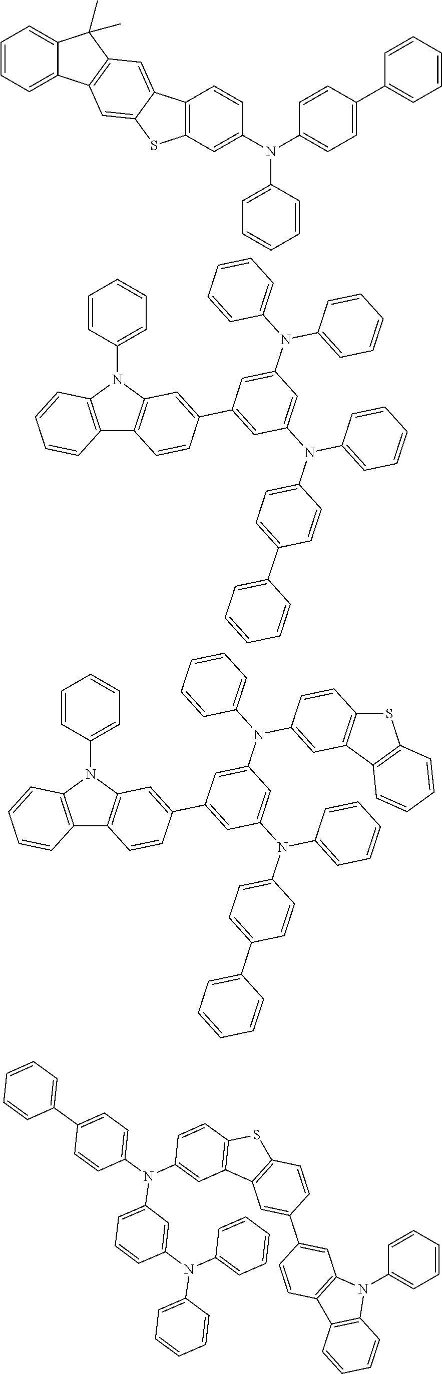

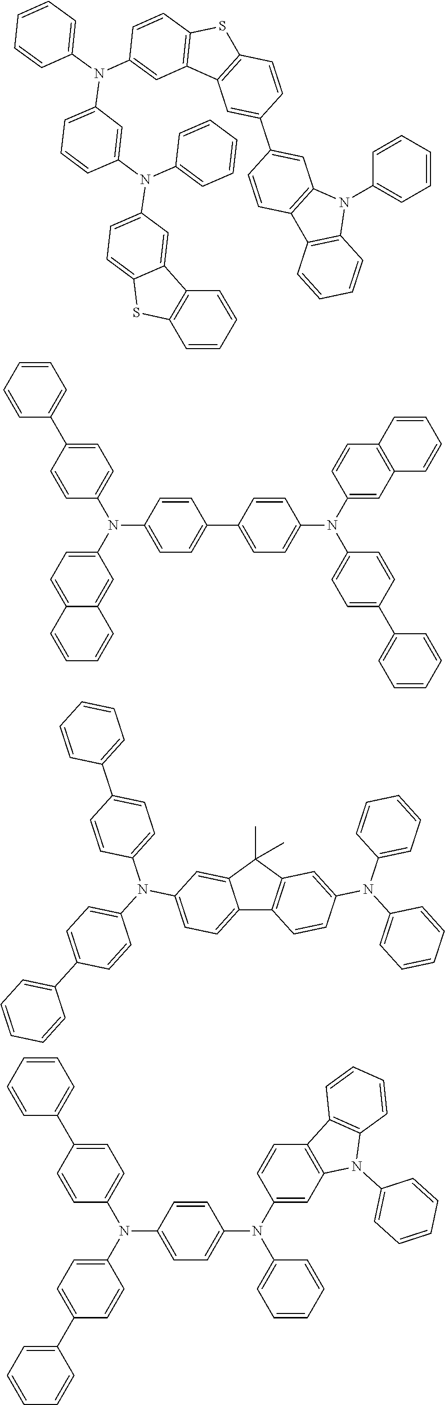

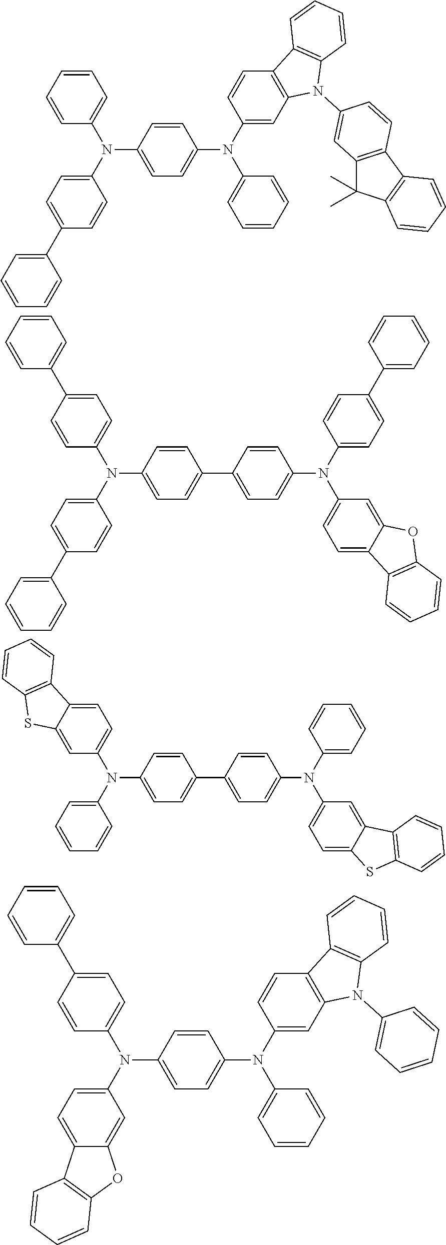

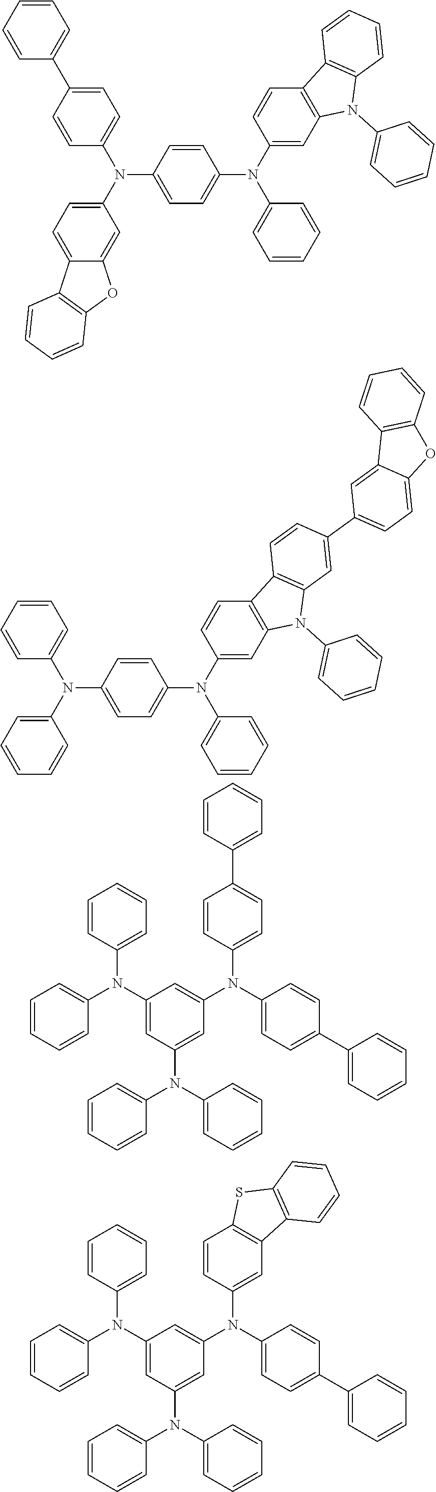

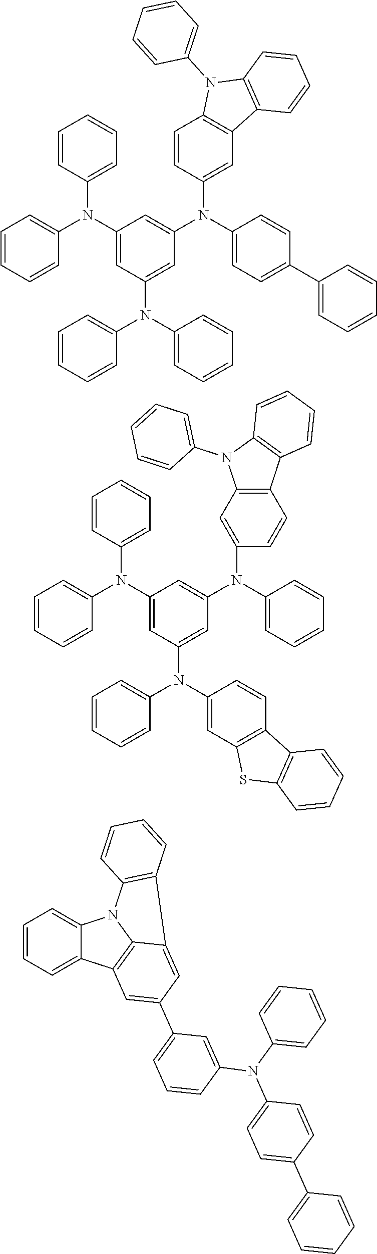

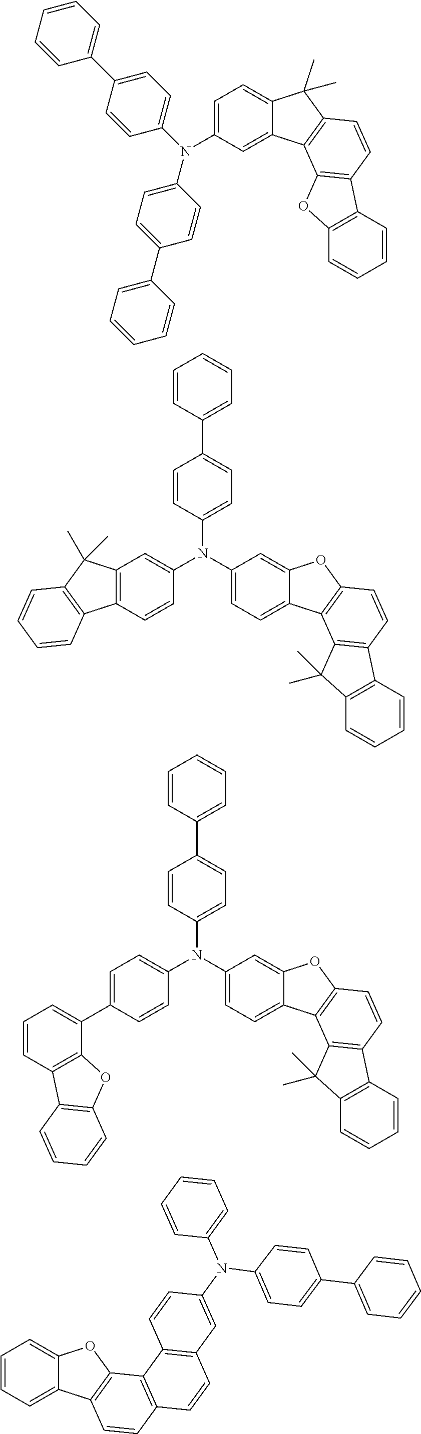

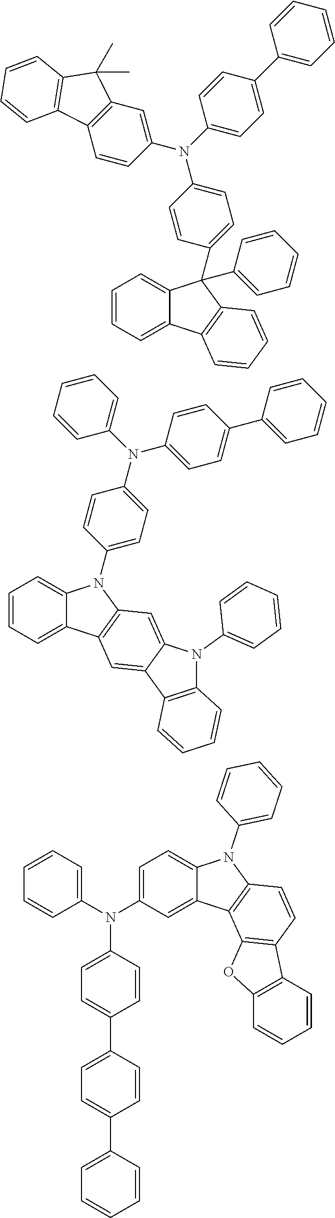

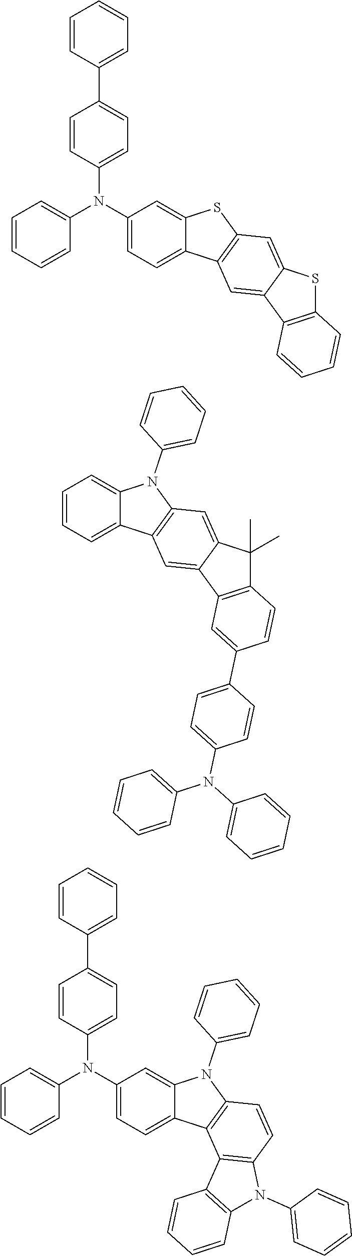 [SMILES: c1ccc(-c2ccc(N(c3ccccc3)c3ccc4c(c3)sc3cc5sc6ccccc6c5cc34)cc2)cc1 ; CC1(C)c2ccc(-c3ccc(N(c4ccccc4)c4ccccc4)cc3)cc2-c2cc3c4ccccc4n(-c4ccccc4)c3cc21 ; c1ccc(-c2ccc(N(c3ccccc3)c3ccc4c5c6c7ccccc7n(-c7ccccc7)c6ccc5n(-c5ccccc5)c4c3)cc2)cc1]

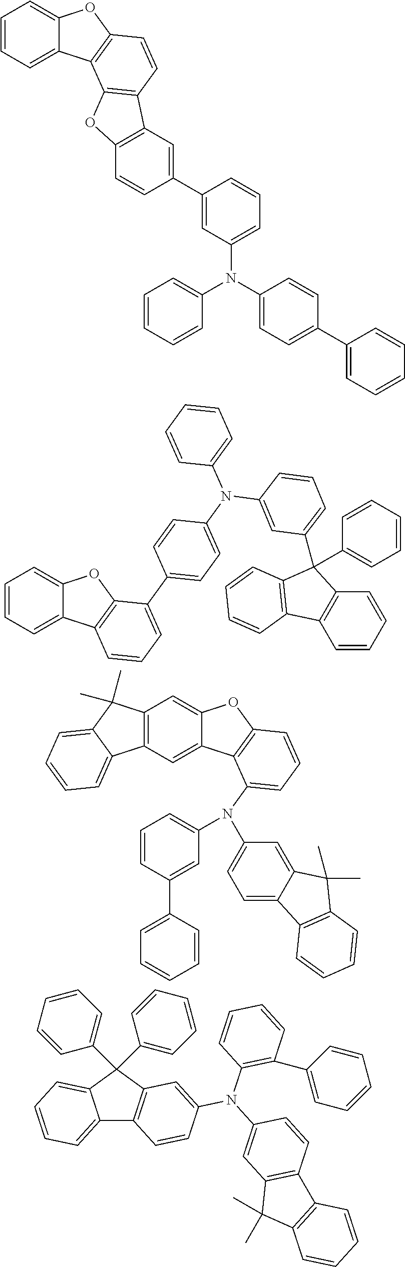

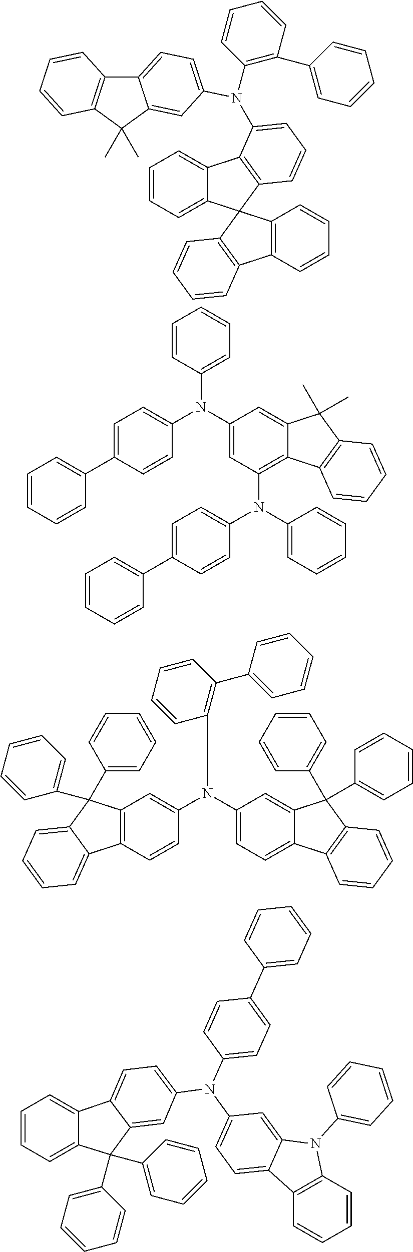

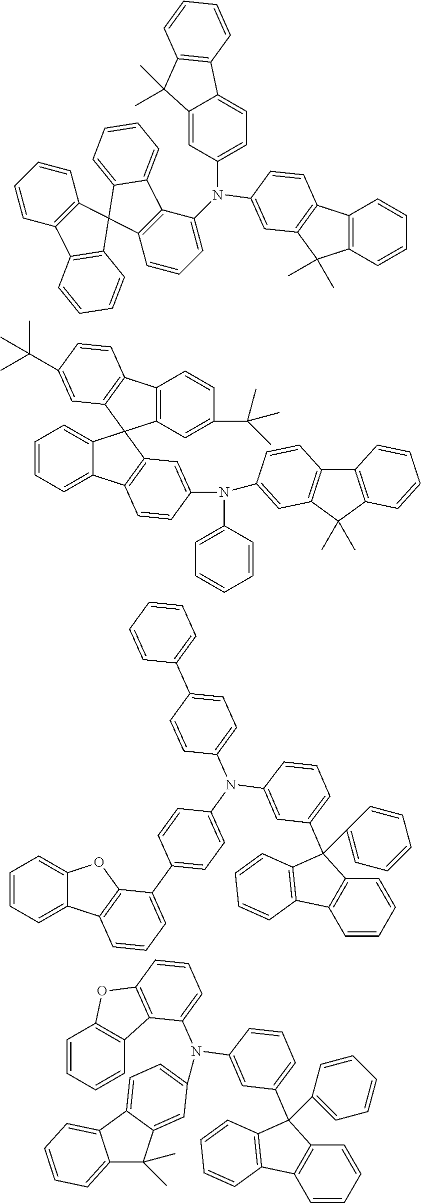

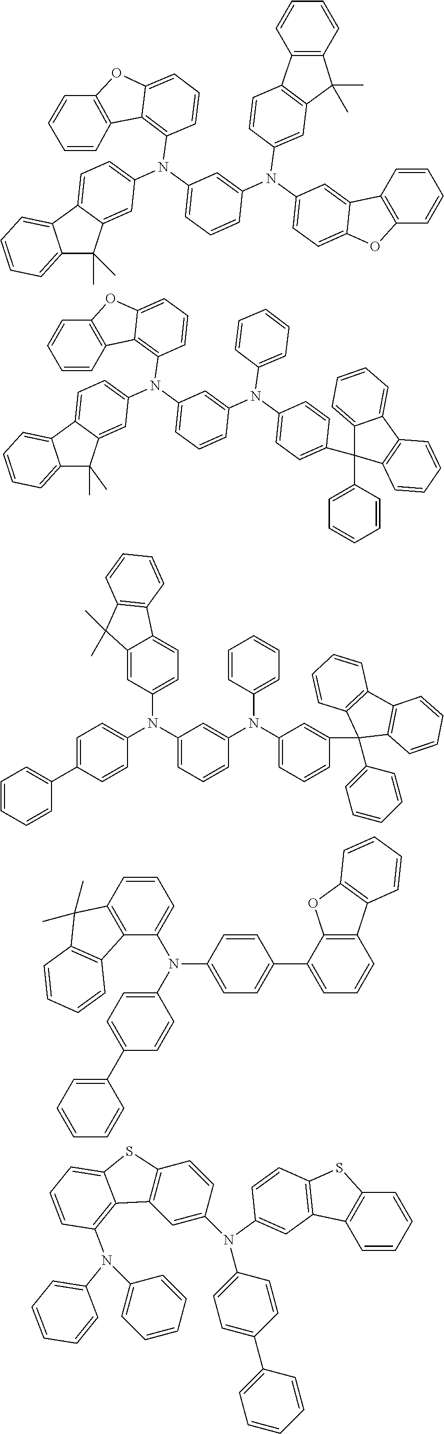

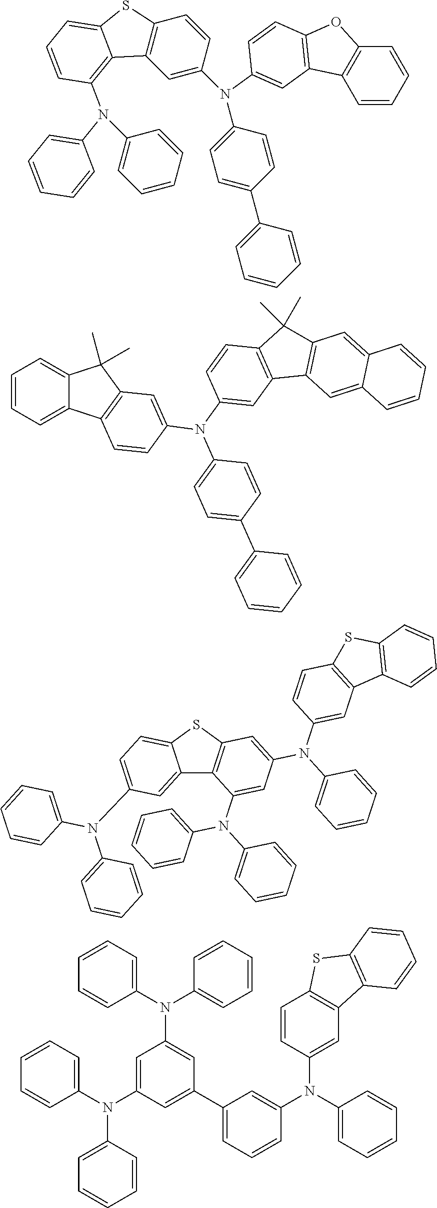

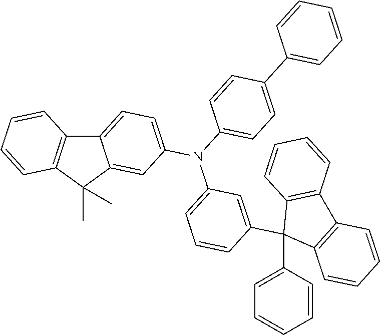 [SMILES: CC1(C)c2ccccc2-c2ccc(N(c3ccc(-c4ccccc4)cc3)c3cccc(C4(c5ccccc5)c5ccccc5-c5ccccc54)c3)cc21]

In the hole transport region, in addition to the compounds described above, known compounds disclosed in U.S. Pat. No. 5,061,569A, JP1993-009471A, WO1995-009147A1, JP1995-126615A, JP1998-095973A, etc. and compounds having a similar structure may also be used.

Also, the charge transport region may be, for example, the electron transport region 150.

The electron transport region 150 may further increase electron injection and/or electron mobility and block holes between the cathode 110 and the light emitting layer 130.

Specifically, the electron transport region 150 may include an electron transport layer between the cathode 110 and the light emitting layer 130, and an electron transport auxiliary layer between the light emitting layer 130 and the electron transport layer, and at least one of the compounds of Group C may be included in at least one of the electron transport layer and the electron transport auxiliary layer.

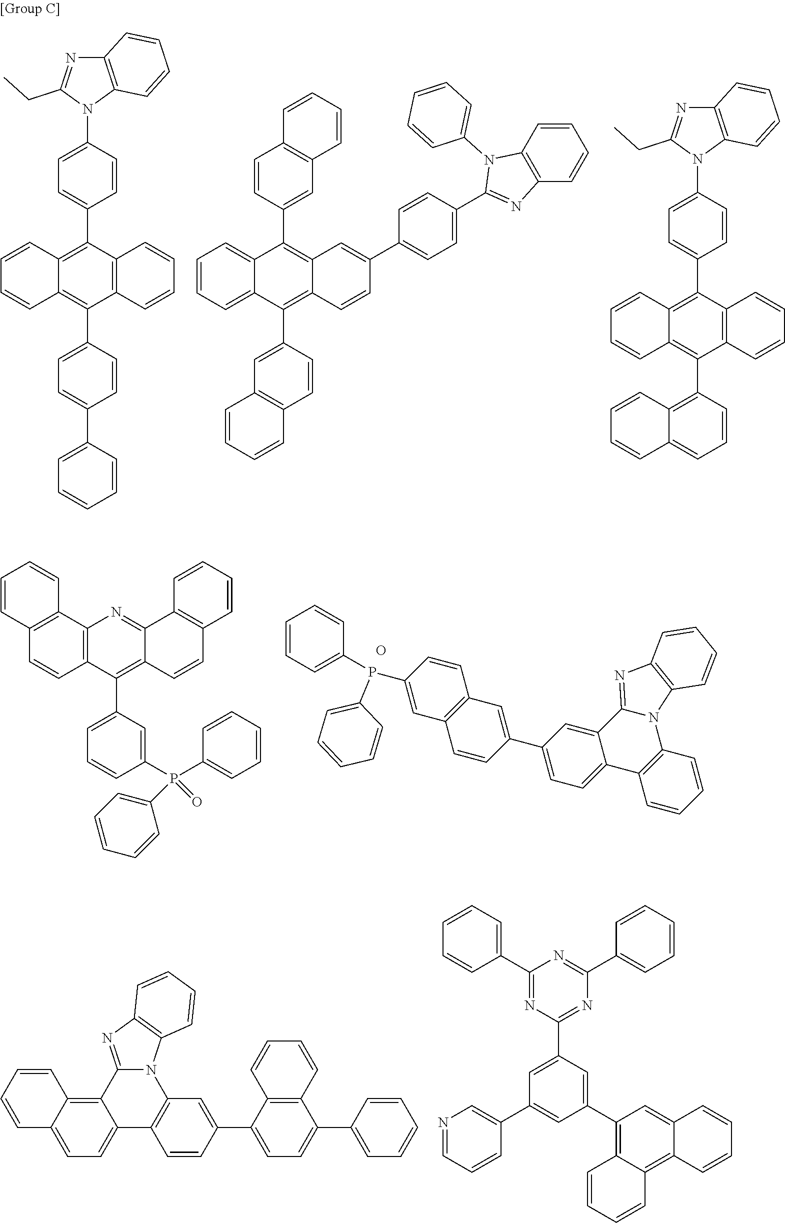

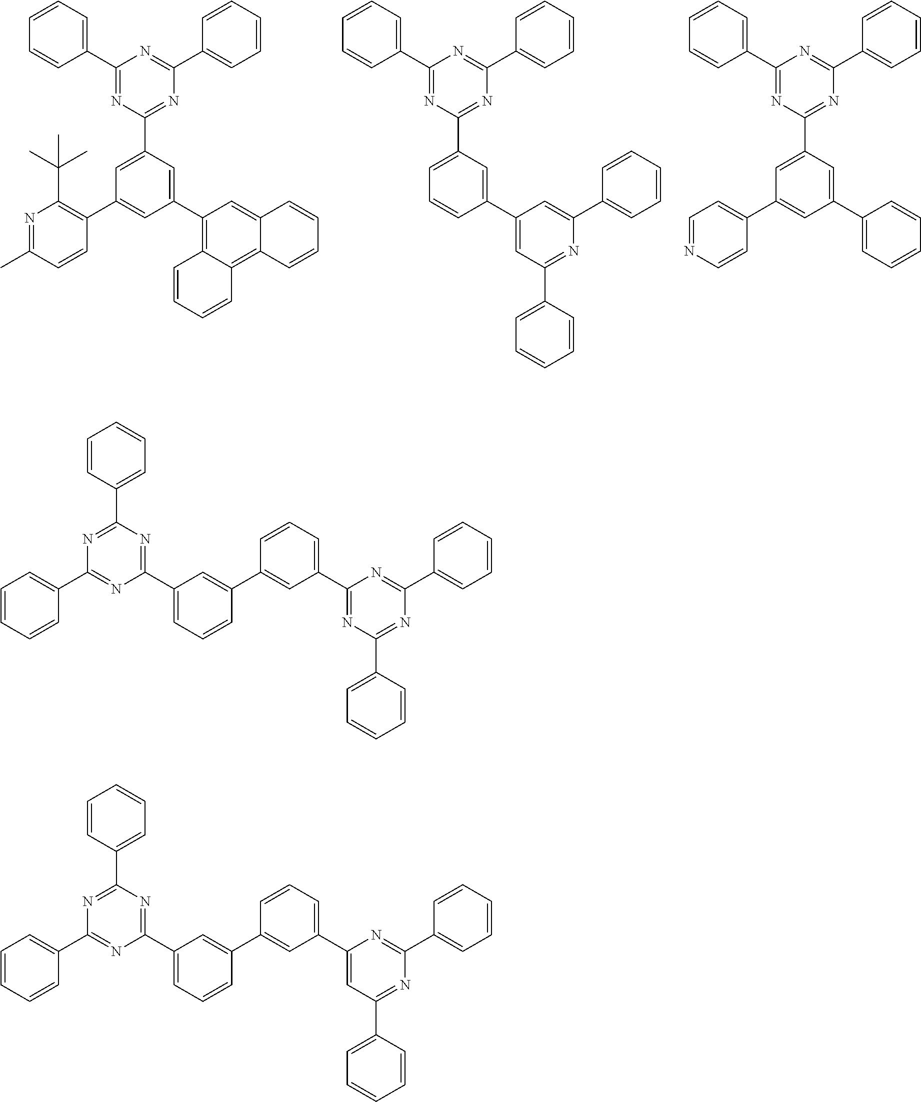

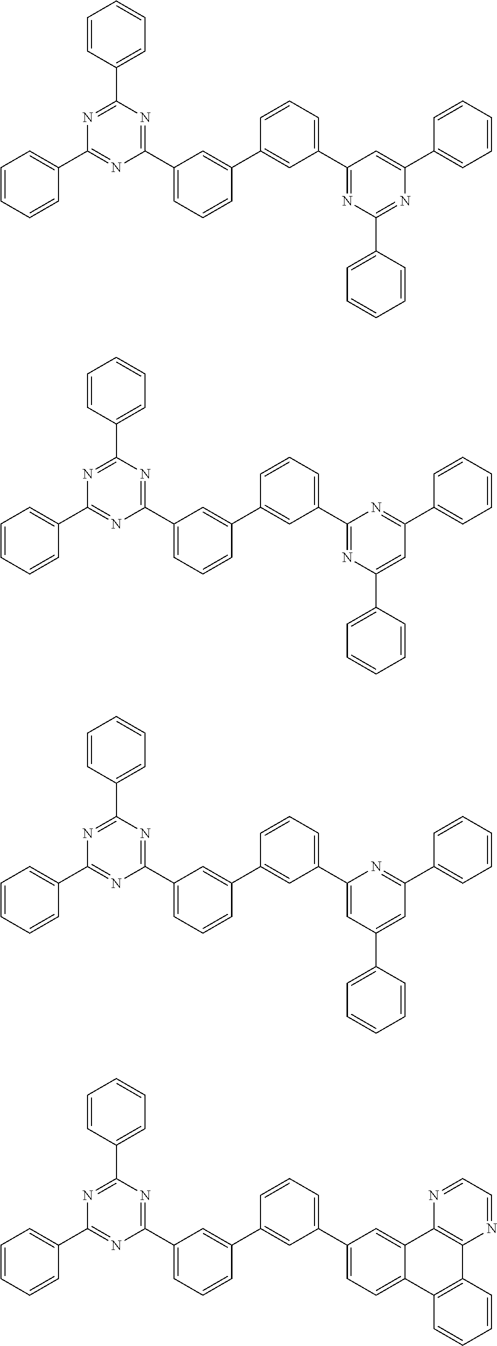 [SMILES: c1ccc(-c2cc(-c3cccc(-c4cccc(-c5nc(-c6ccccc6)nc(-c6ccccc6)n5)c4)c3)nc(-c3ccccc3)n2)cc1 ; c1ccc(-c2cc(-c3ccccc3)nc(-c3cccc(-c4cccc(-c5nc(-c6ccccc6)nc(-c6ccccc6)n5)c4)c3)n2)cc1 ; c1ccc(-c2cc(-c3ccccc3)nc(-c3cccc(-c4cccc(-c5nc(-c6ccccc6)nc(-c6ccccc6)n5)c4)c3)c2)cc1 ; c1ccc(-c2nc(-c3ccccc3)nc(-c3cccc(-c4cccc(-c5ccc6c7ccccc7c7nccnc7c6c5)c4)c3)n2)cc1]

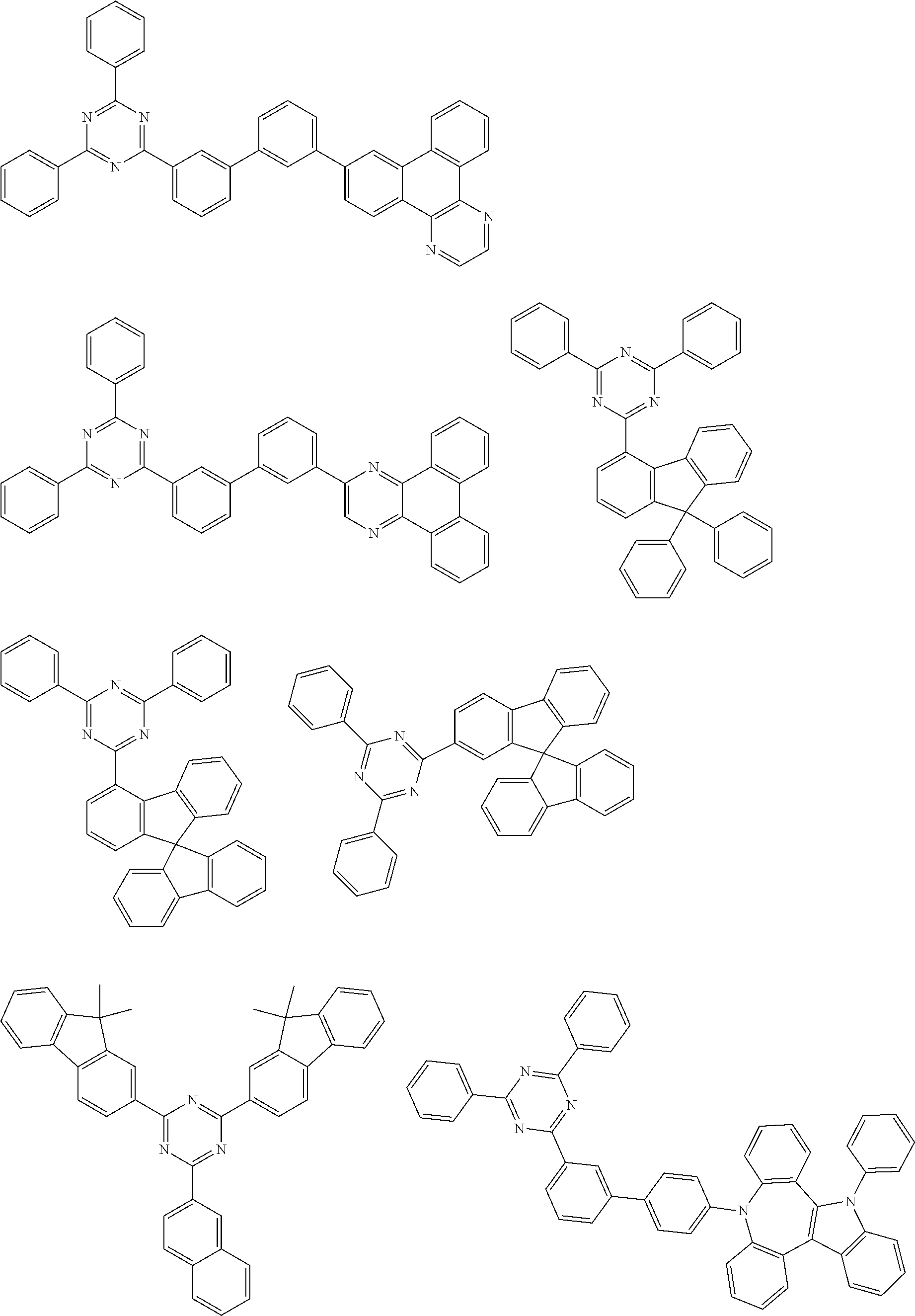

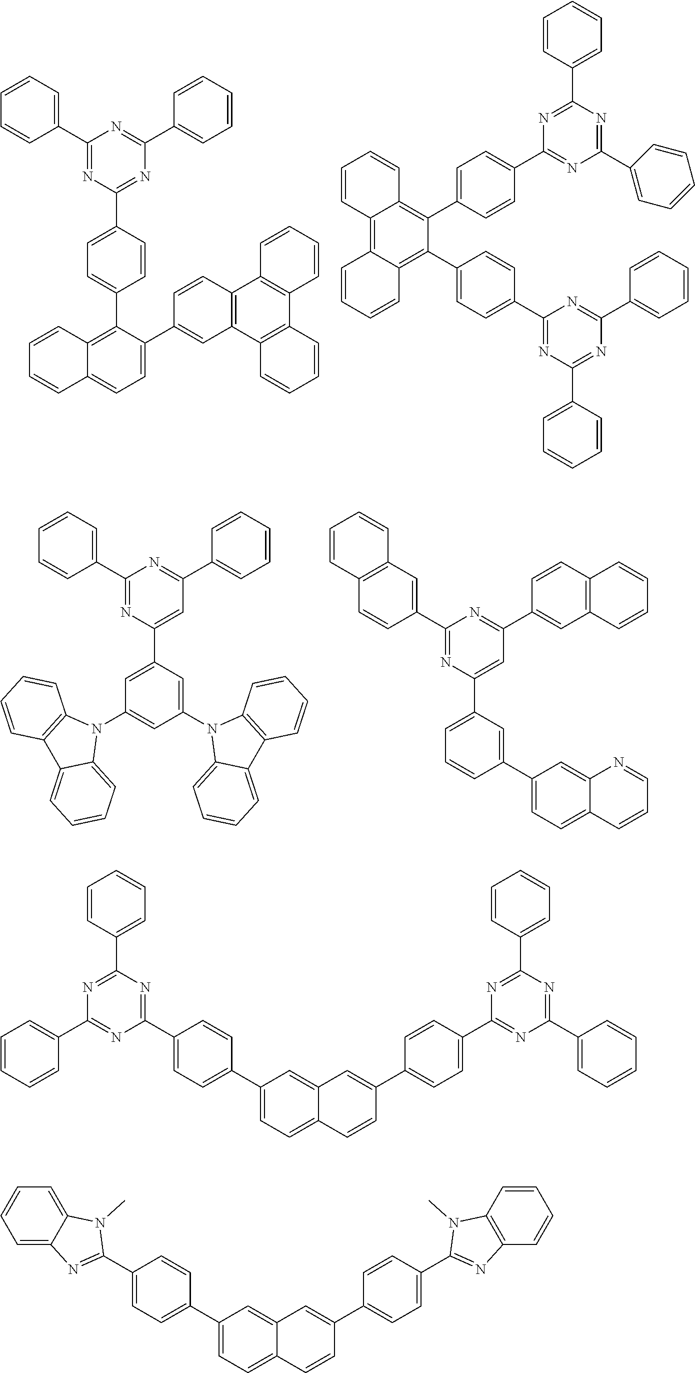

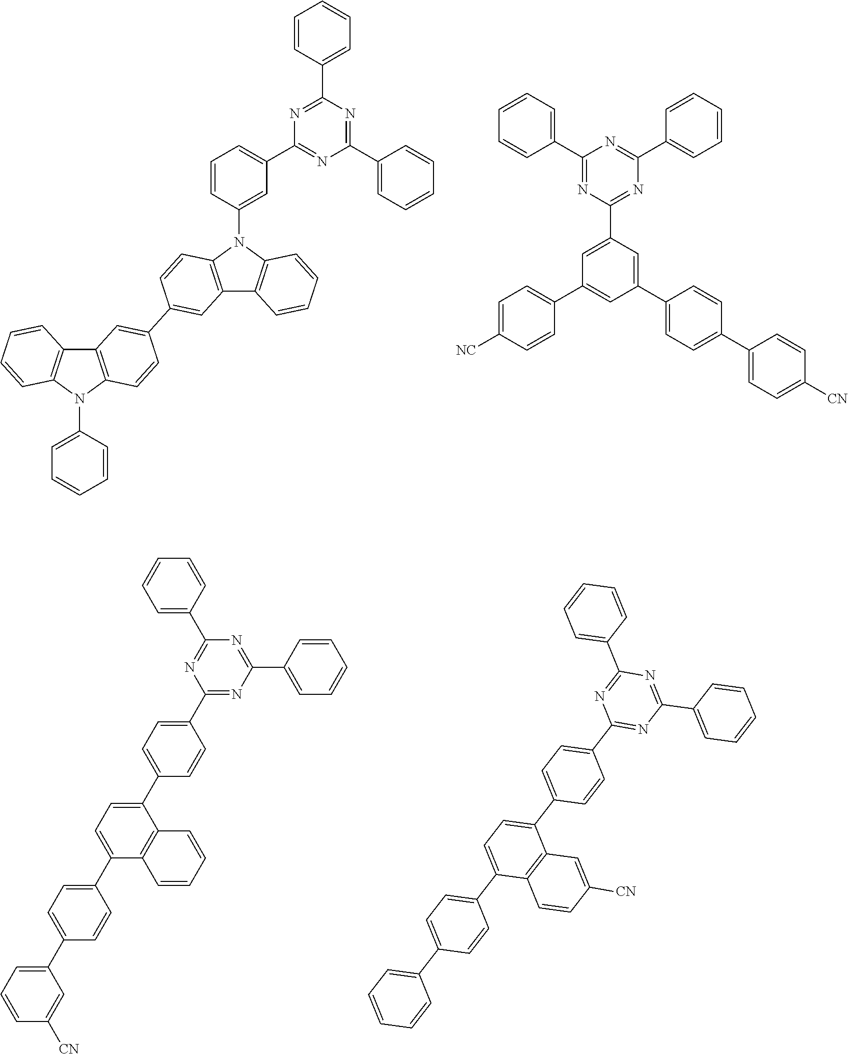 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; N#Cc1ccc(-c2ccc(-c3cc(-c4ccc(C#N)cc4)cc(-c4nc(-c5ccccc5)nc(-c5ccccc5)n4)c3)cc2)cc1 ; N#Cc1cccc(-c2ccc(-c3ccc(-c4ccc(-c5nc(-c6ccccc6)nc(-c6ccccc6)n5)cc4)c4ccccc34)cc2)c1 ; N#Cc1ccc2c(-c3ccc(-c4ccccc4)cc3)ccc(-c3ccc(-c4nc(-c5ccccc5)nc(-c5ccccc5)n4)cc3)c2c1]

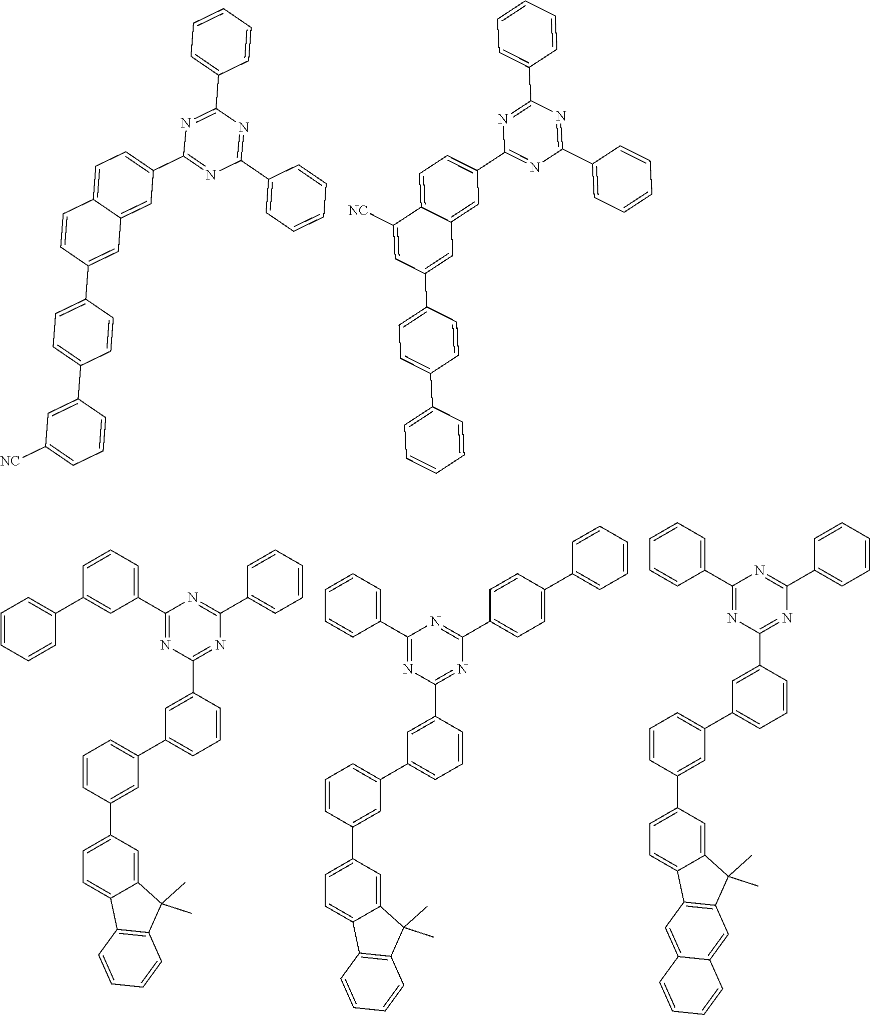

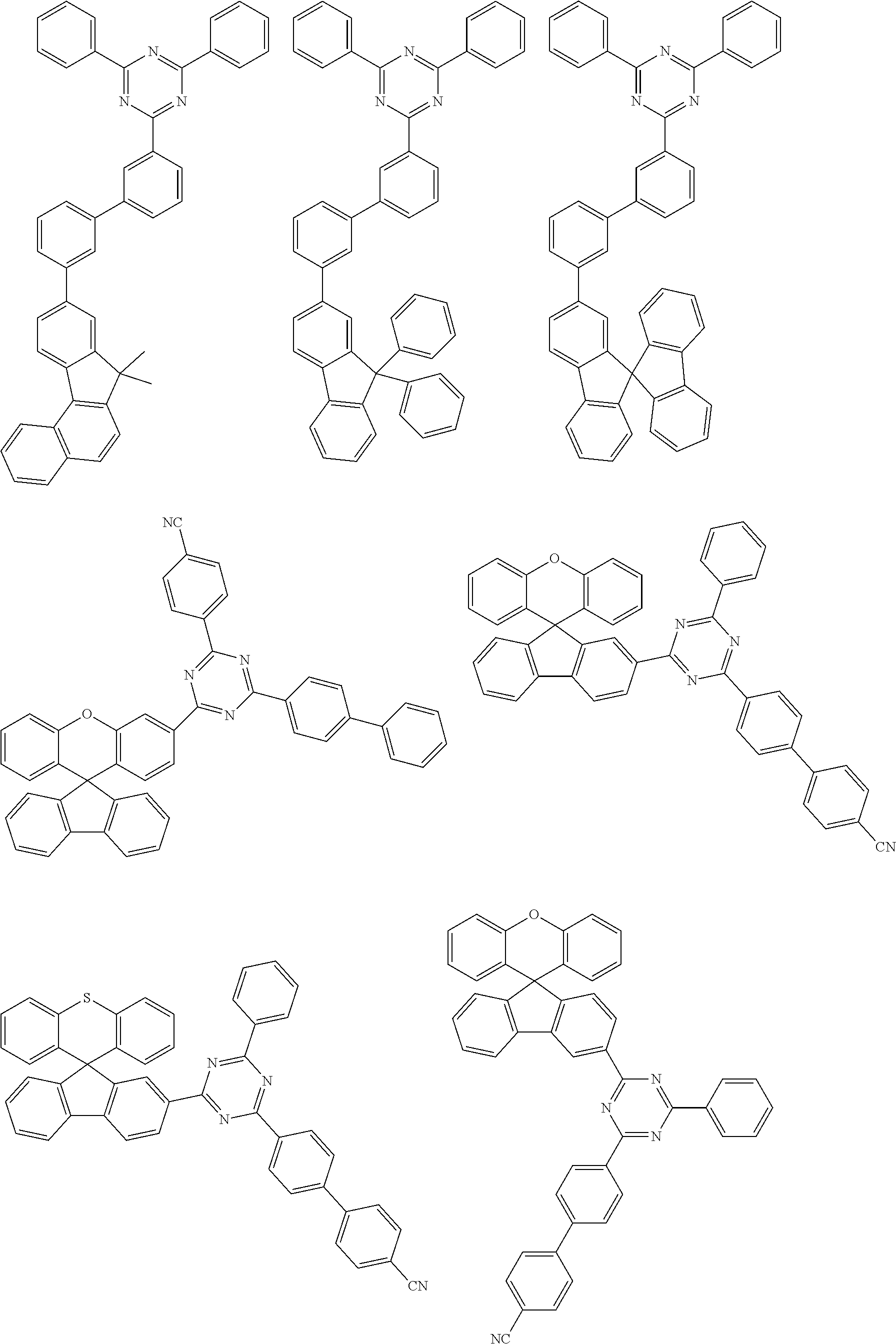

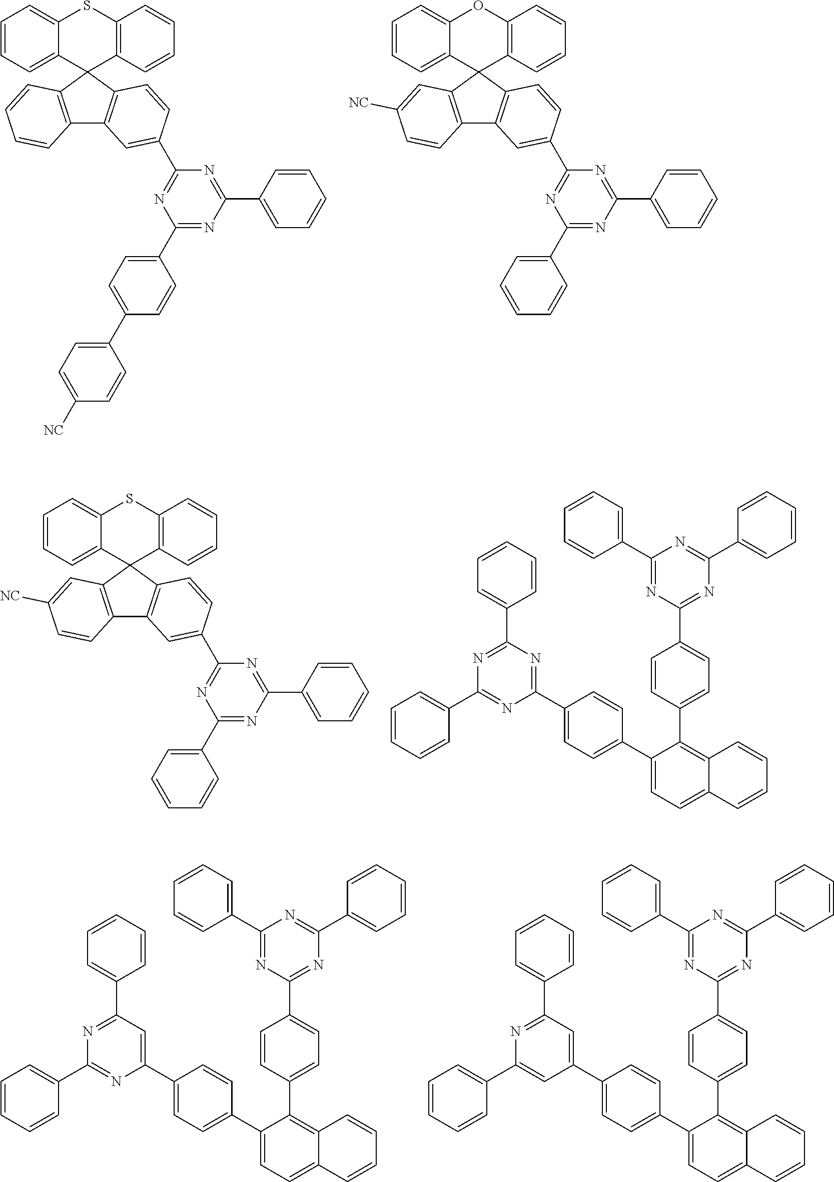

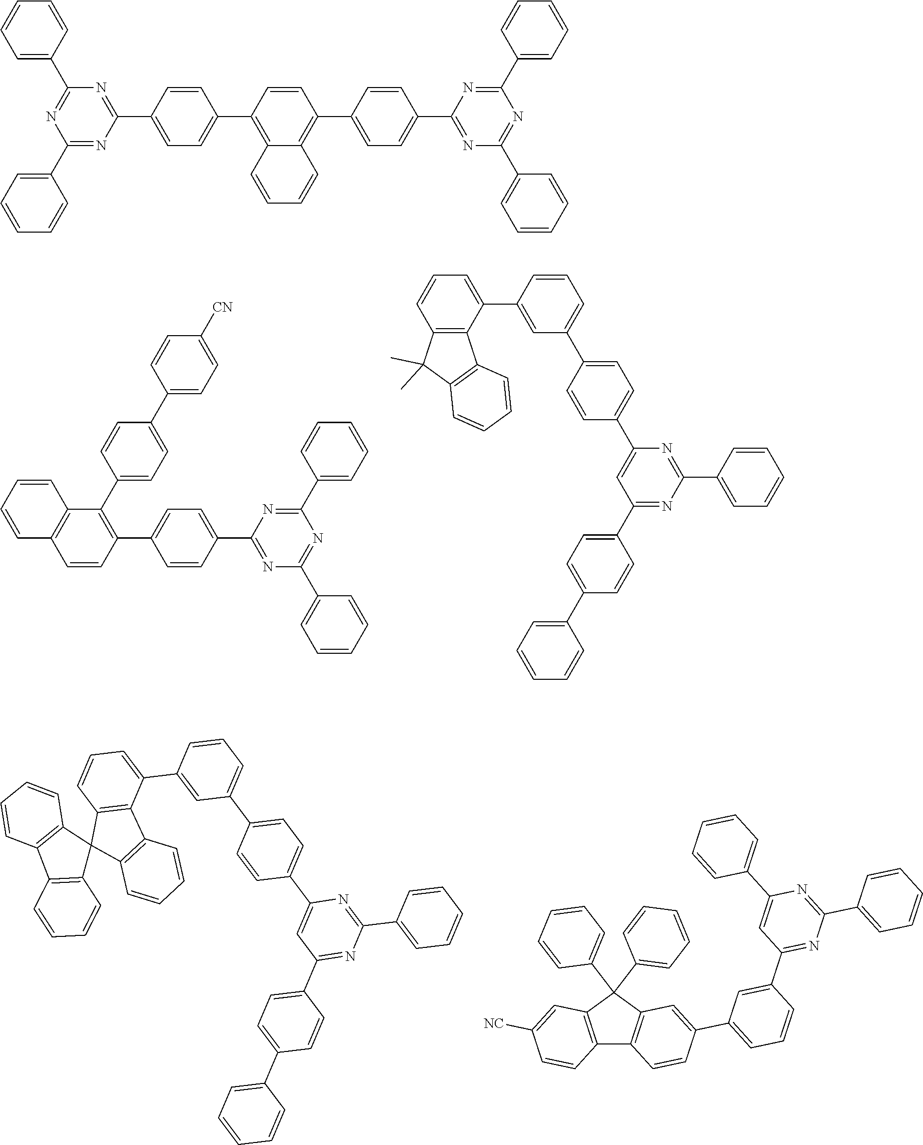

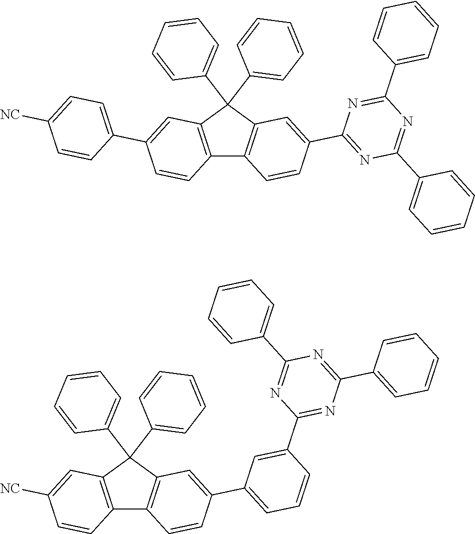 [SMILES: N#Cc1ccc(-c2ccc3c(c2)C(c2ccccc2)(c2ccccc2)c2cc(-c4nc(-c5ccccc5)nc(-c5ccccc5)n4)ccc2-3)cc1 ; N#Cc1ccc2c(c1)C(c1ccccc1)(c1ccccc1)c1cc(-c3cccc(-c4nc(-c5ccccc5)nc(-c5ccccc5)n4)c3)ccc1-2]

An embodiment of the present invention may provide an organic light emitting diode including the light emitting layer as the organic layer.

Another embodiment of the present invention may provide an organic light emitting diode including a light emitting layer and a hole transport region as the organic layer.

Another embodiment of the present invention may provide an organic light emitting diode including a light emitting layer and an electron transport region as the organic layer.

Another embodiment of the present invention may provide an organic light emitting diode including a hole transport region 140 and an electron transport region 150 in addition to the light emitting layer 130 as the organic layer 105, as shown in FIG. 1.

On the other hand, an organic light emitting diode may further include an electron injection layer (not shown), a hole injection layer (not shown), etc. in addition to the light emitting layer as the organic layer.

The organic light emitting diodes 100 may be manufactured by forming an anode or a cathode on a substrate, and then forming an organic layer by a dry film method such as vacuum deposition, sputtering, plasma plating and ion plating, and forming a cathode or an anode thereon.

The organic light emitting diode may be applied to an organic light emitting display device.

### MODE FOR INVENTION

Hereinafter, the embodiments are illustrated in more detail with reference to examples. However, these examples are exemplary, and the scope of claims is not limited thereto.

### Synthesis of First Compound

### Synthesis Example 1: Synthesis of Intermediate Int-6

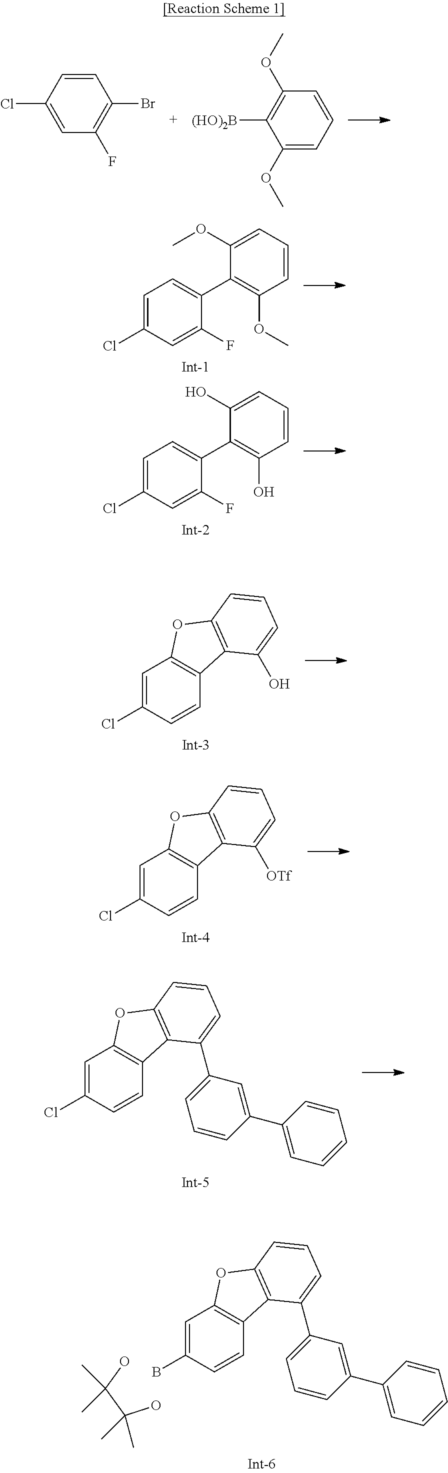

### 1st Step: Synthesis of Intermediate Int-1

11-bromo-4-chloro-2-fluorobenzene (61 g, 291 mmol), 2,6-dimethoxyphenylboronic acid (50.4 g, 277 mmol), K₂CO₃ (60.4 g, 437 mmol), and Pd(PPh₃)₄(10.1 g, 8.7 mmol) were dissolved in THE (500 ml) and distilled water (200 ml) in a round-bottomed flask and then, stirred under reflux at 60° C. for 12 hours. When a reaction was completed, after removing an aqueous layer therefrom, column chromatography (hexane:DCM (20%)) was conducted, obtaining 38 g (51%) of Intermediate Int-1.

### 2nd Step: Synthesis of Intermediate Int-2

Intermediate Int-1 (38 g, 142 mmol) and pyridine hydrochloride (165 g, 1425 mmol) were placed in a round-bottomed flask and stirred under reflux at 200° C. for 24 hours. When a reaction was completed, the resultant was cooled to room temperature and slowly poured into distilled water and then, stirred for 1 hour. A solid was filtered therefrom, obtaining 23 g (68%) of Intermediate Int-2.

### 3rd Step: Synthesis of Intermediate Int-3

Intermediate Int-2 (23 g, 96 mmol) and K₂CO₃ (20 g, 144 mmol) were dissolved in NMP (100 ml) in a round bottomed flask and then, stirred under reflux at 180° C. for 12 hours. When a reaction was completed, the mixture was poured into an excessive amount of distilled water. A solid was filtered therefrom, dissolved in ethyl acetate, and dried with MgSO₄, and an organic layer was removed therefrom under a reduced pressure. Column chromatography (hexane:ethyl acetate 30%) was performed, obtaining 16 g (76%) of Intermediate Int-3.

### 4th Step: Synthesis of Intermediate Int-4

Intermediate Int-3 (16 g, 73 mmol) and pyridine (12 m1, 146 mmol) were dissolved in DCM (200 ml) in a round-bottomed flask. After lowering the temperature to 0° C., trifluoromethanesulfonic anhydride (14.7 m1, 88 mmol) was slowly added thereto in a dropwise fashion. After stirring the obtained mixture for 6 hours, when a reaction was completed, an excessive amount of distilled water was added thereto and then, stirred for 30 minutes and extracted with DCM. After removing an organic solvent under a reduced pressure, the rest was vacuum-dried, obtaining 22.5 g (88%) of Intermediate Int-4.

### 5th Step: Synthesis of Intermediate Int-5

21 g (83%) of Intermediate Int-5 was synthesized in the same manner as the 1st step using Intermediate Int-4 (25 g, 71.29 mmol), 3-biphenylboronic acid (16.23 g, 81.78 mmol), K₂CO₃ (14.78 g, 106.93 mmol), and Pd(PPh₃)₄(4.12 g, 3.56 mmol).

### 6th Step: Synthesis of Intermediate Int-6

Intermediate Int-5 (21 g, 59.18 mmol), bis(pinacolato)diboron (19.54 g, 76.94 mmol), Pd(dppf)Cl₂ (2.42 g, 2.96 mmol), tricyclohexylphosphine (3.32 g, 11.84 mmol) and potassium acetate (11.62 g, 118.37 mmol) were dissolved in DMF (dimethylformamide, 320 ml) in a round-bottomed flask. The mixture was stirred under reflux at 120° C. for 10 hours. When a reaction was completed, the mixture was poured into an excessive amount of distilled water and then, stirred for 1 hour. A solid was filtered therefrom and then, dissolved in DCM. MgSO₄ was used to remove moisture therefrom, and an organic solvent was filtered with a silica gel pad and removed under a reduced pressure. The solid was recrystallized with ethyl acetate and hexane, obtaining 18.49 g (70%) of Intermediate Int-6.

### Synthesis Example 2: Synthesis of Intermediate Int-14

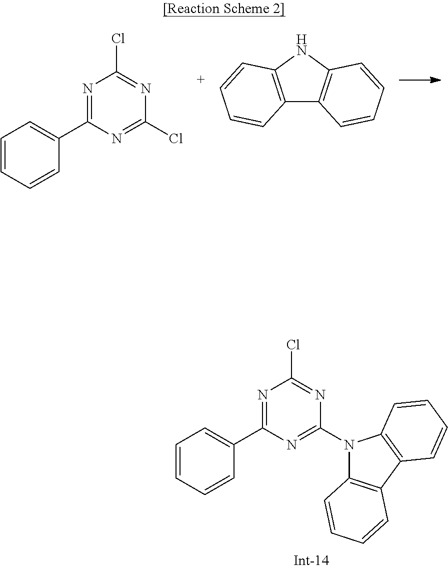 [SMILES: Clc1nc(Cl)nc(-c2ccccc2)n1 ; c1ccc2c(c1)[nH]c1ccccc12 ; Clc1nc(-c2ccccc2)nc(-n2c3ccccc3c3ccccc32)n1]

2,4-dichloro-6-phenyl-1,3,5-triazine (30 g, 132.71 mmol), carbazole (17.75 g, 106.17 mmol), and sodium tert-butoxide (14.03 g, 145.98 mmol) were placed in a round-bottomed flask and stirred with THE (650 ml) at room temperature for 12 hours. A solid produced therein was filtered and stirred in an aqueous layer for 30 minutes. After the filtering, a product therefrom was dried, obtaining 20 g (42%) of Intermediate Int-14.

### Synthesis Example 3: Synthesis of Compound 1-27

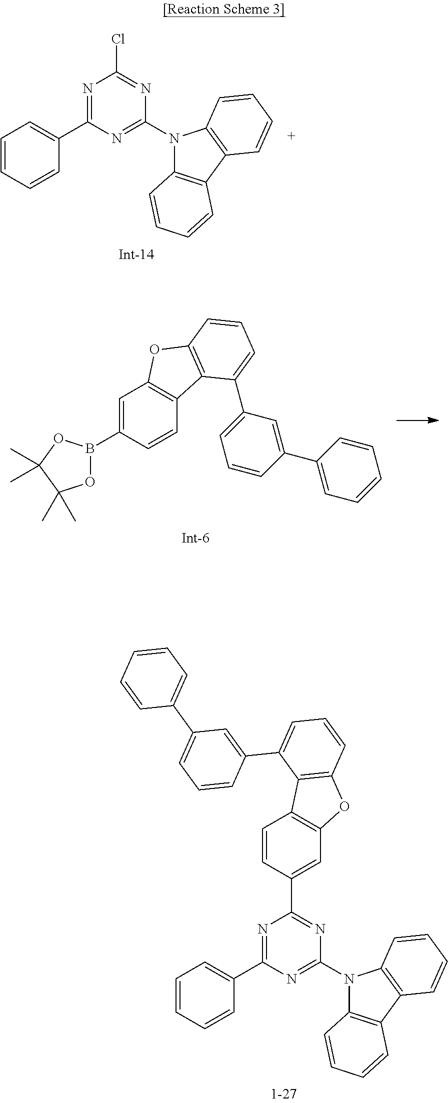 [SMILES: Clc1nc(-c2ccccc2)nc(-n2c3ccccc3c3ccccc32)n1 ; CC1(C)OB(c2ccc3c(c2)oc2cccc(-c4cccc(-c5ccccc5)c4)c23)OC1(C)C ; c1ccc(-c2cccc(-c3cccc4oc5cc(-c6nc(-c7ccccc7)nc(-n7c8ccccc8c8ccccc87)n6)ccc5c34)c2)cc1]

Intermediate Int-14 (9.5 g, 26.62 mmol), Intermediate Int-6 (14.26 g, 31.95 mmol), K₂CO₃(9.20 g, 66.56 mmol), and Pd(PPh₃)₄(1.54 g, 1.33 mmol) were placed in a round-bottomed flask and dissolved in THE (100 ml) and distilled water (40 ml) and then, stirred under reflux at 70° C. for 12 hours. When a reaction was completed, the mixture was added to 500 mL of methanol to crystallize a solid, and the solid was filtered, dissolved in monochlorobenzene, filtered with silica gel/Celite, and after removing an appropriate amount of an organic solvent, recrystallized with methanol, obtaining 13.14 g (77%) of Compound 1-27.

(LC/MS theoretical value: 640.23 g/mol, measured value: M+=641.39 g/mol)

### Synthesis Example 4: Synthesis of Compound 1-24

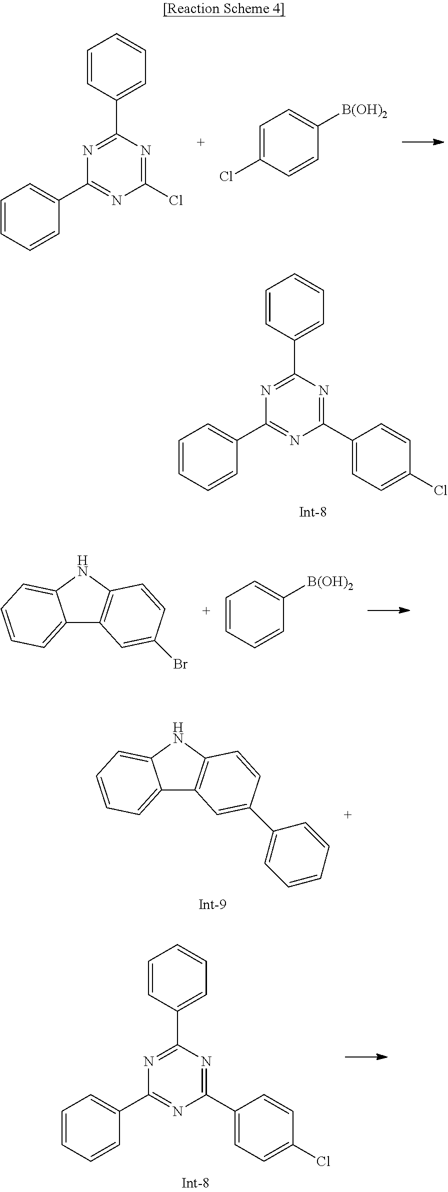

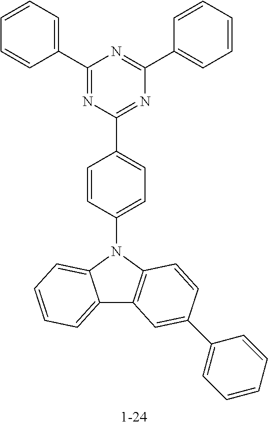 [SMILES: c1ccc(-c2ccc3c(c2)c2ccccc2n3-c2ccc(-c3nc(-c4ccccc4)nc(-c4ccccc4)n3)cc2)cc1]

### 1st Step: Synthesis of Intermediate Int-8

23.4 g (87.3 mmol) of 2-chloro-4,6-diphenyl-1,3,5-triazine was added to 100 mL of THF, 100 mL of toluene, and 100 mL of distilled water, and 0.9 equivalent of 4-chlorophenylboronic acid, 0.03 equivalent of Pd(PPh₃)₄, and 2 equivalent of K₂CO₃ were added to the solution and then, stirred under reflux under a nitrogen atmosphere for 6 hours. After removing an aqueous layer, an organic layer therefrom was dried under a reduced pressure. A solid obtained therefrom was washed with water and hexane and then, recrystallized with 200 mL of toluene to obtain 20 g (67%) of Intermediate Int-8.

### 2nd Step: Synthesis of Intermediate Int-9

35 g (142 mmol) of 3-bromo-9H-carbazole was dissolved in 500 mL of THF, and 17.3 g (142 mmol) of phenylboronic acid and 8.2 g (7.1 mmol) of Pd(PPh₃)₄ were added thereto and then, stirred. 49.1 g (356 mmol) of K₂CO₃ saturated in water was added thereto and then, stirred under reflux at 80° C. for 12 hours. When a reaction was completed, water was added to the reaction solution, and the mixture was extracted with DCM, treated with MgSO₄ to removed moisture, filtered, and concentrated under a reduced pressure. The obtained residue was separated and purified through column chromatography (hexane:DCM (20%)) to obtain 22.0 g (64%) of Intermediate Int-9.

### 3rd Step: Synthesis of Compound 1-24

22.0 g (90.4 mmol) of Intermediate Int-9, 31.1 g (90.4 mmol) of Intermediate Int-8, 13.1 g (135.6 mmol) of NaOtBu, 2.5 g (2.7 mmol) of Pd₂(dba)₃, and 5.5 g (50% in toluene) of P(t-Bu)₃ were added to 300 mL of xylene and then, stirred under reflux under a nitrogen flow for 12 hours. After removing the xylene, 200 mL of methanol was added to the obtained mixture, and a solid crystallized therein was filtered, dissolved in MCB (monochlorobenzene), and filtered with silica gel, and an appropriate amount of an organic solvent was concentrated to obtain 32 g (64%) of Compound 1-24.

(LC/MS theoretical value: 550.22 g/mol, measured value: M+=551.23 g/mol)

### Synthesis Example 5: Synthesis of Compound 1-25

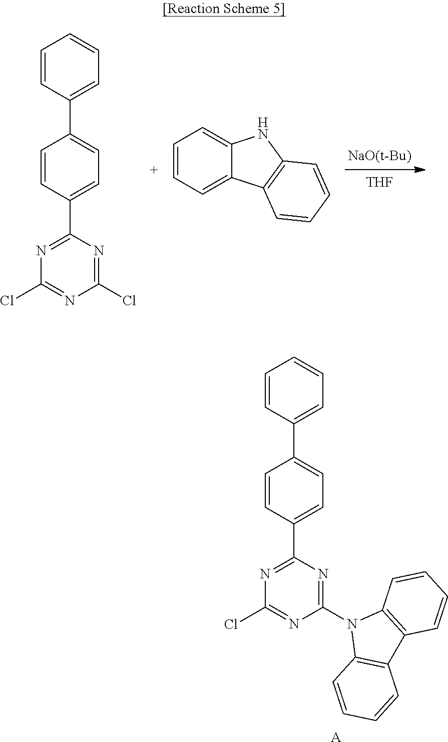

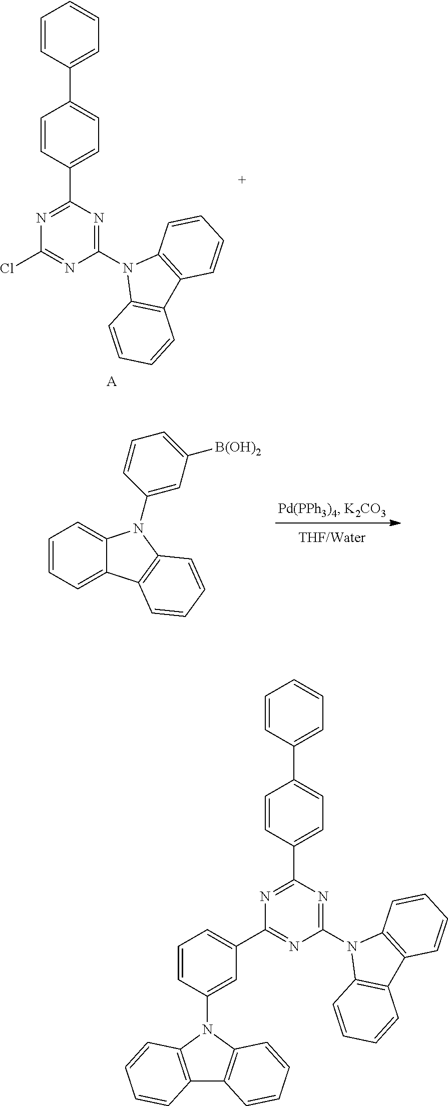

### 1st Step: Synthesis of Intermediate A

65.5 g (216.79 mmol) of 2-[1,1′-biphenyl]-4-yl-4,6-dichloro-1,3,5-triazine and 25 g (149.51 mmol) of carbazole were suspended in 800 ml of THF, and 15.09 g (156.99 mmol) of NaO(t-Bu) was slowly added thereto. After stirring the mixture for 12 hours at room temperature, a solid produced therein was filtered, washed with distilled water, acetone, and hexane in order to obtain 40.15 g (yield of 62%) of Intermediate A.

### 2nd Step: Synthesis of Compound 1-25

10 g (23.10 mmol) of Intermediate A, 8.70 g (23.56 mmol) of 3-(9H-carbazol-9-yl)phenyl boronic acid, 0.8 g (0.69 mmol) of Pd(PPh₃)₄, and 6.39 g (46.2 mmol) of K₂CO₃ were suspended in 100 ml of THE and 50 ml of distilled water and then, stirred under reflux for 12 hours. When a reaction was completed, after cooling to room temperature, the generated solid was filtered and washed with distilled water and acetone. The resulting solid was heated and dissolved in 200 ml of dichlorobenzene, silica gel-filtered, and recrystallized in 150 ml of dichlorobenzene to obtain 11 g (yield of 74%) of Compound 1-25.

(LC/MS: theoretical value: 639.75 g/mol, measured value:640.40 g/mol)

### Synthesis of Second Compound

### Synthesis Example 6: Synthesis of Compound 2-2

It was synthesized in the same manner as described in KR10-2017-0037277A.

### Synthesis Example 7: Synthesis of Compound 2-15

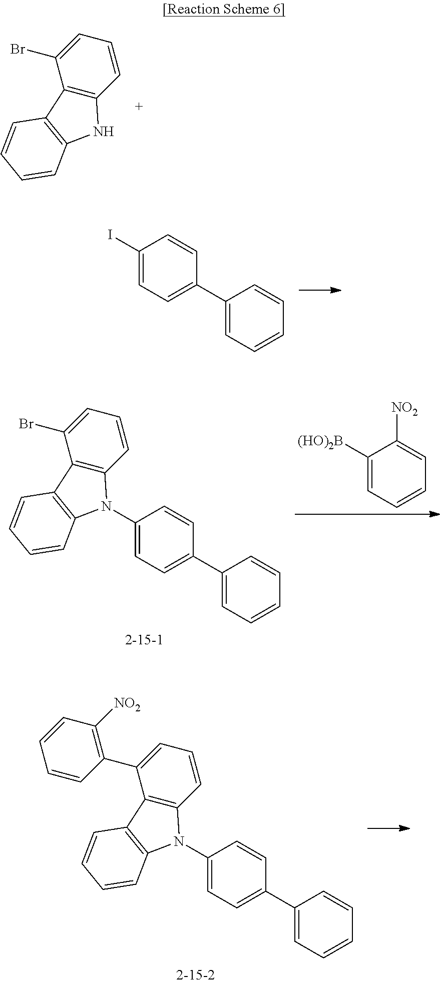 [SMILES: Brc1cccc2[nH]c3ccccc3c12 ; Ic1ccc(-c2ccccc2)cc1 ; Brc1cccc2c1c1ccccc1n2-c1ccc(-c2ccccc2)cc1 ; O=[N+]([O-])c1ccccc1B(O)O ; O=[N+]([O-])c1ccccc1-c1cccc2c1c1ccccc1n2-c1ccc(-c2ccccc2)cc1]

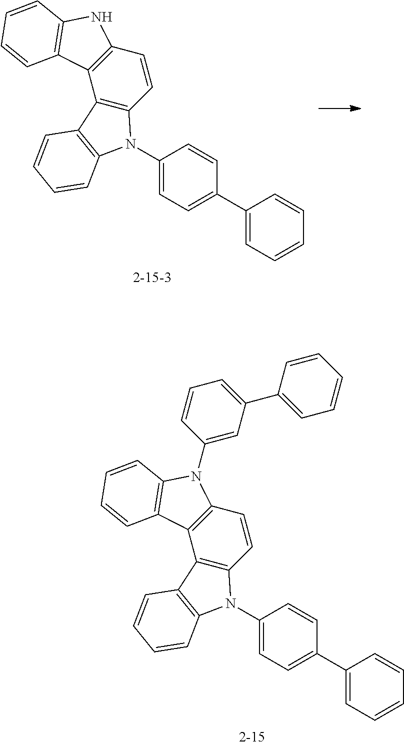 [SMILES: c1ccc(-c2ccc(-n3c4ccccc4c4c5c(ccc43)[nH]c3ccccc35)cc2)cc1 ; c1ccc(-c2ccc(-n3c4ccccc4c4c5c6ccccc6n(-c6cccc(-c7ccccc7)c6)c5ccc43)cc2)cc1]

### 1st Step: Synthesis of Intermediate 2-15-1

In a round-bottomed flask, 10.44 g (42.41 mmol) of 4-bromo-9H-carbazole, 11.88 g (42.41 mmol) of 4-iodo-1,1′-biphenyl(Aldrich), 0.388 g (0.424 mmol) of Pd₂(dba)₃, 0.206 g (0.848 mmol) of P(t-Bu)3, and 6.11 g (63.61 mmol) of NaO(t-Bu) were suspended in 420 ml of toluene and stirred at 60° C. for 12 hours. After completion of the reaction, distilled water was added thereto, stirred for 30 minutes, and extracted and only the organic layer was columned with a silica gel column (hexane/dichloromethane=9:1 (v/v)) to obtain 14.70 g (yield of 87%) of Intermediate 2-15-1.

### 2nd Step: Synthesis of Intermediate 2-15-2

In a round-bottom flask, 15.50 g (38.92 mmol) of the synthesized Intermediate 2-15-1, 7.15 g (42.81 mmol) of (2-nitrophenyl)-boronic acid, 16.14 g (116.75 mmol) of potassium carbonate, and 1.35 g (1.17 mmol) of tetrakis-(triphenylphosphine)palladium(0) (Pd(PPh₃)₄) was suspended in 150 ml of toluene and 70 ml of distilled water and then stirred under reflux for 12 hours. Then, extraction was performed with dichloromethane and distilled water, and the organic layer was filtered through silica gel. Then, the organic solution was removed, and the product solid was recrystallized from dichloromethane and n-hexane to obtain 13.72 g (yield of 80%) of Intermediate 2-15-2.

### 3rd Step: Synthesis of Intermediate 2-15-3

22.46 g (51.00 mmol) of Intermediate 2-15-2 and 52.8 ml of triethyl phosphite were placed in a round-bottomed flask and then, substituted with nitrogen and stirred for 12 hours at 160° C. When a reaction was completed, 3 L of MeOH was added thereto and then, filtered, and a filtrate therefrom was volatilized. A product therefrom was purified (hexane) through column chromatography, obtaining 10.42 g (yield: 50%) of Intermediate 2-15-3.

### 4th Step: Synthesis of Compound 2-15

Compound 2-15 was synthesized in the same manner as in the 1st step of Synthesis Example 7 by using Intermediate 2-15-3 and 3-iodo-1,1′-biphenyl(yield: 60%).

(LC/MS:theoretical value 560.23 g/mol, measured value:561.57 g/mol)

### Synthesis Example 8: Synthesis of Compound 2-13

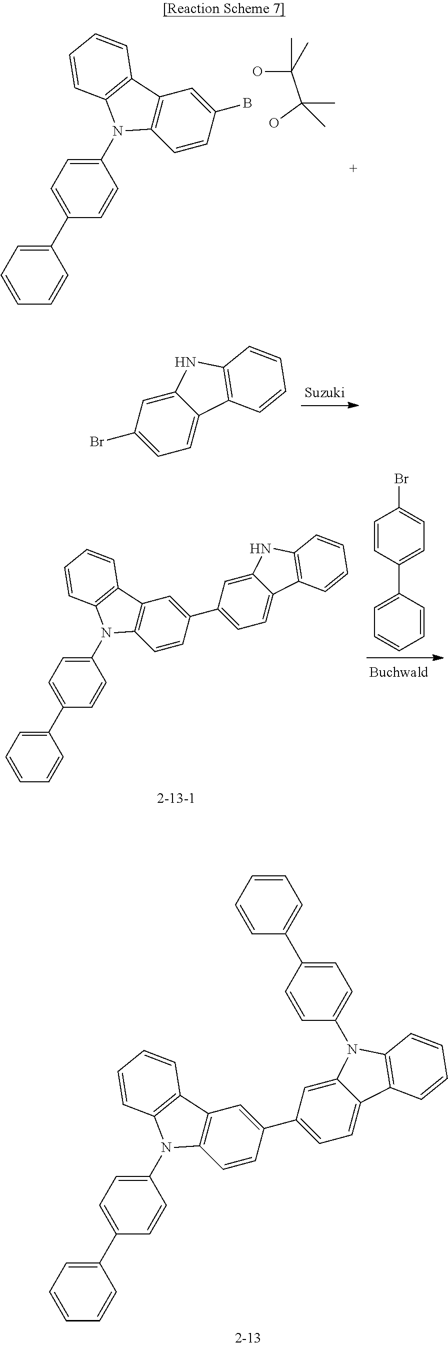

### 1st Step: Synthesis of Intermediate 2-13-1

In a round-bottomed flask, 18.23 g (40.94 mmol) of 2-[9-([1,1′-biphenyl]-4-yl)-9H-carbazole-3-yl]-4,4,5,5-tetramethyl-1,3,2-dioxaborolane, 11.08 g (45.03 mmol) of 2-bromo-9H-carbazole, 11.32 g (81.88 mmol) of potassium carbonate, and 1.42 g (1.23 mmol) of tetrakis-(triphenylphosphine)palladium (0) (Pd(PPh₃)₄) were suspended in 180 ml of tetrahydrofuran (THF) and 75 ml of distilled water and then, stirred under reflux for 12 hours. After extracting with dichloromethane and distilled water, an organic layer was silica gel-filtered. Subsequently, after removing an organic solution, a product solid therefrom was recrystallized with dichloromethane and n-hexane, obtaining 18.05 g (yield: 91%) of Intermediate 2-13-1.

### 2nd Step: Synthesis of Compound 2-13

In a round-bottomed flask, 13.29 g (27.42 mmol) of Intermediate 2-13-1, 6.39 g (27.42 mmol) of 4-bromo-biphenyl, 0.25 g (0.274 mmol) of Pd₂(dba)₃, 0.133 g (0.274 mmol) of P(t-Bu)₃, and 3.95 g (41.13 mmol) of NaO(t-Bu) were suspended in 300 ml of toluene and then, stirred at 60° C. for 12 hours. When a reaction was completed, distilled water was added thereto and then, stirred for 30 minutes and extracted, and an organic layer therefrom alone was columned through silica gel column (hexane/dichloromethane=9:1 (v/v)), obtaining 15.37 g (yield: 88%) of Compound 2-13.

LC-Mass (theoretical value: 636.26 g/mol, measured value: M+=637.40 g/mol)

### Synthesis of Third Compound

### Synthesis Example 9: Synthesis of Compound 3-6

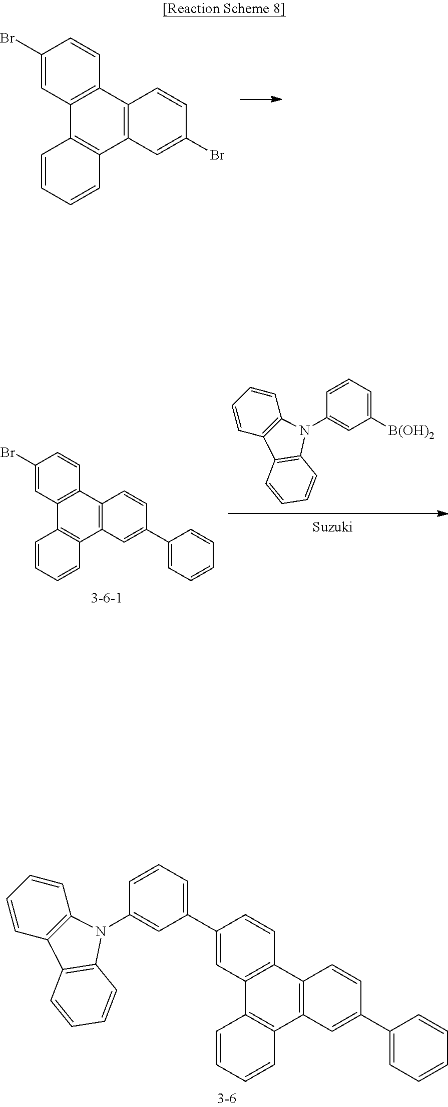

### 1st Step: Synthesis of Intermediate 3-6-1

Intermediate 3-6-1 was obtained by the same synthesis method described in KR2014135532 using 2,7-dibromotriphenylene (888041-37-0).

### 2nd Step: Synthesis of Compound 3-6

Compound 3-6 was synthesized in a yield of 80% using 1 equivalent of Intermediate 3-6-1 and 1.1 equivalents of intermediate (3-(9H-carbazol-9-yl)phenyl)boronic acid (cas: 864377-33-3) in the same manner as step 2 of Synthetic Example 5.

LC-Mass (theoretical value: 545.21 g/mol, measured value: M+=546.27 g/mol)

### Synthesis Example 10: Synthesis of Compound 3-7

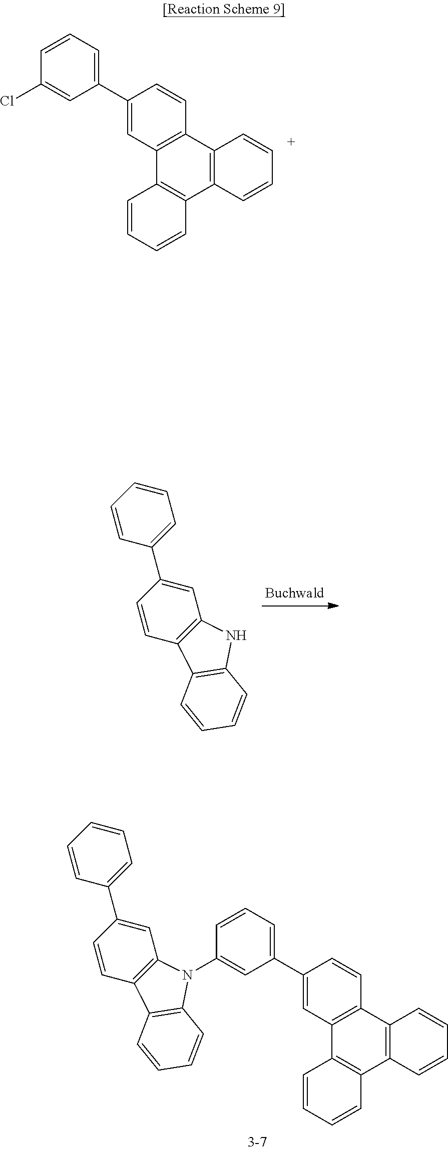 [SMILES: Clc1cccc(-c2ccc3c4ccccc4c4ccccc4c3c2)c1 ; c1ccc(-c2ccc3c(c2)[nH]c2ccccc23)cc1 ; c1ccc(-c2ccc3c4ccccc4n(-c4cccc(-c5ccc6c7ccccc7c7ccccc7c6c5)c4)c3c2)cc1]

### 1st Step: Synthesis of 3-7

Compound 3-7 was synthesized in a yield of 85% using the same method as 2nd step of Synthetic Example 8, using 1 equivalent of 2-(3-chlorophenyl)-triphenylene (cas: 1384206-44-3) and 1.05 equivalents of 2-phenyl-9H-carbazole (cas:88590-00-5).

LC-Mass (theoretical value: 545.21 g/mol, measured value: M+=546.24 g/mol)

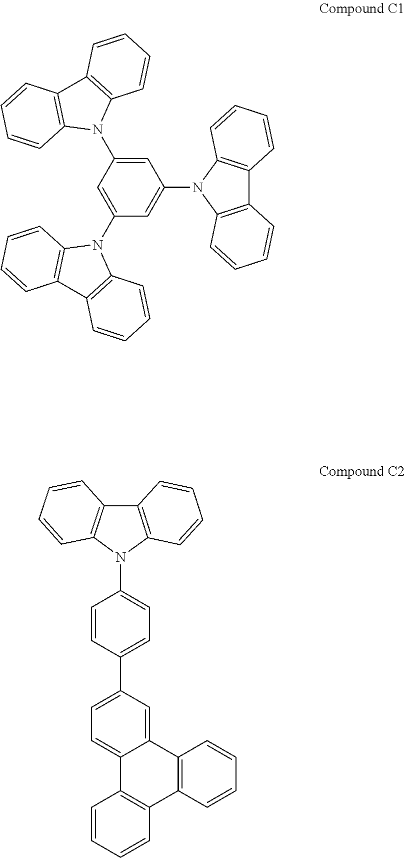 [SMILES: c1ccc2c(c1)c1ccccc1n2-c1cc(-n2c3ccccc3c3ccccc32)cc(-n2c3ccccc3c3ccccc32)c1 ; c1ccc2c(c1)c1ccccc1c1cc(-c3ccc(-n4c5ccccc5c5ccccc54)cc3)ccc21]

### Synthesis of Dopant

### Synthesis Example 11: Synthesis of Dopant Compound PtGD

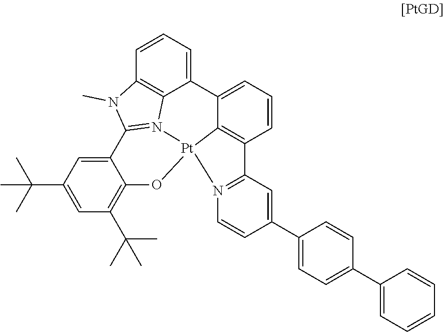

It was synthesized in the same manner as described in KR1999337.

### (Manufacture of Organic Light Emitting Diode)

### Example 1

A glass substrate coated with a thin film of ITO (Indium Tin Oxide) was washed with distilled water. After washing with the distilled water, the glass substrate was washed with a solvent such as isopropyl alcohol, acetone, methanol, and the like ultrasonically and dried and then, moved to a plasma cleaner, cleaned by using oxygen plasma for 10 minutes, and moved to a vacuum depositor. This prepared ITO transparent electrode was used as an anode, Compound A doped with 3% NDP-9 (Novaled GmbH) was vacuum-deposited on the ITO substrate to form a 100 Å-thick hole injection layer, and Compound A is deposited on the hole injection layer to form a 1350 Å-thick hole transport layer. Compound B was deposited on the hole transport layer to a thickness of 350 Å to form a hole transport auxiliary layer. Compounds 1-27, 2-2, and 3-7 were simultaneously used as hosts on the hole transport auxiliary layer, and 15 wt % of PtGD was doped as a dopant to form a 400 Å-thick light emitting layer by vacuum deposition. Here, Compounds 1-27, 2-2, and 3-7 were used in a weight ratio of 30:55:15, and the ratios were described separately for the following examples and comparative examples. Subsequently, on the light emitting layer, Compound C was deposited to form a 50 Å-thick electron transport auxiliary layer, and Compound D and LiQ in a weight ratio of 1:1 were simultaneously vacuum-deposited to form a 300 Å-thick electron transport layer. On the electron transport layer, a cathode was formed by sequentially vacuum-depositing 15 Å of LiQ and 1,200 Å of Al, manufacturing an organic light emitting diode.

The organic light emitting diode was manufactured to have a structure of ITO/Compound A (3% NDP-9 doping, 100 Å)/Compound A (1,350 Å)/Compound B (350 Å)/EML [{85 wt % host (1-27: 2-2:3-7)}+{15 wt % dopant (PtGD)}](400 Å)/Compound C (50 Å)/Compound D:LiQ (300 Å)/LiQ (15 Å)/Al (1,200 Å).
Compound A: N-(biphenyl-4-yl)-9,9-dimethyl-N-(4-(9-phenyl-9H-carbazol-3-yl)phenyl)-9H-fluoren-2-amine
B: N,N-bis(9,9-dimethyl-9H-fluoren-4-yl)-9,9-spirobi(fluorene)-2-amine
Compound C: 2-[3′-(9,9-dimethyl-9H-fluoren-2-yl)[1,1′-biphenyl]-3-yl]-4,6-diphenyl-1,3,5-triazine
Compound D: 2-[4-[4-(4′-cyano-1,1′-biphenyl-4-yl)-1-naphthyl]phenyl]-4,6-diphenyl-1,3,5-triazine

### Examples 2 and 3

Organic light emitting diodes were manufactured in the same manner as in Example 1, except that the composition was changed to the host shown in Tables 1 to 3.

### Comparative Examples 1 to 8

Organic light emitting diodes were manufactured in the same manner as in Example 1, except that the composition was changed to the host shown in Tables 1 to 3.

### Evaluation

The efficiency and life-spans of the organic light emitting diodes according to Examples 1 to 3 and Comparative Examples 1 to 8 were measured.

Specific measurement methods are as follows, and the results are shown in Tables 1 to 3.

### (1) Measurement of Life-span

The results were obtained by measuring a time when current efficiency (cd/A) was decreased down to 95%, while luminance (cd/m²) was maintained to be 24,000 cd/m². The relative life-span ratio was shown based on the life-span values of Comparative Examples 1, 5, and 7, respectively.

(2) Measurement of Current Density Change according to Voltage Change

The manufactured organic light emitting diodes were measured with respect to a current flowing through a unit device by using a current-voltage meter (Keithley 2400), while increasing a voltage from 0 V to 10 V, and the measured current value was divided by an area to provide the results.

### (3) Measurement of Luminance Change Depending on Voltage Change

Luminance was measured by using a luminance meter (Minolta Cs-1000A), while increasing the voltage of the organic light emitting diodes from 0 V to 10 V.

### (4) Measurement of Luminous Efficiency

The current efficiency (cd/A) of the required luminance of 9000 nits was calculated using the luminance, current density, and voltage measured from (1) and (2). The relative efficiency ratio was shown based on the current efficiency values of Comparative Examples 1, 5, and 7, respectively.

TABLE 1

| | | | | First | | Life- |
|---|---|---|---|---|---|---|
| | | | | host:second | | span |
| | | | | host:third | Efficiency | ratio |
| | First | Second | Third | host ratio | ratio | (T95) |
| | host | host | host | (wt:wt) | (%) | (%) |
| Ex. 1 | 1-27 | 2-2 | 3-7 | 30:55:15 | 100 | 120 |
| Comp. | 1-27 | 2-2 | — | 35:65:0 | 100 | 100 |
| Ex. 1 | | | | | | |
| Comp. | 1-27 | — | 3-7 | 35:0:65 | 85 | 45 |
| Ex. 2 | | | | | | |
| Comp. | 1-27 | 2-2 | C1 | 30:55:15 | 98 | 96 |
| Ex. 3 | | | | | | |
| Comp. | 1-27 | 2-2 | C2 | 30:55:15 | 95 | 102 |
| Ex. 4 | | | | | | |

TABLE 2

| | | | | First | | Life- |
|---|---|---|---|---|---|---|
| | | | | host:second | | span |
| | | | | host:third | Efficiency | ratio |
| | First | Second | Third | host ratio | ratio | (T95) |
| | host | host | host | (wt:wt) | (%) | (%) |
| Ex. 2 | 1-24 | 2-15 | 3-6 | 35:55:10 | 100 | 115 |
| Comp. | 1-24 | 2-15 | — | 35:65:0 | 100 | 100 |
| Ex. 5 | | | | | | |
| Comp. | 1-24 | — | 3-6 | 35:0:65 | 85 | 35 |
| Ex. 6 | | | | | | |

TABLE 3

| | | | | First | | Life- |
|---|---|---|---|---|---|---|
| | | | | host:second | | span |
| | | | | host:third | Efficiency | ratio |
| | First | Second | Third | host ratio | ratio | (T95) |
| | host | host | host | (wt:wt) | (%) | (%) |
| Ex. 3 | 1-25 | 2-13 | 3-7 | 32:48:20 | 100 | 130 |
| Comp. | 1-25 | 2-13 | — | 35:65:0 | 100 | 100 |
| Ex. 7 | | | | | | |
| Comp. | 1-25 | — | 3-7 | 35:0:65 | 80 | 50 |
| Ex. 8 | | | | | | |

Referring to Tables 1 to 3, the organic light emitting diodes according to Examples 1 to 3 exhibited significantly improved life-span while maintaining the same or higher efficiency compared to the organic light emitting diodes according to Comparative Examples 1 to 8.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

1. A composition for an organic optoelectronic device, comprising:
a first compound;
a second compound; and
a third compound,
wherein the first compound is represented by Chemical Formula 1,
the second compound is represented by Chemical Formula 2 or a combination of Chemical Formula 3 and Chemical Formula 4, and
the third compound is represented by Chemical Formula 5: 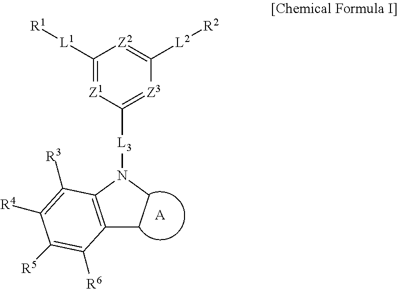
wherein, in Chemical Formula 1,
Z¹ to Z³ are N or C-L^{a}-R^{a},
at least two of Z¹ to Z³ are N,
L^{a} and L¹ to L³ are each independently a single bond, a substituted or unsubstituted C6 to C20 arylene group, a substituted or unsubstituted C2 to C20 heterocyclic group, or a combination thereof,
R¹ and R² are each independently a substituted or unsubstituted C6 to C30 aryl group, a substituted or unsubstituted C2 to C30 heterocyclic group, or a combination thereof,
R^{a} and R³ to R⁶ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
ring A is represented by one of Chemical Formula I-1 to Chemical Formula I-6, 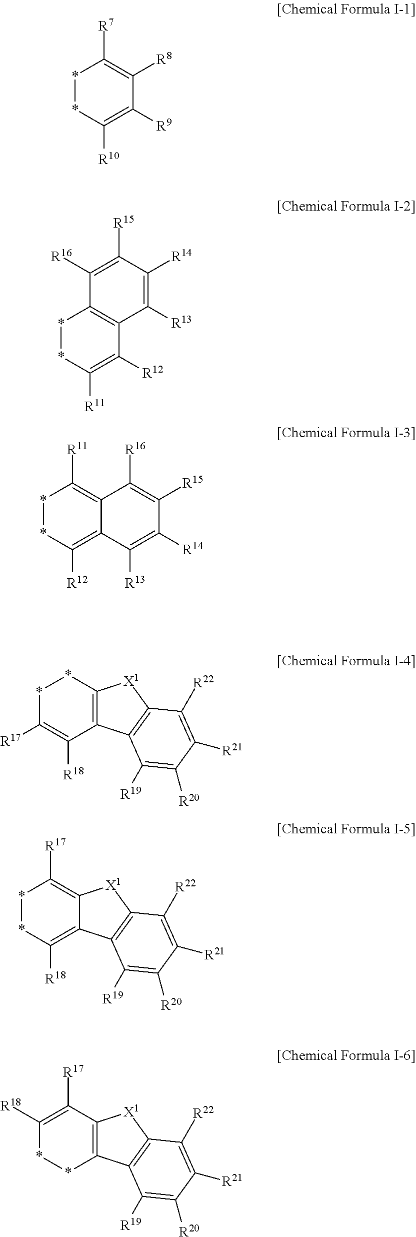
wherein, in Chemical Formula I-1 to Chemical Formula I-6,
X¹ is O, S, or NR,
R^{b} and R⁷ to R²² are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof, and
* is a linking point; 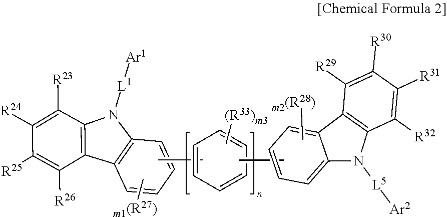
wherein, in Chemical Formula 2,
Ar¹ and Ar² are each independently a substituted or unsubstituted C6 to C30 aryl group or a substituted or unsubstituted C2 to C30 heterocyclic group,
L⁴ and L⁵ are each independently a single bond or a substituted or unsubstituted C6 to C20 arylene group,
R²³ to R³³ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group,
m1 and m2 are each independently an integer of 1 to 3,
m3 is an integer of 1 to 4, and
n is an integer of 0 to 2; 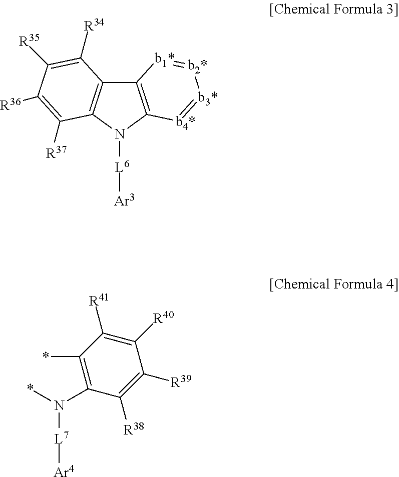
wherein, in Chemical Formulas 3 and 4,
Ar³ and Ar⁴ are each independently a substituted or unsubstituted C6 to C30 aryl group or a substituted or unsubstituted C2 to C30 heterocyclic group,
among b₁* to b₄* in Chemical Formula 3, two adjacent ones are each a linking carbon (C) that is linked to * in Chemical Formula 4,
among b₁* to b₄* in Chemical Formula 3, the remaining two that are not linked to * in Chemical Formula 4 are each independently C-L^{b}-R^{c},
L^{b}, L⁶, and L⁷ are each independently a single bond or a substituted or unsubstituted C6 to C20 arylene group, and
R^{c} and R³⁴ to R⁴¹ are each independently hydrogen, deuterium, a cyano group, a halogen, a substituted or unsubstituted amine group, a substituted or unsubstituted C1 to C30 alkyl group, a substituted or unsubstituted silyl group, a substituted or unsubstituted C6 to C30 aryl group, or a substituted or unsubstituted C2 to C30 heterocyclic group; 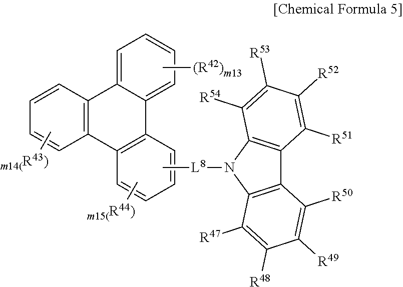
wherein, in Chemical Formula 5,
R⁴² to R⁴⁴ and R⁴⁷ to R⁵⁴ are each independently hydrogen, deuterium, a substituted or unsubstituted C1 to C30 alkyl group, a substituted or unsubstituted C6 to C30 aryl group, a substituted or unsubstituted C2 to C30 heterocyclic group, a substituted or unsubstituted silyl group, a substituted or unsubstituted amine group, a halogen, a cyano group, or a combination thereof,
m13 and m14 are each independently an integer of 1 to 4,
m15 is an integer of 1 to 3, and
L⁸ is a single bond or a substituted or unsubstituted C6 to C20 arylene group including at least one of a meta-phenylene group and a para-phenylene group.

2. The composition for an organic optoelectronic device as claimed in claim 1, wherein:
the first compound is represented by Chemical Formula 1A or Chemical Formula 1E: 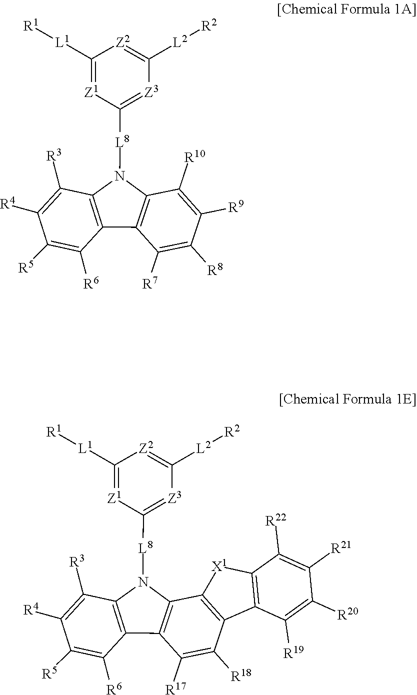
in Chemical Formula 1A and Chemical Formula 1E, Z¹ to Z³, L¹ to L³, R¹ to R¹⁰, R¹⁷ to R²² and X¹ are defined the same as those of Chemical Formula 1.

3. The composition for an organic optoelectronic device as claimed in claim 2, wherein the first compound is represented by Chemical Formula 1A.

4. The composition for an organic optoelectronic device as claimed in claim 1, wherein:
the second compound is represented by one of Chemical Formula 2-6, Chemical Formula 2-8, or Chemical Formula 3C: 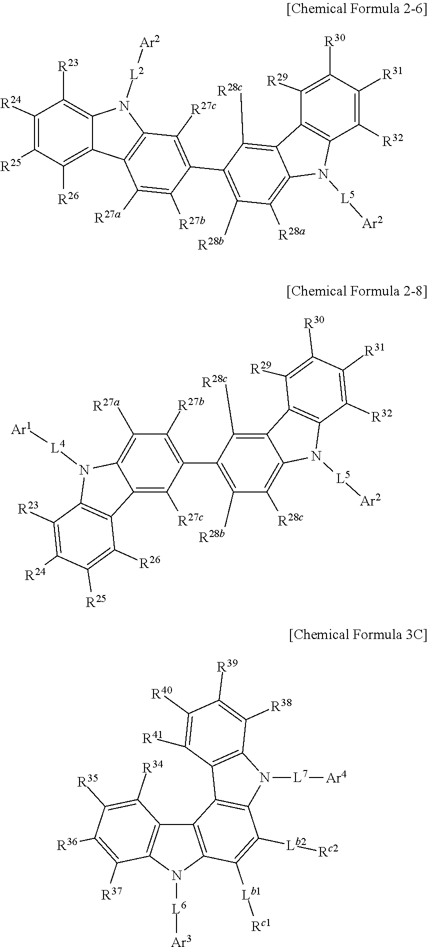
in Chemical Formula 2-6, Chemical Formula 2-8, and Chemical Formula 3C, the definitions of L⁴ to L⁷, Ar¹ to Ar⁴, R²³ to R²⁶, R²⁹ to R³², and R³⁴ to R⁴¹ are defined the same as those of Chemical Formula 2, Chemical Formula 3, and Chemical Formula 4,
the definitions of R^{27a}, R^{27b}, R^{27c}, R^{28a}, R^{28b} and R^{28c} are defined the same as R²⁷ and R²⁸ of Chemical Formula 2,
L^{b1} and L^{b2} are defined the same as L^{b} of Chemical Formula 3, and
R^{c1} and R^{c2} are defined the same as R^{c} of Chemical Formula 3.

5. The composition for an organic optoelectronic device as claimed in claim 1, wherein in Chemical Formula 5, L⁸ is a single bond, a substituted or unsubstituted phenylene group including at least one of a meta-phenylene group and a para-phenylene group, a substituted or unsubstituted biphenylene group including at least one of a meta-phenylene group and a para-phenylene group, or a substituted or unsubstituted terphenylene group including at least one of a meta-phenylene group and a para-phenylene group.

6. The composition for an organic optoelectronic device as claimed in claim 1, wherein:
in Chemical Formula 5, L⁸ is a single bond or a linking group listed in Group I: 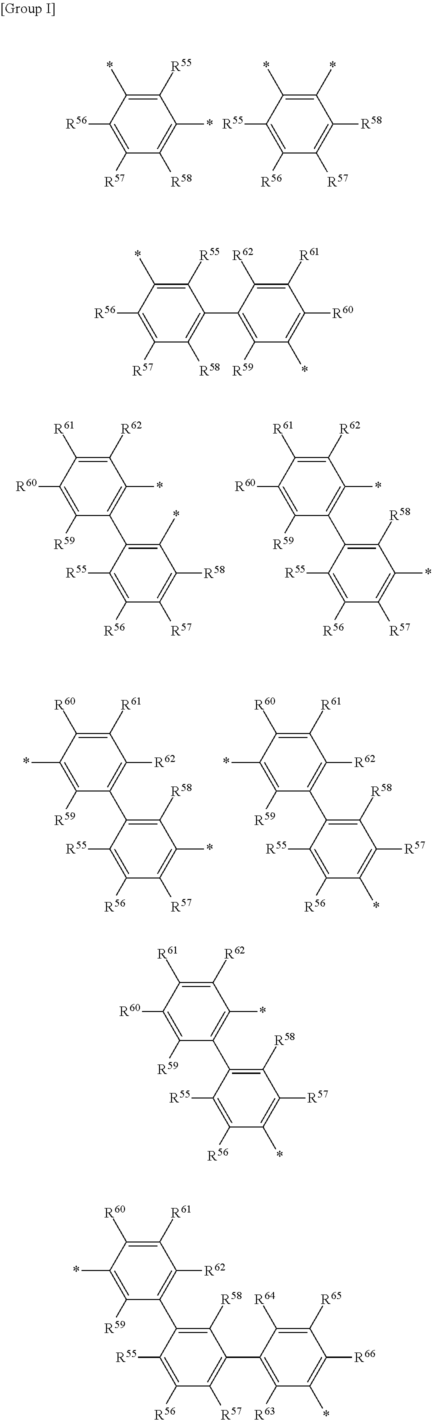 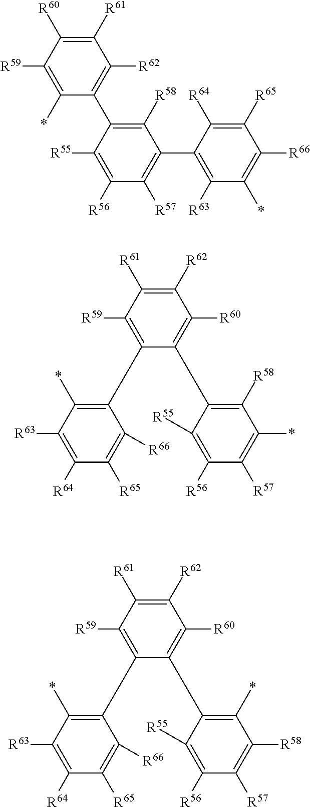
in Group I,
R⁵⁵ to R⁶⁶ are each independently hydrogen, deuterium, a C1 to C10 alkyl group, a substituted or unsubstituted C6 to C12 aryl group, a halogen, a cyano group, or a combination thereof, and
* is a linking point.

7. The composition for an organic optoelectronic device as claimed in claim 1, wherein:
the third compound is represented by one of Chemical Formula 5-I to Chemical Formula 5-III: 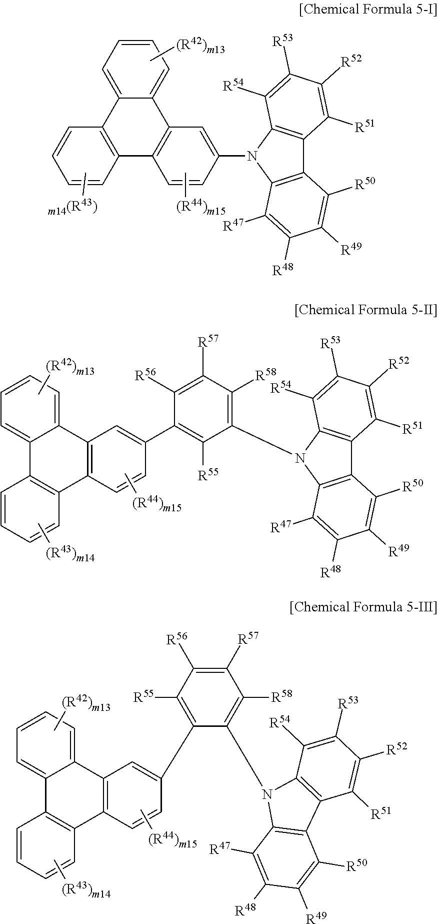
in Chemical Formula 5-I to Chemical Formula 5-III, R⁴² to R⁴⁴, R⁴⁷ to R⁵⁸, and m13 to m15 are defined the same as those of Chemical Formula 5.

8. The composition for an organic optoelectronic device as claimed in claim 1, wherein in Chemical Formula 5, R⁴² to R⁴⁴ are each independently hydrogen, deuterium, a substituted or unsubstituted phenyl group, or a substituted or unsubstituted biphenyl group.

9. The composition for an organic optoelectronic device as claimed in claim 1, wherein in Chemical Formula 5, R⁴⁷ to R⁵⁴ are each independently hydrogen, deuterium, a substituted or unsubstituted phenyl group, a substituted or unsubstituted biphenyl group, a substituted or unsubstituted carbazolyl group, a substituted or unsubstituted dibenzofuranyl group, or a substituted or unsubstituted dibenzothiophenyl group.

10. The composition for an organic optoelectronic device as claimed in claim 1, wherein:
the first compound is represented by Chemical Formula 1A,
the second compound is represented by one of Chemical Formula 2-6, Chemical Formula 2-8, or Chemical Formula 3C, and
the third compound is represented by Chemical Formula 5-II: 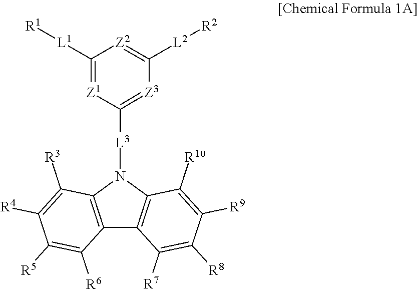
in Chemical Formula 1A,
Z¹ to Z³, L¹ to L³ and R¹ to R¹⁰ are defined the same as those of Chemical Formula 1; 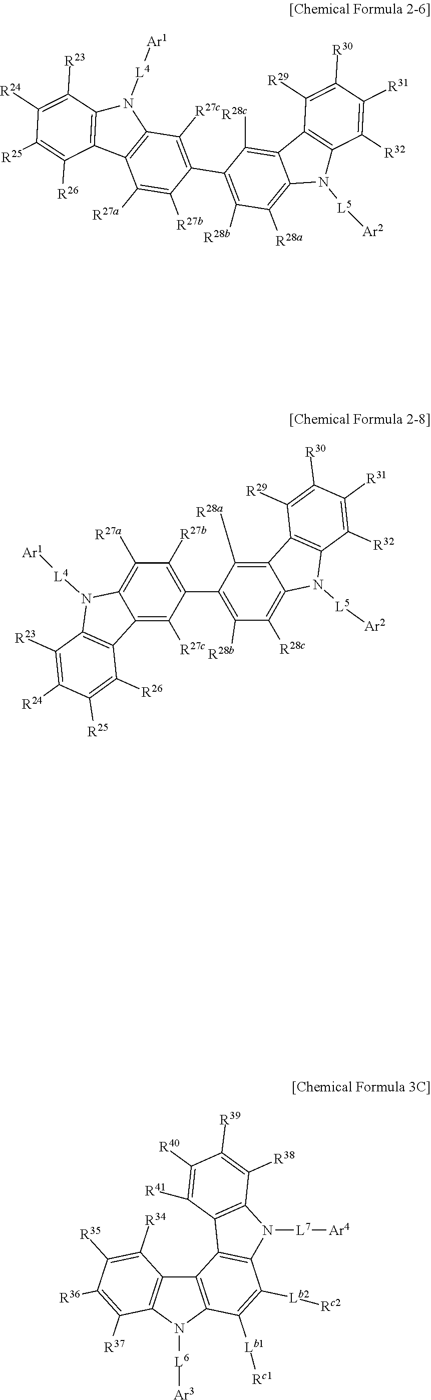
wherein, in Chemical Formula 2-6, Chemical Formula 2-8, and Chemical Formula 3C, R²³ to R²⁶, R^{27a}, R^{27b}, R^{27c}, R^{28a}, R^{28b}, R^{28c}, R²⁹ to R³², and R³⁴ to R⁴¹ are each independently hydrogen, deuterium, a substituted or unsubstituted C6 to C12 aryl group, a substituted or unsubstituted carbazolyl group, a substituted or unsubstituted dibenzofuranyl group, or a substituted or unsubstituted dibenzothiophenyl group, and
*-L⁴-Ar¹, *-L⁵-Ar², *-L⁶-Ar³, and *-L⁷-Ar⁴ are each independently a substituent listed in Group II, 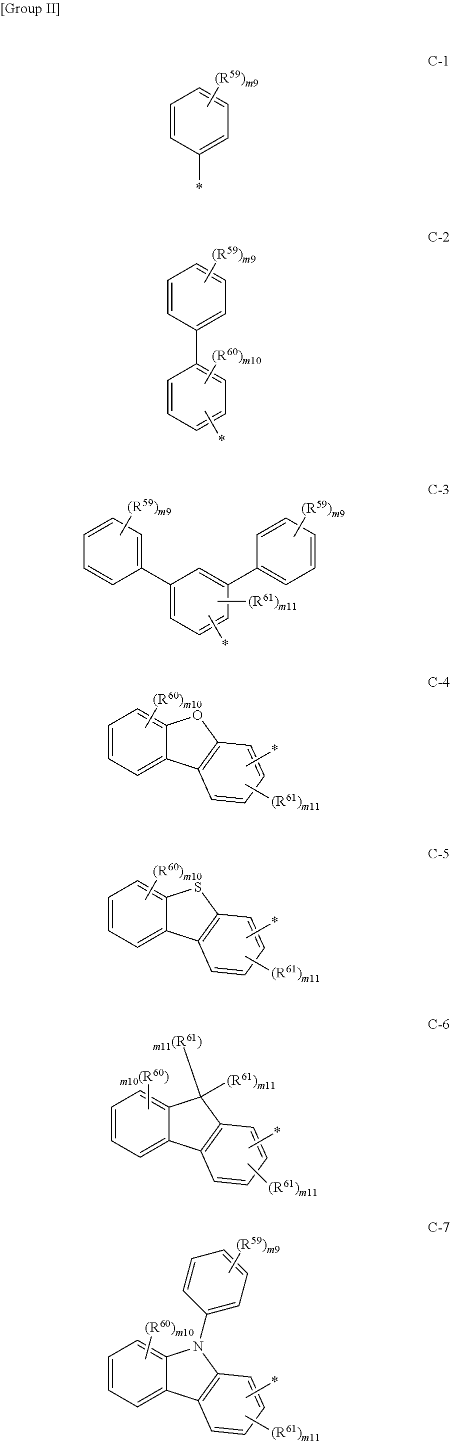 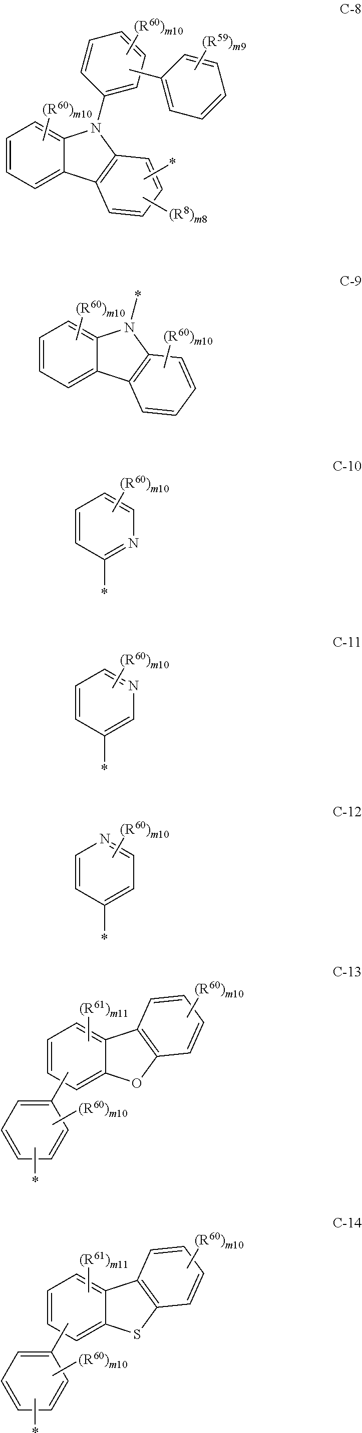 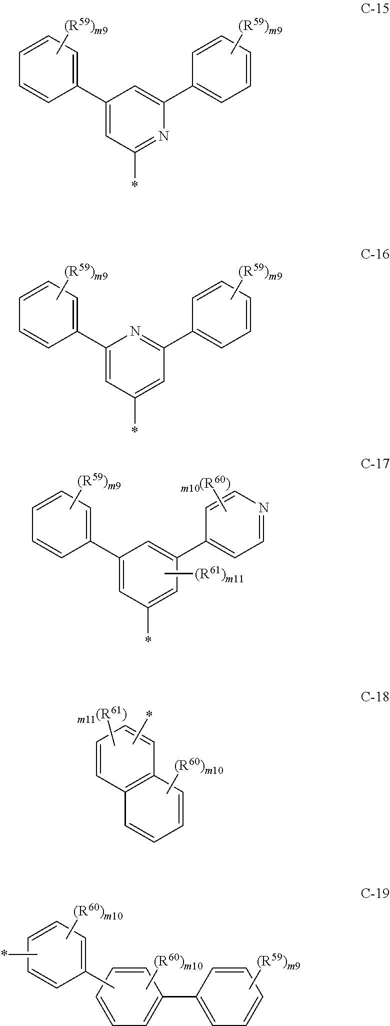 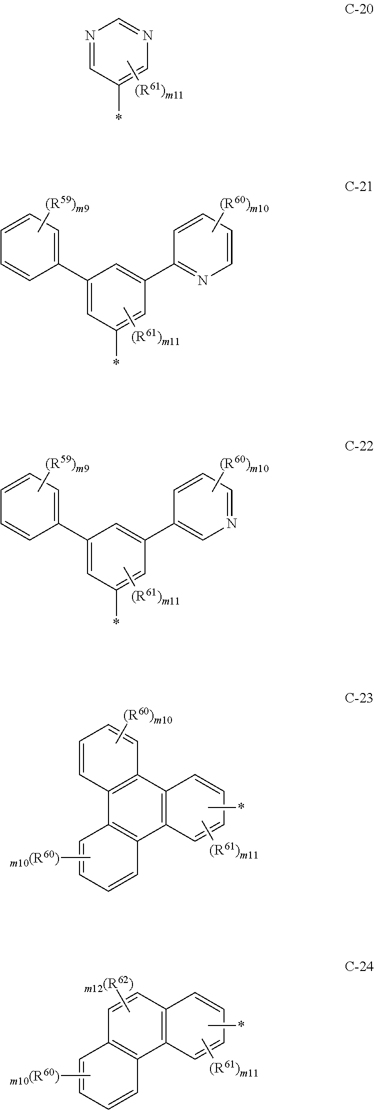 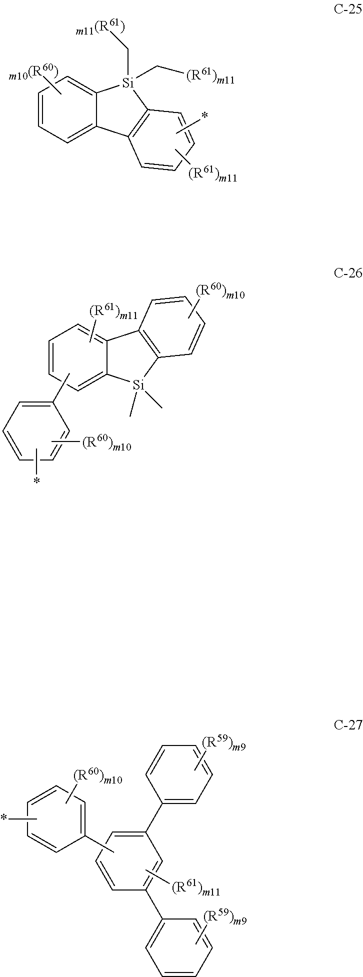
in Group II,
R⁵⁹ to R⁶² are each independently hydrogen, deuterium, a C1 to C4 alkyl group, a C6 to C18 aryl group, or a C2 to C30 heteroaryl group,
m9 is an integer of 1 to 5,
m10 is an integer of 1 to 4,
m11 is an integer of 1 to 3,
m12 is an integer of 1 or 2, and
* is a linking point; 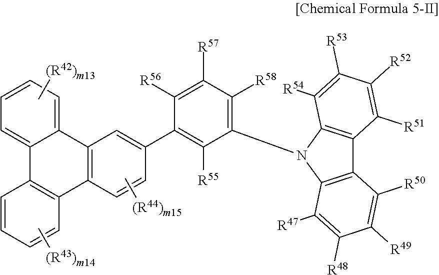
wherein, in Chemical Formula 5-II, R⁴² to R⁴⁴, R⁴⁷ to R⁵⁸, and m13 to m15 are defined the same as those of Chemical Formula 5.

11. An organic optoelectronic device, comprising:
an anode and a cathode facing each other, and
at least one organic layer between the anode and the cathode,
wherein the at least one organic layer includes the composition for an organic optoelectronic device as claimed in claim 1.

12. The organic optoelectronic device as claimed in claim 11, wherein:
the organic layer includes a light emitting layer, and
the light emitting layer includes the composition for an organic optoelectronic device.

13. The organic optoelectronic device as claimed in claim 12, wherein the first compound, the second compound, and the third compound are each included as a phosphorescent host of the light emitting layer.

14. The organic optoelectronic device as claimed in claim 13, wherein:
the first compound is included in an amount of about 20 wt % to 50 wt %, based on a total combined weight of the first compound, the second compound, and the third compound,
the second compound is included in an amount of about 40 wt % to 60 wt %, based on a total combined weight of the first compound, the second compound, and the third compound, and
the third compound is included in an amount of about 10 wt % to 30 wt %, based on a total combined weight of the first compound, the second compound, and the third compound.

15. The organic optoelectronic device as claimed in claim 12, wherein the composition for an organic optoelectronic device further includes a dopant.

16. The organic optoelectronic device as claimed in claim 15, wherein the composition for an organic optoelectronic device is a green light emitting composition.

17. A display device comprising the organic optoelectronic device as claimed in claim 11.
